(19) United States
(12) Patent Application Publication
(10) Pub. No.: US 2026/0114117 A1
(43) Pub. Date: Apr. 23, 2026

(54) ORGANIC LIGHT EMITTING DEVICE

(71) Applicant: LG CHEM, LTD., Seoul (KR)

(72) Inventors: Hoon Jun KIM, Daejeon (KR); Miyeon HAN, Daejeon (KR); Min Woo JUNG, Daejeon (KR); Young Seok KIM, Daejeon (KR); Jun Hyoung PARK, Daejeon (KR); Joongsuk HO, Daejeon (KR); Hye Min CHO, Daejeon (KR); Hojung LEE, Daejeon (KR); Soyeon KIM, Daejeon (KR); Hyungjin PARK, Daejeon (KR); Jeonghoe HEO, Daejeon (KR)

(21) Appl. No.: 19/346,119

(22) Filed: Sep. 30, 2025

(30) Foreign Application Priority Data
Oct. 2, 2024 (KR) 10-2024-0133748
Sep. 15, 2025 (KR) 10-2025-0131746

(51) Int. Cl. H10K 50/12; H10K 85/30; H10K 85/60

(52) U.S. Cl. CPC H10K 50/12; H10K 85/342; H10K 85/615; H10K 85/633; H10K 85/636; H10K 85/654; H10K 85/6572; H10K 85/6574; H10K 85/6576

(57) ABSTRACT

A composition for an organic light emitting device, including a first compound of the following Chemical Formula 1 and a second compound of the following Chemical Formula 2:

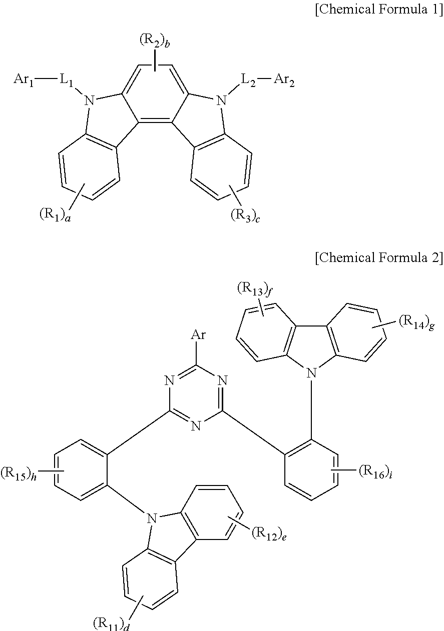

wherein: Ar₁ is a substituted or unsubstituted C₆₋₆₀ aryl; Ar₂ is a substituted or unsubstituted C₆₋₆₀ aryl, or a substituted or unsubstituted C₂₋₆₀ heteroaryl containing at least one heteroatom selected among N, O and S, provided that the case where Ar₂ is a monocyclic containing one or more N atoms is excluded; Ar is C₆₋₆₀ aryl that is unsubstituted or substituted with one or more substituents selected from the group consisting of deuterium, tritium, alkyl, and aryl, or substituted with a substituent to which two or more substituents of the above-exemplified substituents are connected; and the other substituents are as described in the specification; and an organic light emitting device including the composition.

### CROSS-REFERENCE TO RELATED APPLICATIONS

This application claims the benefit of and priority to Korean Patent Application No. 10-2024-0133748, filed Oct. 2, 2024, and Korean Patent Application No. 10-2025-0131746, filed Sep. 15, 2025, the disclosures of which are incorporated herein by reference in their entirety.

### TECHNICAL FIELD

The present disclosure relates to an organic light emitting device.

### BACKGROUND ART

In general, an organic light emitting phenomenon refers to a phenomenon where electric energy is converted into light energy by using an organic material. The organic light emitting device using the organic light emitting phenomenon has characteristics such as a wide viewing angle, an excellent contrast, a fast response time, an excellent luminance, driving voltage and response speed, and thus many studies have proceeded.

The organic light emitting device generally has a structure which comprises an anode, a cathode, and an organic material layer interposed between the anode and the cathode. The organic material layer frequently has a multilayered structure that comprises different materials in order to enhance efficiency and stability of the organic light emitting device, and for example, the organic material layer may be formed of a hole injection layer, a hole transport layer, a light emitting layer, an electron transport layer, an electron injection layer and the like. In the structure of the organic light emitting device, if a voltage is applied between two electrodes, the holes are injected from an anode into the organic material layer and the electrons are injected from the cathode into the organic material layer, and when the injected holes and electrons meet each other, an exciton is formed, and light is emitted when the exciton falls to a ground state again.

There is a continuous need to develop a new material for the organic material used in the organic light emitting device as described above.

### PRIOR ART LITERATURE

### Patent Literature

(Patent Literature 0001) Korean Unexamined Patent Publication No. 10-2000-0051826

### DETAILED DESCRIPTION OF THE INVENTION

### Technical Problem

It is an object of the present disclosure to provide an organic light emitting device.

### Technical Solution

According to the present disclosure, there is provided a composition for an organic light emitting device, comprising a first compound represented by the following Chemical Formula 1 and a second compound represented by the following Chemical Formula 2:

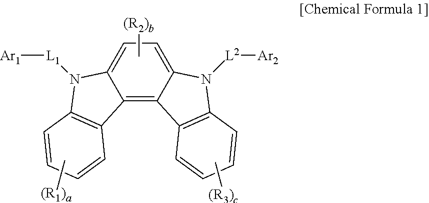

wherein in Chemical Formula 1,
L₁ and L₂ are each independently a single bond, or a substituted or unsubstituted C₆₋₆₀ arylene,
Ar₁ is a substituted or unsubstituted C₆₋₆₀ aryl,
Ar₂ is a substituted or unsubstituted C₆₋₆₀ aryl, or a substituted or unsubstituted C₂₋₆₀ heteroaryl containing at least one heteroatom selected among N, O and S, provided that the case where Ar₂ is a monocyclic containing one or more N atoms is excluded,
R₁ to R₃ are each independently hydrogen, deuterium, or tritium,
a and b are each independently an integer from 0 to 4, and
b is an integer from 0 to 2,

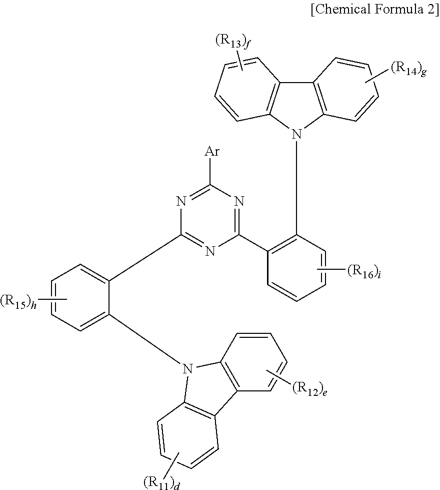

wherein in Chemical Formula 2,
Ar is C₆₋₆₀ aryl unsubstituted or substituted with one or more substituents selected from the group consisting of deuterium, tritium, alkyl, and aryl, or being unsubstituted or substituted with a substituent to which two or more substituents of the above-exemplified substituents are connected,
R₁₁ to R₁₄ are each independently hydrogen, deuterium, tritium, or a substituted or unsubstituted C₆₋₆₀ aryl; or are combined with adjacent substituents to form a substituted or unsubstituted C₆₋₆₀ aromatic ring or a substituted or unsubstituted C₂₋₆₀ heteroaromatic ring containing at least one heteroatom selected among N, O and S,
R₁₅ and R₁₆ are each independently hydrogen, deuterium, tritium, or a substituted or unsubstituted C₆₋₆₀ aryl, and
d to i are each independently an integer from 0 to 4.

Further, according to the present disclosure, there is provided an organic light emitting device comprising: a first electrode; a second electrode that is provided opposite to the first electrode; and one or more organic material layers that are provided between the first electrode and the second electrode, wherein one or more layers of the organic material layers comprises the composition for an organic light emitting device.

Further, according to the present disclosure, there is provided an organic light emitting device comprising: an anode; a cathode which is provided opposite to the anode; and a light emitting layer which is interposed between the anode and the cathode, wherein the light emitting layer includes the first compound represented by Chemical Formula 1, and the second compound represented by Chemical Formula 2.

### Advantageous Effects

The above-mentioned organic light emitting device includes two types of host compounds in the light emitting layer, and thus can improve efficiency, driving voltage and/or lifetime characteristics in the organic light emitting device.

### BRIEF DESCRIPTION OF THE DRAWINGS

FIG. 1 shows an example of an organic light emitting device comprising a substrate 1, an anode 2, a light emitting layer 3, and a cathode 4.

FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron injection and transport layer 9, and a cathode 4.

FIG. 3 shows an example of an organic light emitting device comprising a substrate 1, an anode 2, a hole injection layer 5, a first hole transport layer 6-1, a second hole transport layer 6-2, an electron blocking layer 7, a light emitting layer 3, a hole blocking layer 8, an electron injection and transport layer 9, and a cathode 4.

### DETAILED DESCRIPTION OF THE EMBODIMENTS

Hereinafter, embodiments of the present disclosure will be described in more detail to help understanding of the invention.

### Definition of Terms

In the present disclosure, the notation [symbol] or [symbol] means a bond linked to another substituent group, and “D” means deuterium.

In the present disclosure, the term “substituted or unsubstituted” means being unsubstituted or substituted with one or more substituents selected from the group consisting of deuterium; tritium; a halogen group; a cyano group; a nitro group; a hydroxy group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; and a heterocyclic group containing at least one of N, O and S atoms, or being unsubstituted or substituted with a substituent group to which two or more substituent groups of the above-exemplified substituent groups are linked. For example, “a substituent in which two or more substituents are linked” may be a biphenylyl group. Namely, a biphenylyl group may be an aryl group, or it may be interpreted as a substituent formed by linking two phenyl groups. In one example, the term “substituted or unsubstituted” may be understood as meaning “being unsubstituted or substituted with one or more substituents selected from the group consisting of deuterium, halogen, cyano, a silyl group, a C₁₋₁₀ alkyl, a C₁₋₁₀ alkoxy and a C₆₋₂₀ aryl”, or “being unsubstituted or substituted with one or more substituents selected from the group consisting of deuterium, halogen, cyano, methyl, ethyl, phenyl, biphenylyl and naphthyl”. Further, the term “substituted with one or more substituents” as used herein may be understood as meaning “being substituted with mono to the maximum number of substitutable hydrogens”. Alternatively, the term “substituted with one or more substituents” as used herein may be understood as meaning “being substituted with 1 to 5 substituents”, or “being substituted with one or two substituents”.

In the present disclosure, the carbon number of a carbonyl group is not particularly limited, but is preferably 1 to 40. Specifically, the carbonyl group may be a substituent having the following structural formulas, but is not limited thereto.

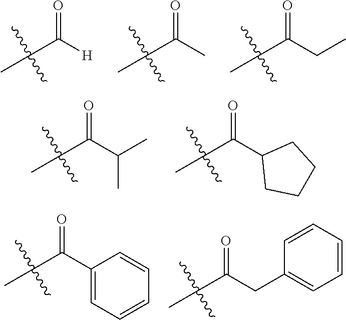

In the present disclosure, an ester group may have a structure in which oxygen of the ester group may be substituted by a straight-chain, branched-chain, or cyclic alkyl group having 1 to 25 carbon atoms, or an aryl group having 6 to 25 carbon atoms. Specifically, the ester group may be a substituent having the following structural formulas, but is not limited thereto.

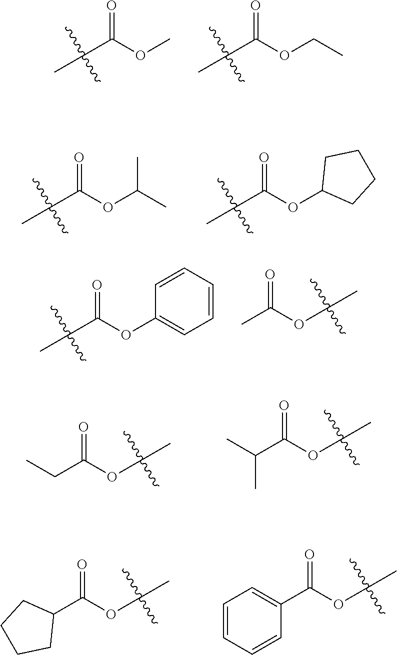

In the present disclosure, the carbon number of an imide group is not particularly limited, but is preferably 1 to 25. Specifically, the imide group may be a substituent group having the following structural formulas, but is not limited thereto.

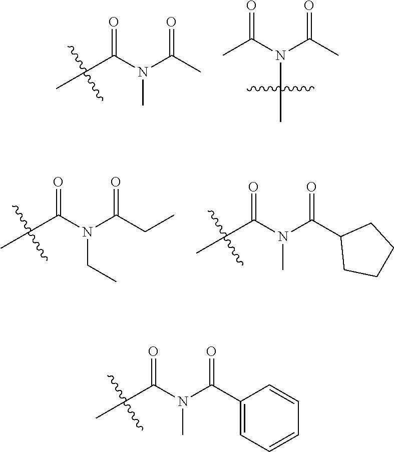

In the present disclosure, a silyl group means —Si(Z₁)(Z₂)(Z₃), wherein Z₁, Z₂ and Z₃ are each independently hydrogen, deuterium, a substituted or unsubstituted C₁₋₆₀ alkyl, a substituted or unsubstituted C₁₋₆₀ haloalkyl, a substituted or unsubstituted C₂₋₆₀ alkenyl, a substituted or unsubstituted C₂₋₆₀ haloalkenyl, or a substituted or unsubstituted C₆₋₆₀ aryl. According to one embodiment, Z₁, Z₂ and Z₃ may be each independently hydrogen, deuterium, a substituted or unsubstituted C₁₋₁₀ alkyl, a substituted or unsubstituted C₁₋₁₀ haloalkyl, or a substituted or unsubstituted C₆₋₂₀ aryl. Specific examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but are not limited thereto.

In the present disclosure, a boron group specifically includes a trimethylboron group, a triethylboron group, a t-butyldimethylboron group, a triphenylboron group, and a phenylboron group, but is not limited thereto.

In the present disclosure, examples of a halogen group include fluoro, chloro, bromo, or iodo.

In the present disclosure, the alkyl group may be straight-chain or branched-chain, and the carbon number thereof is not particularly limited, but is preferably 1 to 40. According to one embodiment, the carbon number of the alkyl group is 1 to 20. According to another embodiment, the carbon number of the alkyl group is 1 to 10. According to another embodiment, the carbon number of the alkyl group is 1 to 5. Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, 1-ethyl-propyl, 1,1-dimethylpropyl, hexyl, n-hexyl, 1-methylpentyl, 2-methylpentyl, 4-methyl-2-pentyl, 3,3-dimethylbutyl, 2-ethylbutyl, heptyl, n-heptyl, isohexyl, 1-methylhexyl, 2-methylhexyl, 3-methylhexyl, 4-methylhexyl, 5-methylhexyl, cyclopentylmethyl, cyclohexylmethyl, octyl, n-octyl, tert-octyl, 1-methylheptyl, 2-ethylhexyl, 2,4,4-trimethyl-1-pentyl, 2,4,4-trimethyl-2-pentyl, 2-propylpentyl, n-nonyl, 2,2-dimethylheptyl, and the like, but are not limited thereto.

In the present disclosure, the alkenyl group may be straight-chain or branched-chain, and the carbon number thereof is not particularly limited, but is preferably 2 to 40. According to one embodiment, the carbon number of the alkenyl group is 2 to 20. According to another embodiment, the carbon number of the alkenyl group is 2 to 10. According to still another embodiment, the carbon number of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present disclosure, the alicyclic group means a monovalent substituent derived from a saturated or unsaturated hydrocarbon ring compound that contains only carbon as a ring-forming atom, but does not have aromaticity, which is understood to encompass both monocyclic and fused polycyclic compounds. According to one embodiment, the carbon number of the alicyclic group is 3 to 60. According to another embodiment, the carbon number of the alicyclic group is 3 to 30. According to another embodiment, the carbon number of the alicyclic group is 3 to 20. Examples of the alicyclic group include a monocyclic group such as a cycloalkyl group, a bridged hydrocarbon group, a spiro hydrocarbon group, a substituent derived from hydrogenated derivatives of aromatic hydrocarbon compound.

Specifically, examples of the cycloalkyl group include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

Further, examples of the bridged hydrocarbon group include bicyclo[1.1.0]butyl, bicyclo[2.2.1]heptyl, bicyclo[4.2.0]octa-1,3,5-trienyl, adamantyl, decalinyl, and the like, but are not limited thereto.

Further, examples of the spiro hydrocarbon group include spiro[3.4]octyl, spiro[5.5]undecanyl, and the like, but are not limited thereto.

Further, a substituent derived from a hydrogenated derivative of the aromatic hydrocarbon compound means a substituent derived from a monocyclic or polycyclic aromatic hydrocarbon compound in which a part of the compound is hydrogenated. Examples of such a substituent include 1H-indenyl, 2H-indenyl, 4H-indenyl, 2,3-dihydro-1H-indenyl, 1,4-dihydronaphthalenyl, 1,2,3,4-tetrahydronaphthalenyl, 6,7,8,9-tetrahydro-5H-benzo[7]annulenyl, 6,7-dihydro-5H-benzocycloheptenyl, and the like, but are not limited thereto.

In the present disclosure, an aryl group is understood to mean a substituent derived from a monocyclic or fused polycyclic compound containing only carbon as a ring-forming atom and also having aromaticity, and the carbon number thereof is not particularly limited, but is preferably 6 to 60. According to one embodiment, the carbon number of the aryl group is 6 to 30. According to one embodiment, the carbon number of the aryl group is 6 to 20. The aryl group may be a phenyl group, a biphenylyl group, a terphenylyl group, quaterphenylyl group, or the like as the monocyclic aryl group, but is not limited thereto. The fused polycyclic aryl group includes a naphthyl group, an anthracenyl group, a phenanthryl group, a pyrenyl group, a perylenyl group, a chrysenyl group, a fluorenyl group, or the like, but is not limited thereto.

In the present disclosure, the fluorenyl group may be substituted, and two substituent groups may be linked with each other to form a spiro structure. In the case where the fluorenyl group is substituted,

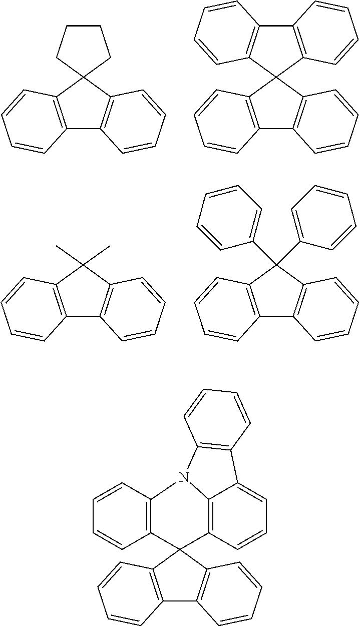

and the like can be formed. However, the structure is not limited thereto.

In the present disclosure, a heterocyclic group means a monovalent substituent derived from a monocyclic or fused polycyclic compound that further contains at least one heteroatom selected among O, N, Si, and S in addition to carbon as a ring-forming atom, and is understood to encompass both substituents with aromaticity and substituents without aromaticity. According to one embodiment, the carbon number of the heterocyclic group is 2 to 60 carbon atoms. According to another embodiment, the carbon number of the heterocyclic group is 2 to 30. According to another embodiment, the carbon number of the heterocyclic group is 2 to 20. Examples of such a heterocyclic group include a heteroaryl group, a substituent derived from a hydrogenated derivative of the heteroaromatic compound, and the like.

Specifically, the heteroaryl group means a substituent derived from a monocyclic or fused polycyclic compound which further contains at least one heteroatom selected among N, O and S in addition to carbon as a ring forming atom, and refers to a substituent having aromaticity. According to one embodiment, the carbon number of the heteroaryl group is 2 to 60. According to another embodiment, the carbon number of the heteroaryl group is 2 to 30. According to another embodiment, the carbon number of the heteroaryl group is 2 to 20. According to another embodiment, the carbon number of the heteroaryl group is 2 to 12. According to another embodiment, the carbon number of the heteroaryl group is 2 to 10. According to another embodiment, the carbon number of the heteroaryl group is 2 to 8. According to another embodiment, the carbon number of the heteroaryl group is 10 to 20. Examples of the heteroaryl group include a thiophenyl group, a furanyl group, a pyrrole group, an imidazolyl group, a thiazolyl group, an oxazolyl group, an oxadiazolyl group, a triazolyl group, a pyridinyl group, a bipyridinyl group, a pyrimidinyl group, a triazinyl group, an acridinyl group, a pyridazinyl group, a pyrazinyl group, a quinolinyl group, a quinazolinyl group, a quinoxalinyl group, a phthalazinyl group, a pyridopyrimidinyl group, a pyridopyrazinyl group, an isoquinolinyl group, an indolyl group, a carbazolyl group, a benzoxazolyl group, a benzoimidazolyl group, a benzothiazolyl group, a benzocarbazolyl group, a benzothiophenyl group, a dibenzothiophenyl group, a benzofuranyl group, a dibenzofuranyl group, a phenanthrolinyl group, an isoxazolyl group, a thiadiazolyl group, a phenothiazinyl group, and the like, but are not limited thereto.

Further, a substituent derived from a hydrogenated derivative of a heteroaromatic compound means a substituent derived from a monocyclic or polycyclic heteroaromatic compound in which a part of the unsaturated bond of the compound is hydrogenated. Examples of such substituents include 1,3-dihydroisobenzofuranyl, 2,3-dihydrobenzofuranyl, 1,3-dihydrobenzo[c]thiophenyl, 2,3-dihydro[b]thiophenyl, and the like, but are not limited thereto.

In the present disclosure, the aryl group in the aralkyl group, the aralkenyl group, the alkylaryl group, the arylamine group and the arylsilyl group is the same as the examples of the aryl group as defined above. In the present disclosure, the alkyl group in the aralkyl group, the alkylaryl group and the alkylamine group is the same as the examples of the alkyl group as defined above. In the present disclosure, the heteroaryl in the heteroarylamine can be applied to the description of the heteroaryl as defined above. In the present disclosure, the alkenyl group in the aralkenyl group is the same as the examples of the alkenyl group as defined above. In the present disclosure, the description of the aryl group as defined above may be applied except that the arylene is a divalent group. In the present disclosure, the description of the heteroaryl as defined above can be applied except that the heteroarylene is a divalent group. In the present disclosure, the description of the aryl group or cycloalkyl group as defined above can be applied except that the hydrocarbon ring is not a monovalent group but formed by combining two substituent groups. In the present disclosure, the description of the heteroaryl as defined above can be applied, except that the heterocycle is not a monovalent group but formed by combining two substituent groups.

In the present disclosure, the term “deuterated or substituted with deuterium” means that at least one of the substitutable hydrogens in a compound, a divalent linking group, or a monovalent substituent has been substituted with deuterium.

Further, the term “unsubstituted or substituted with deuterium” or “substituted or unsubstituted with deuterium” means that “mono to the maximum number of unsubstituted or substitutable hydrogens have been substituted with deuterium.” In one example, the term “phenanthryl unsubstituted or substituted with deuterium” may be understood as meaning “phenanthryl unsubstituted or substituted with 1 to 9 deuterium atoms”, considering that the maximum number of hydrogens that can be substituted with deuterium in the phenanthryl structure is 9.

Further, “deuterated structure” means to include compounds, divalent linking groups, or monovalent substituents of all structures in which at least one hydrogen is substituted with deuterium. As an example, the deuterated structure of phenyl can be understood to refer to monovalent substituents of all structures in which at least one substitutable hydrogen in the phenyl group is substituted with deuterium, as follows.

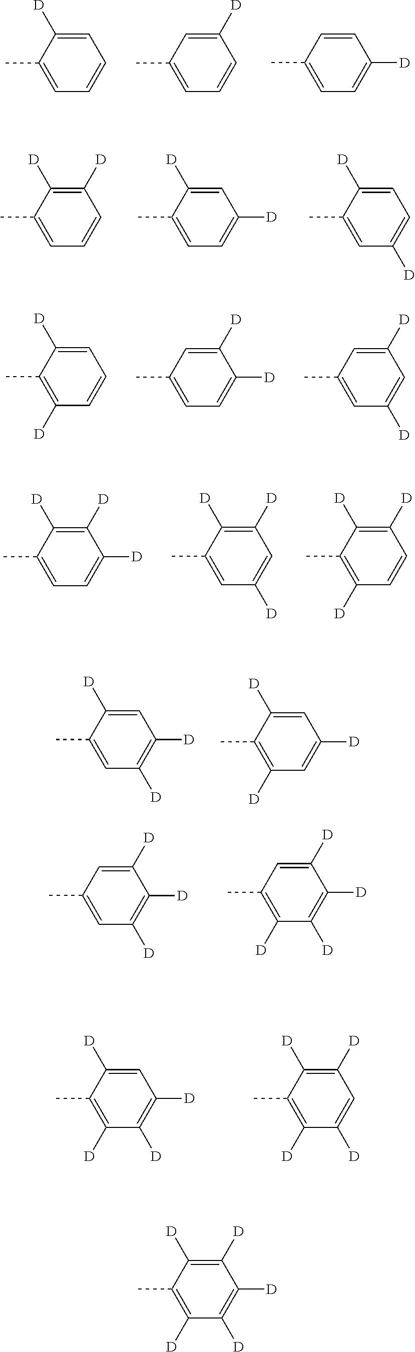

In addition, the “deuterium substitution rate” or “degree of deuteration” of a compound means that the ratio of the number of substituted deuterium atoms to the total number of hydrogen atoms (the sum of the number of hydrogen atoms substitutable with deuterium and the number of substituted deuterium atoms in a compound) that can exist in the compound is calculated as a percentage. Therefore, when the “deuterium substitution rate” or “degree of deuteration” of a compound is “K %”, it means that K % of the hydrogen atoms substitutable with deuterium in the compound are substituted with deuterium.

At this time, the “deuterium substitution rate” or “degree of deuteration” can be determined according to a commonly known method using MALDI-TOF MS (Matrix-Assisted Laser Desorption/Ionization Time-of-Flight Mass Spectrometer), a nuclear magnetic resonance spectroscopy (¹H NMR), TLC/MS (Thin-Layer Chromatography/Mass Spectrometry), GC/MS (Gas Chromatography/Mass Spectrometry), or the like. More specifically, when using MALDI-TOF MS, the “deuterium substitution rate” or “degree of deuteration” may be obtained by determining the number of substituted deuterium in the compound through MALDI-TOF MS analysis, and then calculating the ratio of the number of substituted deuterium to the total number of hydrogen atoms that can exist in the compound as a percentage.

Provided herein is an organic light emitting device comprising: an anode; a cathode which is provided opposite to the anode; and a light emitting layer which is interposed between the anode and the cathode, wherein the light emitting layer includes the first compound represented by Chemical Formula 1, and the second compound represented by Chemical Formula 2.

Further, the terms “tritiated structure”, “tritium substitution rate”, or “degree of tritium” may be applied to the deuterium-related descriptions described above, except that tritium is substituted for deuterium.

The organic light emitting device according to the present disclosure simultaneously contains two types of compounds having a specific structure as host materials in the light emitting layer, and thus can improve efficiency, driving voltage, and/or lifetime characteristics in the organic light emitting device.

Hereinafter, the present disclosure will be described in detail for each configuration.

### The Composition for an Organic Light Emitting Device

In one embodiment of the present disclosure, a composition for an organic light emitting device is provided, comprising the first compound represented by Chemical Formula 1 and the second compound represented by Chemical Formula 2. The first and second compounds can serve as hosts within the light emitting layer of an organic light emitting device.

Hereinafter, the first compound and the second compound will be sequentially described.

### (The First Compound)

The first compound is represented by Chemical Formula 1. Specifically, the first compound can efficiently transport holes to the dopant material, and thus, together with the second compound, which has excellent electron transport capabilities, can increase the probability of hole and electron recombination within the light emitting layer.

Meanwhile, L₁ and L₂ may be each independently a single bond, or a substituted or unsubstituted C₆₋₆₀ arylene.

For example, L₁ and L₂ may be each independently a single bond, or phenylene substituted or unsubstituted with deuterium.

Further, Ar₁ may be unsubstituted or substituted C₆₋₂₀ aryl.

For example, Ar₁ may be phenyl, biphenylyl, terphenylyl, or quaterphenylyl, wherein, Ar₁ may be unsubstituted, or substituted with one or more substituents selected from the group consisting of deuterium; tritium; C₁₋₁₀ alkyl substituted or unsubstituted with deuterium or tritium; and C₆₋₂₀ aryl substituted or unsubstituted with deuterium or tritium.

Further, Ar₂ may be substituted or unsubstituted C₆₋₂₀ aryl, or substituted or unsubstituted C₂₋₂₀ heteroaryl containing at least one heteroatom selected among N, O and, provided that the case where Ar₂ is a monocyclic containing one or more N atoms is excluded. Wherein, the monocyclic ring containing one or more N atoms is a compound composed of one ring containing one or more nitrogen atoms in addition to carbon atom as a ring constituent atom, and refers to an imidazolyl group, a triazolyl group, a pyridinyl group, a pyrimidinyl group, a triazinyl group, and the like, but are not limited thereto.

More specifically, Ar₂ may be a substituted or unsubstituted C₆₋₂₀ aryl, or a substituted or unsubstituted C₂₋₂₀ heteroaryl containing at least one heteroatom selected among N, O and S.

For example, Ar₂ may be phenyl, biphenylyl, terphenylyl, quaterphenylyl, dibenzofuranyl, dibenzothiophenyl, phenanthryl, triphenylenyl, benzonaphthofuranyl, benzonaphthothiophenyl, carbazolyl, or 9-phenylcarbazolyl,
wherein, Ar₂ may be unsubstituted, or substituted with one or more substituents selected from the group consisting of deuterium; tritium; C₁₋₁₀ alkyl substituted or unsubstituted with deuterium or tritium; and C₆₋₂₀ aryl substituted or unsubstituted with deuterium or tritium.

More specifically for example, Ar₂ may be phenyl, biphenylyl, terphenylyl, quaterphenylyl, dibenzofuranyl, dibenzothiophenyl, benzonaphthofuranyl, benzonaphthothiophenyl, carbazolyl, or 9-phenylcarbazolyl,
wherein, Ar₂ may be unsubstituted, or substituted with one or more substituents selected from the group consisting of deuterium; tritium; methyl substituted or unsubstituted with deuterium or tritium; and phenyl substituted or unsubstituted with deuterium or tritium.

Further, R₁, R₂ and R₃ are all hydrogen; or

R₁, R₂ and R₃ are all deuterium; or

R₁ and R₃ are deuterium, R₂ is hydrogen.

Wherein, a means the number of R₁, and when a is 2 or more, two or more R₁ may be the same as or different from each other. Specifically, a is 0, 1, 2, 3, or 4.

Further, wherein, b means the number of R₂, and when b is 2 or more, two or more R₂ may be the same as or different from each other. Specifically, b is 0, 1, or 2.

Further, wherein, c means the number of R₃, and when c is 2 or more, two or more R₃ may be the same as or different from each other. Specifically, c is 0, 1, 2, 3, or 4.

Further, a+b+c is 0, 8, or 10.

Further, the first compound may not contain deuterium or tritium, or may contain one or more deuterium or tritium atoms.

When the first compound contains deuterium or tritium, the deuterium/tritium substitution rate of the first compound may be from 1% to 100%. Specifically, the deuterium/tritium substitution rate of the first compound may be 5% or more, 10% or more, 20% or more, 30% or more, 40% or more, 50% or more, 60% or more, 70% or more, 75% or more, 80% or more, or 90% or more, and 100% or less.

In one embodiment, the first compound may not contain deuterium or tritium, or may contain 1 to 50 deuterium or tritium atoms. More specifically, the first compound may not contain deuterium or tritium atom, or may contain 1 or more, 2 or more, 3 or more, 4 or more, 5 or more, 6 or more, 7 or more, 8 or more, or 9 or more, and 50 or less, 40 or less, 30 or less, 28 or less, 26 or less, 24 or less, 22 or less, 20 or less, 18 or less, 16 or less, 14 or less, 13 or less, 12 or less, 11 or less, or 10 or less deuterium or tritium atoms.

Meanwhile, representative examples of the first compound are as follows:

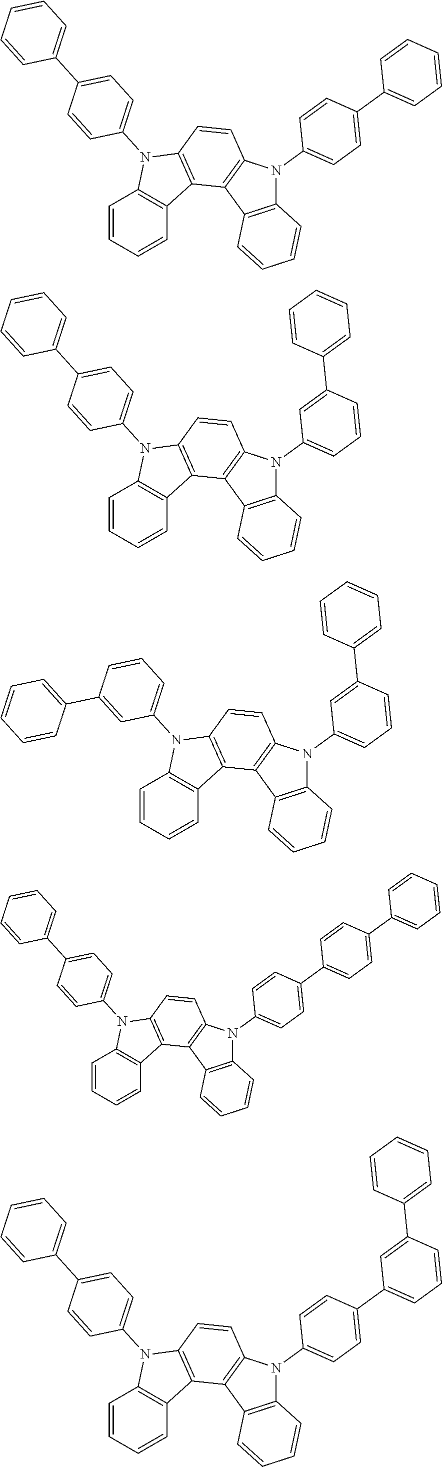

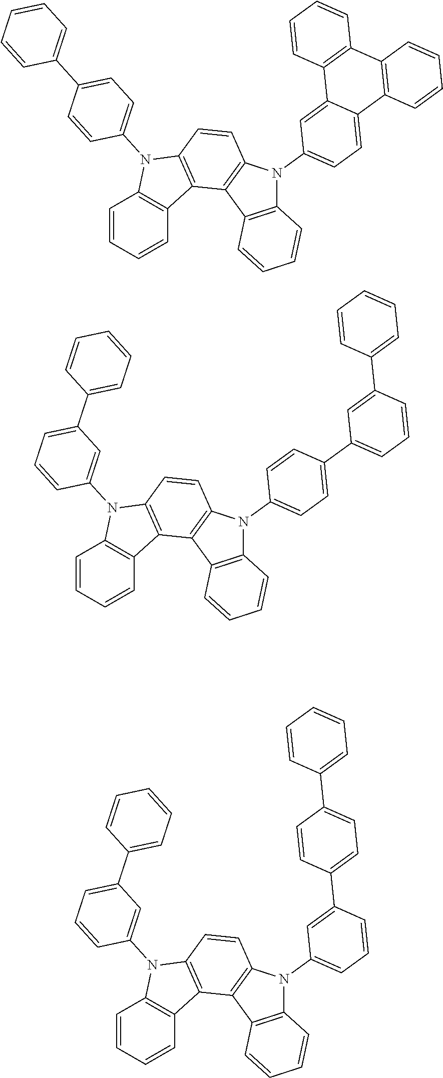 [SMILES: c1ccc(-c2ccc(-n3c4ccccc4c4c5c6ccccc6n(-c6ccc7c8ccccc8c8ccccc8c7c6)c5ccc43)cc2)cc1 ; c1ccc(-c2cccc(-c3ccc(-n4c5ccccc5c5c6c7ccccc7n(-c7cccc(-c8ccccc8)c7)c6ccc54)cc3)c2)cc1 ; c1ccc(-c2ccc(-c3cccc(-n4c5ccccc5c5c6c7ccccc7n(-c7cccc(-c8ccccc8)c7)c6ccc54)c3)cc2)cc1]

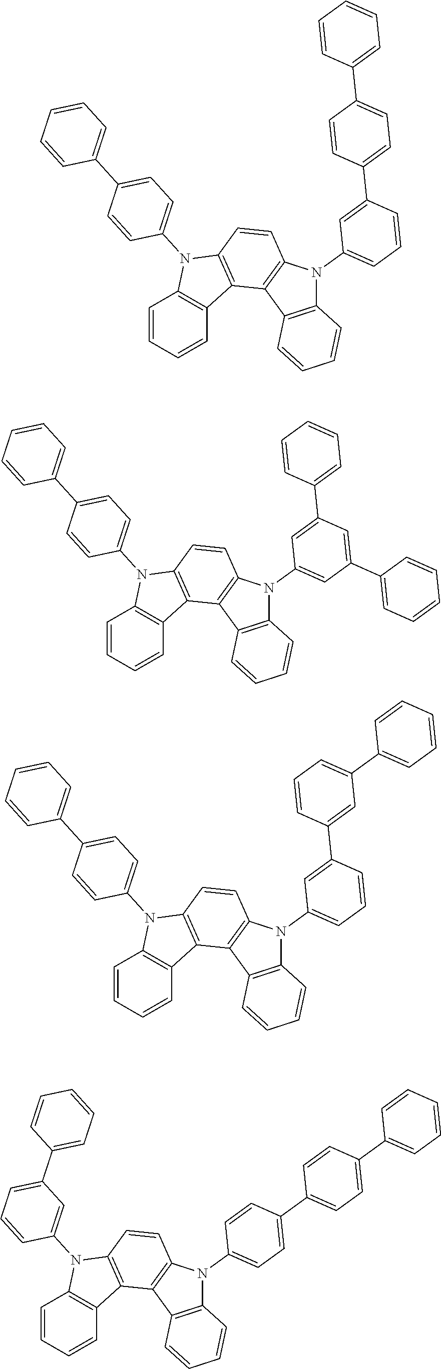 [SMILES: c1ccc(-c2ccc(-c3cccc(-n4c5ccccc5c5c6c7ccccc7n(-c7ccc(-c8ccccc8)cc7)c6ccc54)c3)cc2)cc1 ; c1ccc(-c2ccc(-n3c4ccccc4c4c5c6ccccc6n(-c6cc(-c7ccccc7)cc(-c7ccccc7)c6)c5ccc43)cc2)cc1 ; c1ccc(-c2ccc(-n3c4ccccc4c4c5c6ccccc6n(-c6cccc(-c7cccc(-c8ccccc8)c7)c6)c5ccc43)cc2)cc1 ; c1ccc(-c2ccc(-c3ccc(-n4c5ccccc5c5c6c7ccccc7n(-c7cccc(-c8ccccc8)c7)c6ccc54)cc3)cc2)cc1]

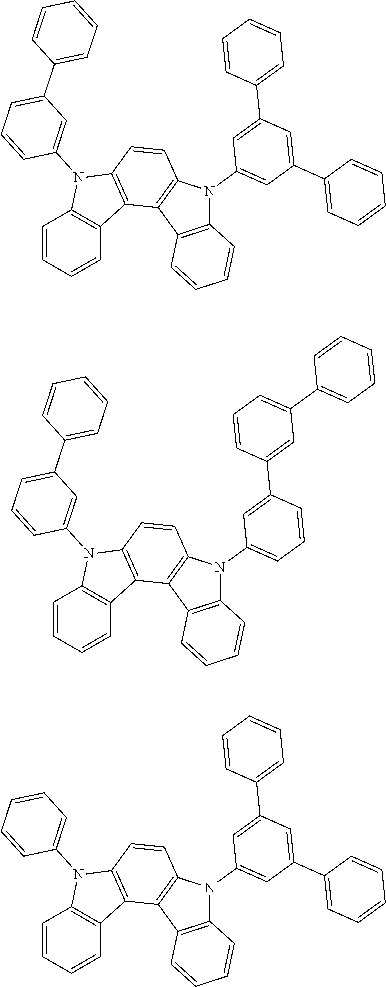 [SMILES: c1ccc(-c2cccc(-n3c4ccccc4c4c5c6ccccc6n(-c6cc(-c7ccccc7)cc(-c7ccccc7)c6)c5ccc43)c2)cc1 ; c1ccc(-c2cccc(-c3cccc(-n4c5ccccc5c5c6c7ccccc7n(-c7cccc(-c8ccccc8)c7)c6ccc54)c3)c2)cc1 ; c1ccc(-c2cc(-c3ccccc3)cc(-n3c4ccccc4c4c5c6ccccc6n(-c6ccccc6)c5ccc43)c2)cc1]

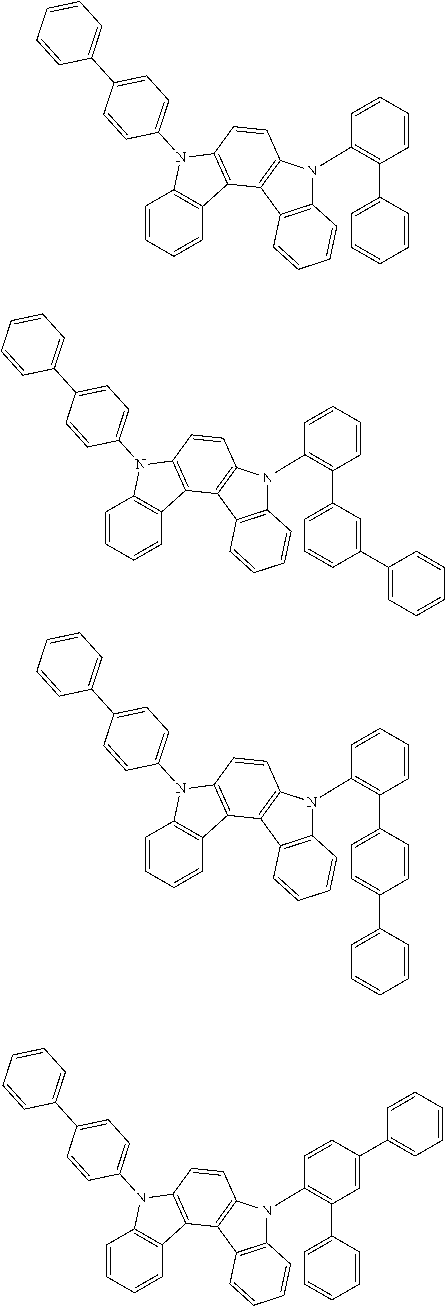 [SMILES: c1ccc(-c2ccc(-n3c4ccccc4c4c5c6ccccc6n(-c6ccccc6-c6ccccc6)c5ccc43)cc2)cc1 ; c1ccc(-c2ccc(-n3c4ccccc4c4c5c6ccccc6n(-c6ccccc6-c6cccc(-c7ccccc7)c6)c5ccc43)cc2)cc1 ; c1ccc(-c2ccc(-c3ccccc3-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6ccc(-c7ccccc7)cc6-c6ccccc6)c5ccc43)cc2)cc1]

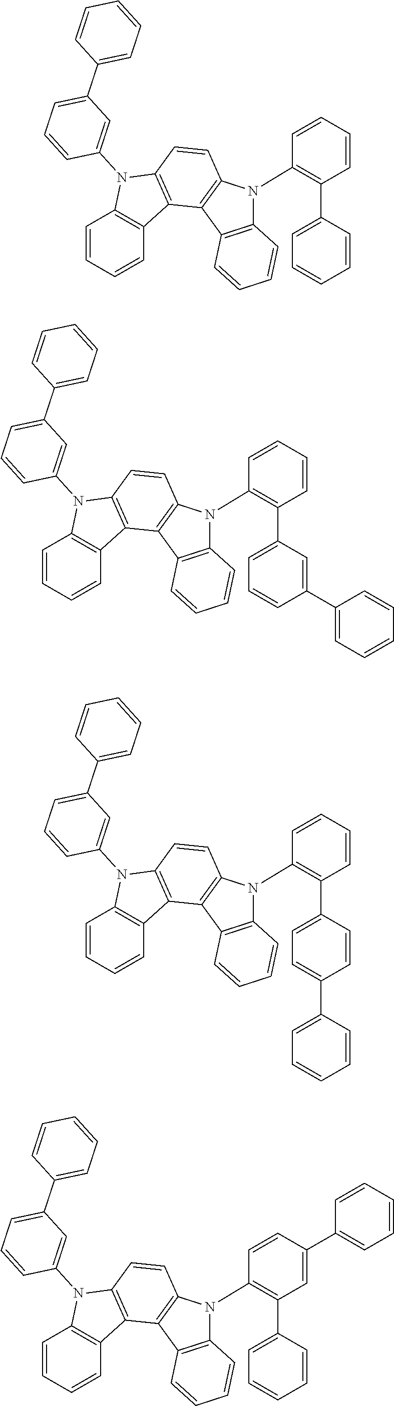 [SMILES: c1ccc(-c2cccc(-n3c4ccccc4c4c5c6ccccc6n(-c6ccccc6-c6ccccc6)c5ccc43)c2)cc1 ; c1ccc(-c2cccc(-c3ccccc3-n3c4ccccc4c4c5c6ccccc6n(-c6cccc(-c7ccccc7)c6)c5ccc43)c2)cc1 ; c1ccc(-c2ccc(-c3ccccc3-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6ccc(-c7ccccc7)cc6-c6ccccc6)c5ccc43)c2)cc1]

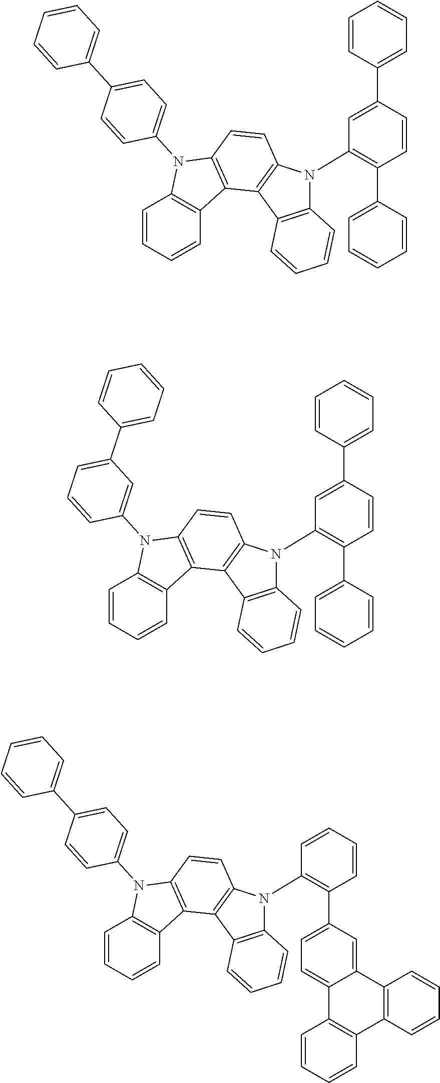 [SMILES: c1ccc(-c2ccc(-n3c4ccccc4c4c5c6ccccc6n(-c6cc(-c7ccccc7)ccc6-c6ccccc6)c5ccc43)cc2)cc1 ; c1ccc(-c2cccc(-n3c4ccccc4c4c5c6ccccc6n(-c6cc(-c7ccccc7)ccc6-c6ccccc6)c5ccc43)c2)cc1 ; c1ccc(-c2ccc(-n3c4ccccc4c4c5c6ccccc6n(-c6ccccc6-c6ccc7c8ccccc8c8ccccc8c7c6)c5ccc43)cc2)cc1]

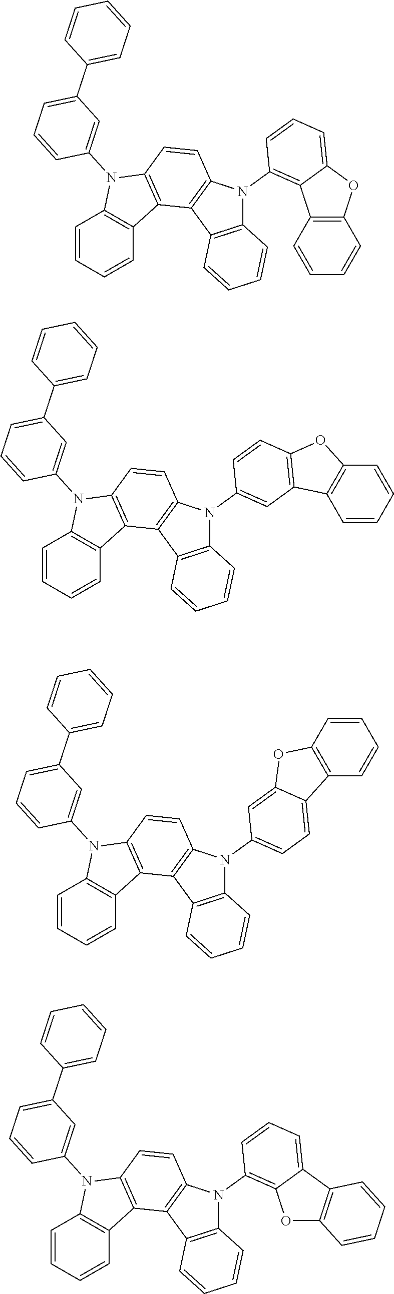 [SMILES: c1ccc(-c2cccc(-n3c4ccccc4c4c5c6ccccc6n(-c6cccc7oc8ccccc8c67)c5ccc43)c2)cc1 ; c1ccc(-c2cccc(-n3c4ccccc4c4c5c6ccccc6n(-c6ccc7oc8ccccc8c7c6)c5ccc43)c2)cc1 ; c1ccc(-c2cccc(-n3c4ccccc4c4c5c6ccccc6n(-c6ccc7c(c6)oc6ccccc67)c5ccc43)c2)cc1 ; c1ccc(-c2cccc(-n3c4ccccc4c4c5c6ccccc6n(-c6cccc7c6oc6ccccc67)c5ccc43)c2)cc1]

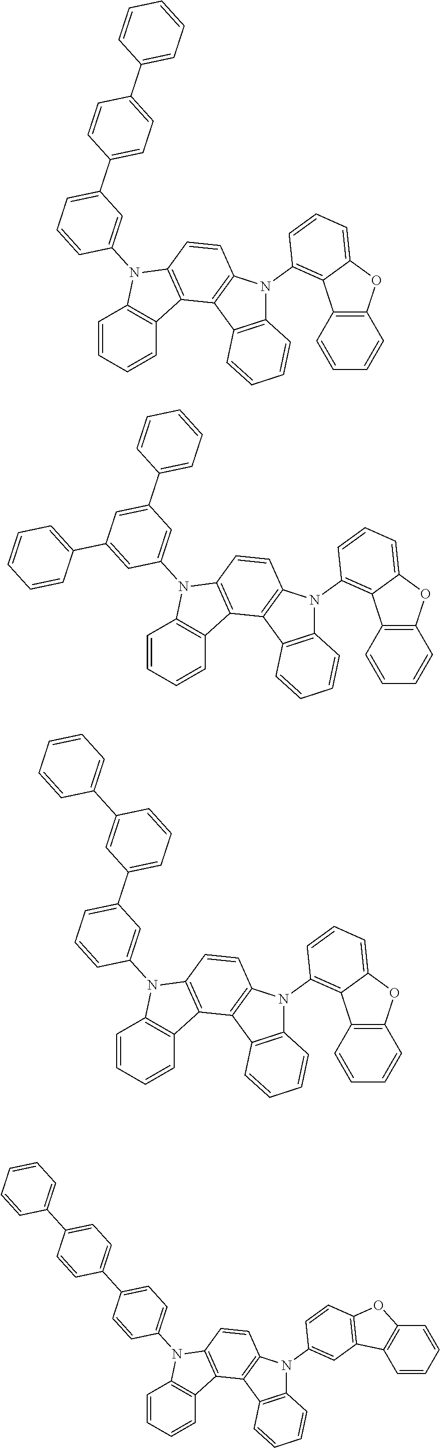 [SMILES: c1ccc(-c2ccc(-c3cccc(-n4c5ccccc5c5c6c7ccccc7n(-c7cccc8oc9ccccc9c78)c6ccc54)c3)cc2)cc1 ; c1ccc(-c2cc(-c3ccccc3)cc(-n3c4ccccc4c4c5c6ccccc6n(-c6cccc7oc8ccccc8c67)c5ccc43)c2)cc1 ; c1ccc(-c2cccc(-c3cccc(-n4c5ccccc5c5c6c7ccccc7n(-c7cccc8oc9ccccc9c78)c6ccc54)c3)c2)cc1 ; c1ccc(-c2ccc(-c3ccc(-n4c5ccccc5c5c6c7ccccc7n(-c7ccc8oc9ccccc9c8c7)c6ccc54)cc3)cc2)cc1]

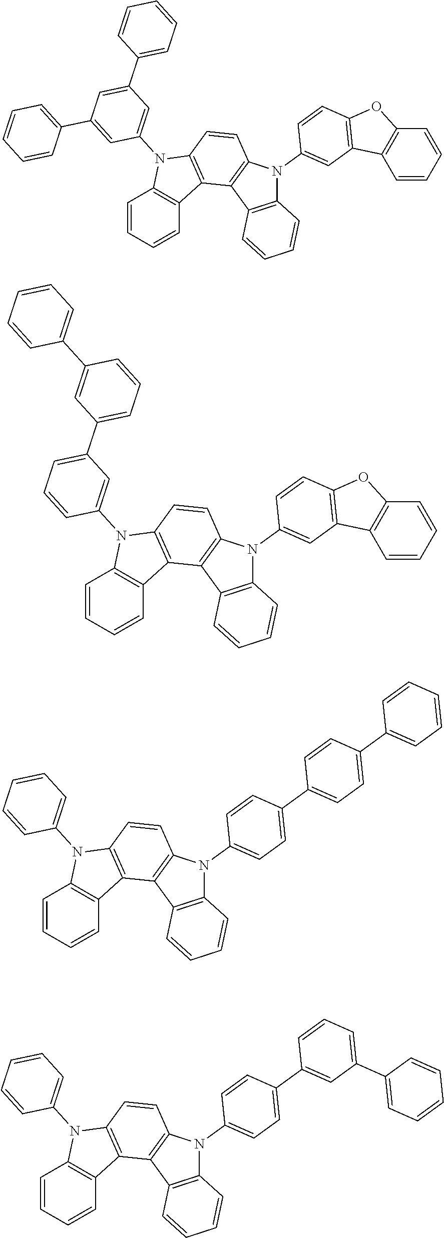 [SMILES: c1ccc(-c2cc(-c3ccccc3)cc(-n3c4ccccc4c4c5c6ccccc6n(-c6ccc7oc8ccccc8c7c6)c5ccc43)c2)cc1 ; c1ccc(-c2cccc(-c3cccc(-n4c5ccccc5c5c6c7ccccc7n(-c7ccc8oc9ccccc9c8c7)c6ccc54)c3)c2)cc1 ; c1ccc(-c2ccc(-c3ccc(-n4c5ccccc5c5c6c7ccccc7n(-c7ccccc7)c6ccc54)cc3)cc2)cc1 ; c1ccc(-c2cccc(-c3ccc(-n4c5ccccc5c5c6c7ccccc7n(-c7ccccc7)c6ccc54)cc3)c2)cc1]

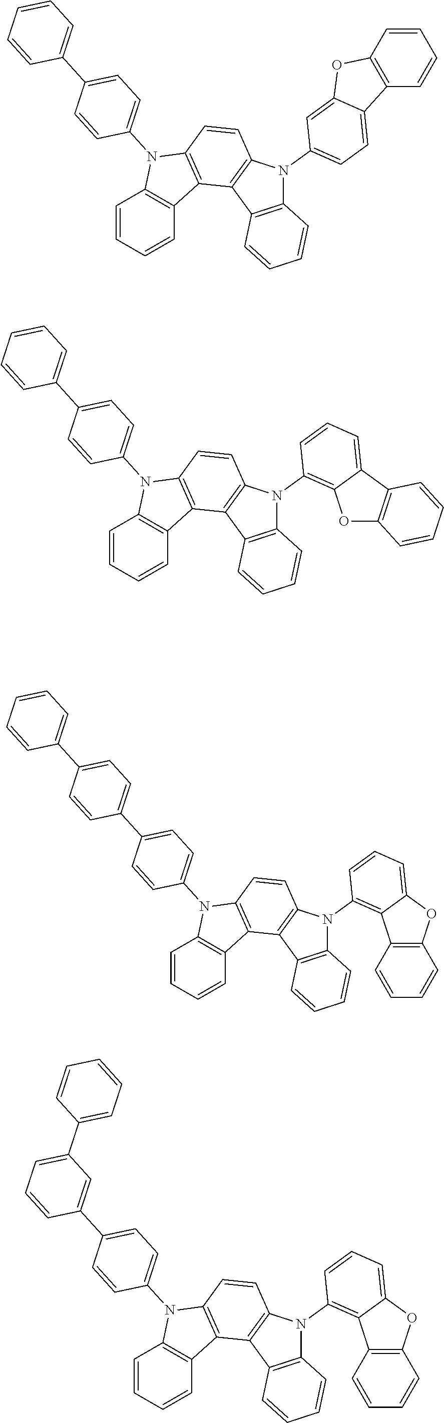 [SMILES: c1ccc(-c2ccc(-n3c4ccccc4c4c5c6ccccc6n(-c6ccc7c(c6)oc6ccccc67)c5ccc43)cc2)cc1 ; c1ccc(-c2ccc(-n3c4ccccc4c4c5c6ccccc6n(-c6cccc7c6oc6ccccc67)c5ccc43)cc2)cc1 ; c1ccc(-c2ccc(-c3ccc(-n4c5ccccc5c5c6c7ccccc7n(-c7cccc8oc9ccccc9c78)c6ccc54)cc3)cc2)cc1 ; c1ccc(-c2cccc(-c3ccc(-n4c5ccccc5c5c6c7ccccc7n(-c7cccc8oc9ccccc9c78)c6ccc54)cc3)c2)cc1]

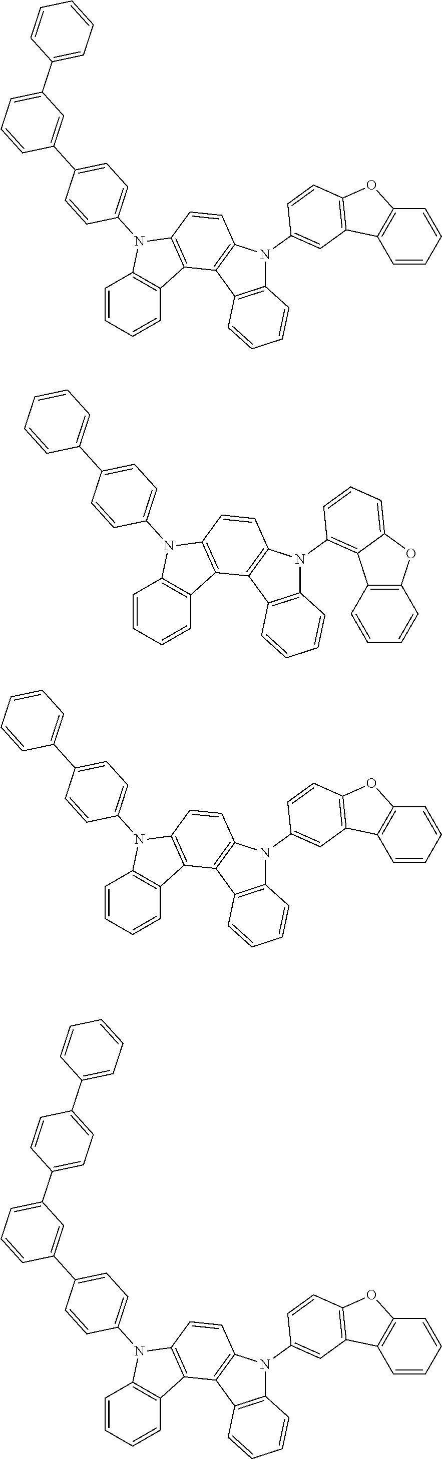 [SMILES: c1ccc(-c2cccc(-c3ccc(-n4c5ccccc5c5c6c7ccccc7n(-c7ccc8oc9ccccc9c8c7)c6ccc54)cc3)c2)cc1 ; c1ccc(-c2ccc(-n3c4ccccc4c4c5c6ccccc6n(-c6cccc7oc8ccccc8c67)c5ccc43)cc2)cc1 ; c1ccc(-c2ccc(-n3c4ccccc4c4c5c6ccccc6n(-c6ccc7oc8ccccc8c7c6)c5ccc43)cc2)cc1 ; c1ccc(-c2ccc(-c3cccc(-c4ccc(-n5c6ccccc6c6c7c8ccccc8n(-c8ccc9oc%10ccccc%10c9c8)c7ccc65)cc4)c3)cc2)cc1]

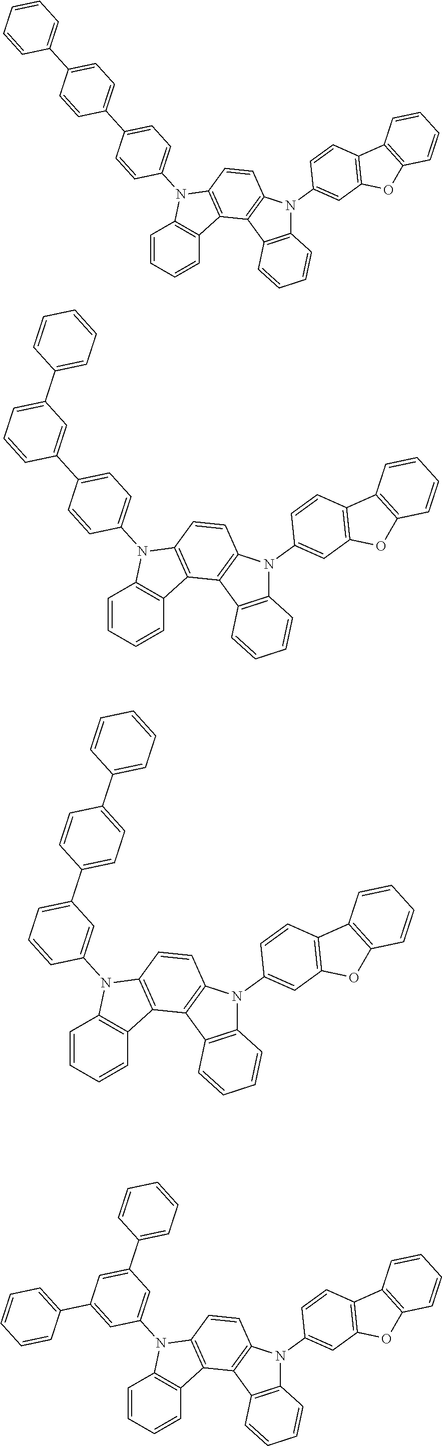 [SMILES: c1ccc(-c2ccc(-c3ccc(-n4c5ccccc5c5c6c7ccccc7n(-c7ccc8c(c7)oc7ccccc78)c6ccc54)cc3)cc2)cc1 ; c1ccc(-c2cccc(-c3ccc(-n4c5ccccc5c5c6c7ccccc7n(-c7ccc8c(c7)oc7ccccc78)c6ccc54)cc3)c2)cc1 ; c1ccc(-c2ccc(-c3cccc(-n4c5ccccc5c5c6c7ccccc7n(-c7ccc8c(c7)oc7ccccc78)c6ccc54)c3)cc2)cc1 ; c1ccc(-c2cc(-c3ccccc3)cc(-n3c4ccccc4c4c5c6ccccc6n(-c6ccc7c(c6)oc6ccccc67)c5ccc43)c2)cc1]

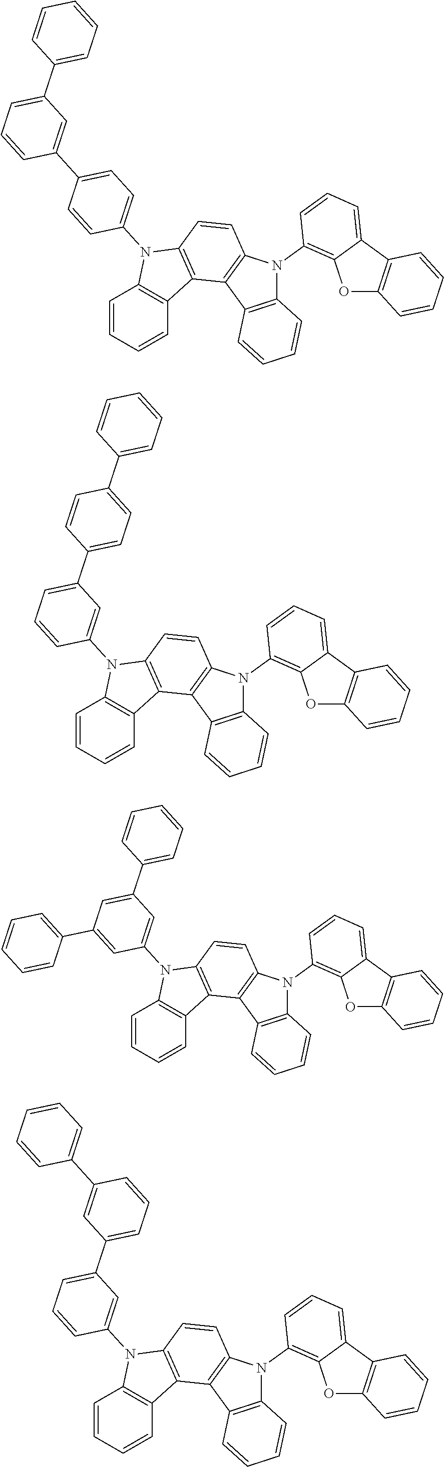

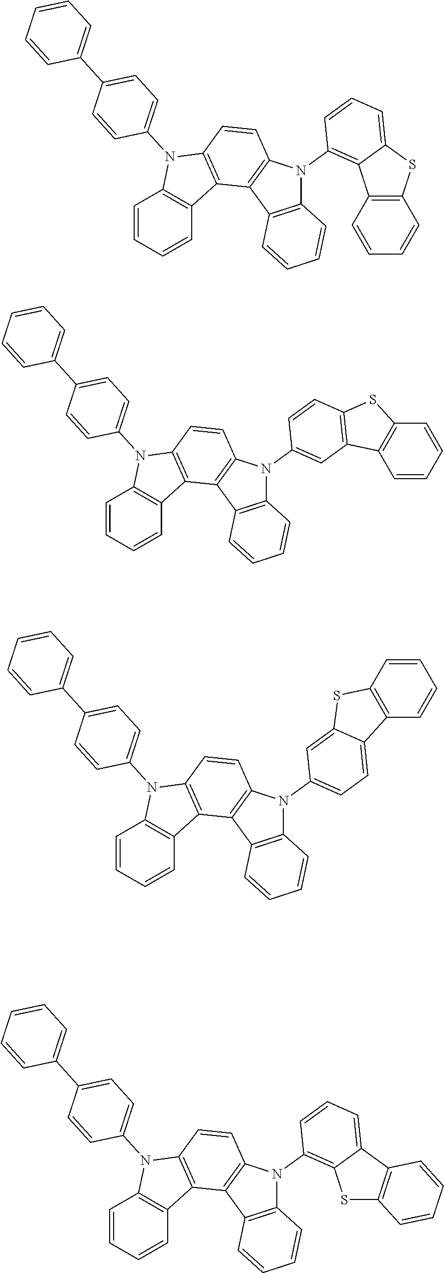 [SMILES: c1ccc(-c2ccc(-n3c4ccccc4c4c5c6ccccc6n(-c6cccc7sc8ccccc8c67)c5ccc43)cc2)cc1 ; c1ccc(-c2ccc(-n3c4ccccc4c4c5c6ccccc6n(-c6ccc7sc8ccccc8c7c6)c5ccc43)cc2)cc1 ; c1ccc(-c2ccc(-n3c4ccccc4c4c5c6ccccc6n(-c6ccc7c(c6)sc6ccccc67)c5ccc43)cc2)cc1 ; c1ccc(-c2ccc(-n3c4ccccc4c4c5c6ccccc6n(-c6cccc7c6sc6ccccc67)c5ccc43)cc2)cc1]

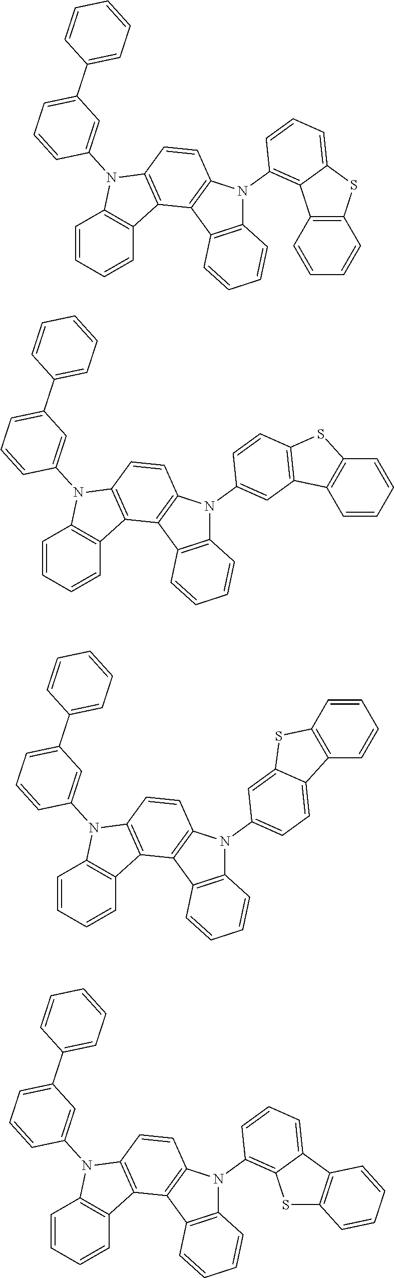 [SMILES: c1ccc(-c2cccc(-n3c4ccccc4c4c5c6ccccc6n(-c6cccc7sc8ccccc8c67)c5ccc43)c2)cc1 ; c1ccc(-c2cccc(-n3c4ccccc4c4c5c6ccccc6n(-c6ccc7sc8ccccc8c7c6)c5ccc43)c2)cc1 ; c1ccc(-c2cccc(-n3c4ccccc4c4c5c6ccccc6n(-c6ccc7c(c6)sc6ccccc67)c5ccc43)c2)cc1 ; c1ccc(-c2cccc(-n3c4ccccc4c4c5c6ccccc6n(-c6cccc7c6sc6ccccc67)c5ccc43)c2)cc1]

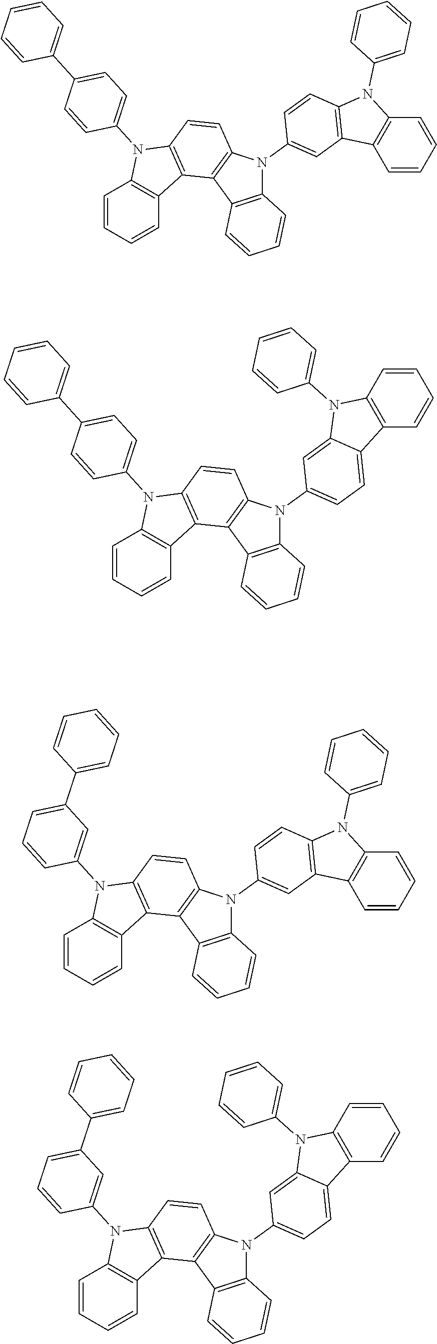 [SMILES: c1ccc(-c2ccc(-n3c4ccccc4c4c5c6ccccc6n(-c6ccc7c(c6)c6ccccc6n7-c6ccccc6)c5ccc43)cc2)cc1 ; c1ccc(-c2ccc(-n3c4ccccc4c4c5c6ccccc6n(-c6ccc7c8ccccc8n(-c8ccccc8)c7c6)c5ccc43)cc2)cc1 ; c1ccc(-c2cccc(-n3c4ccccc4c4c5c6ccccc6n(-c6ccc7c(c6)c6ccccc6n7-c6ccccc6)c5ccc43)c2)cc1 ; c1ccc(-c2cccc(-n3c4ccccc4c4c5c6ccccc6n(-c6ccc7c8ccccc8n(-c8ccccc8)c7c6)c5ccc43)c2)cc1]

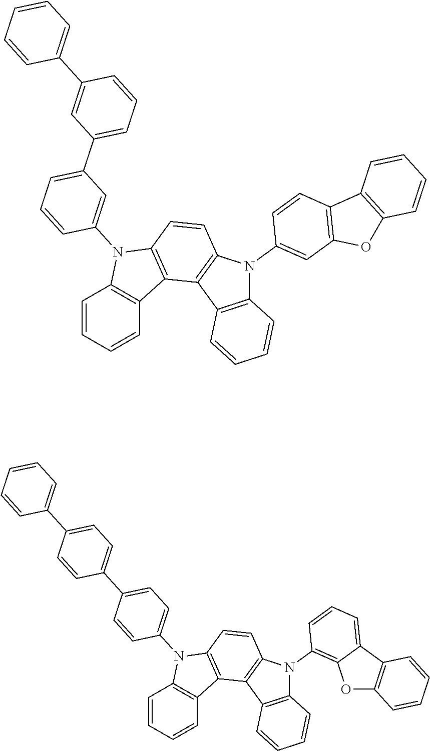 [SMILES: c1ccc(-c2cccc(-c3cccc(-n4c5ccccc5c5c6c7ccccc7n(-c7ccc8c(c7)oc7ccccc78)c6ccc54)c3)c2)cc1 ; c1ccc(-c2ccc(-c3ccc(-n4c5ccccc5c5c6c7ccccc7n(-c7cccc8c7oc7ccccc78)c6ccc54)cc3)cc2)cc1]

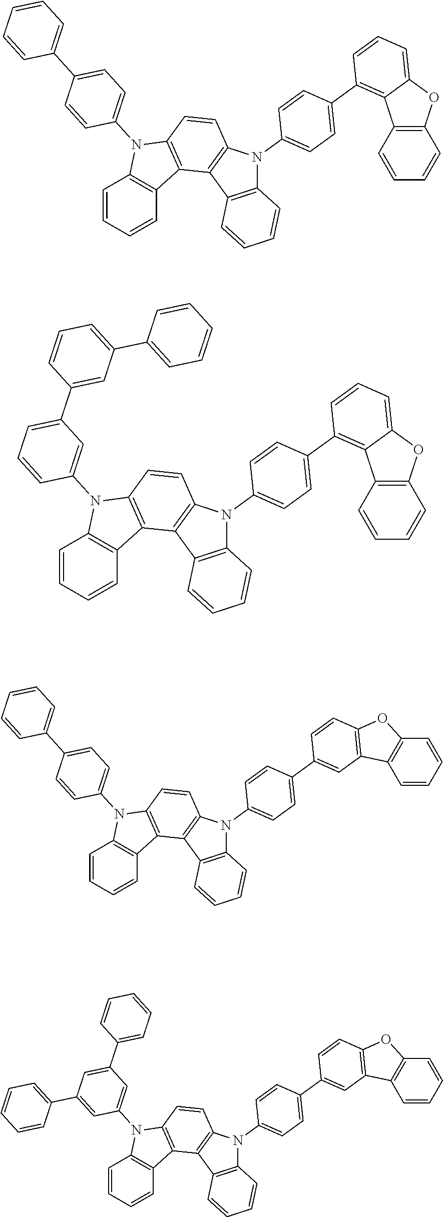 [SMILES: c1ccc(-c2ccc(-n3c4ccccc4c4c5c6ccccc6n(-c6ccc(-c7cccc8oc9ccccc9c78)cc6)c5ccc43)cc2)cc1 ; c1ccc(-c2cccc(-c3cccc(-n4c5ccccc5c5c6c7ccccc7n(-c7ccc(-c8cccc9oc%10ccccc%10c89)cc7)c6ccc54)c3)c2)cc1 ; c1ccc(-c2ccc(-n3c4ccccc4c4c5c6ccccc6n(-c6ccc(-c7ccc8oc9ccccc9c8c7)cc6)c5ccc43)cc2)cc1 ; c1ccc(-c2cc(-c3ccccc3)cc(-n3c4ccccc4c4c5c6ccccc6n(-c6ccc(-c7ccc8oc9ccccc9c8c7)cc6)c5ccc43)c2)cc1]

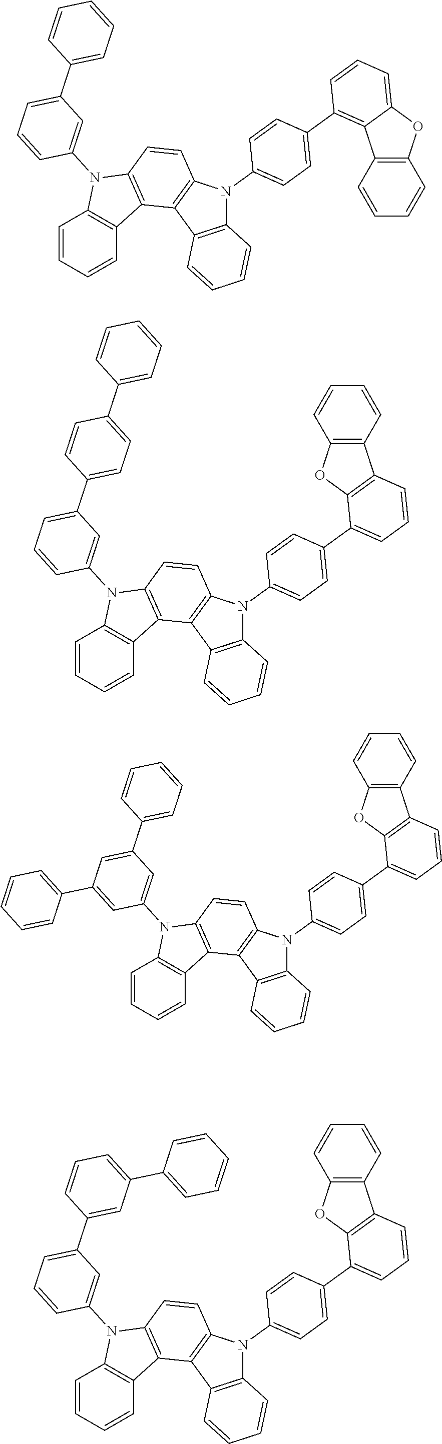 [SMILES: c1ccc(-c2cccc(-n3c4ccccc4c4c5c6ccccc6n(-c6ccc(-c7cccc8oc9ccccc9c78)cc6)c5ccc43)c2)cc1 ; c1ccc(-c2ccc(-c3cccc(-n4c5ccccc5c5c6c7ccccc7n(-c7ccc(-c8cccc9c8oc8ccccc89)cc7)c6ccc54)c3)cc2)cc1 ; c1ccc(-c2cc(-c3ccccc3)cc(-n3c4ccccc4c4c5c6ccccc6n(-c6ccc(-c7cccc8c7oc7ccccc78)cc6)c5ccc43)c2)cc1 ; c1ccc(-c2cccc(-c3cccc(-n4c5ccccc5c5c6c7ccccc7n(-c7ccc(-c8cccc9c8oc8ccccc89)cc7)c6ccc54)c3)c2)cc1]

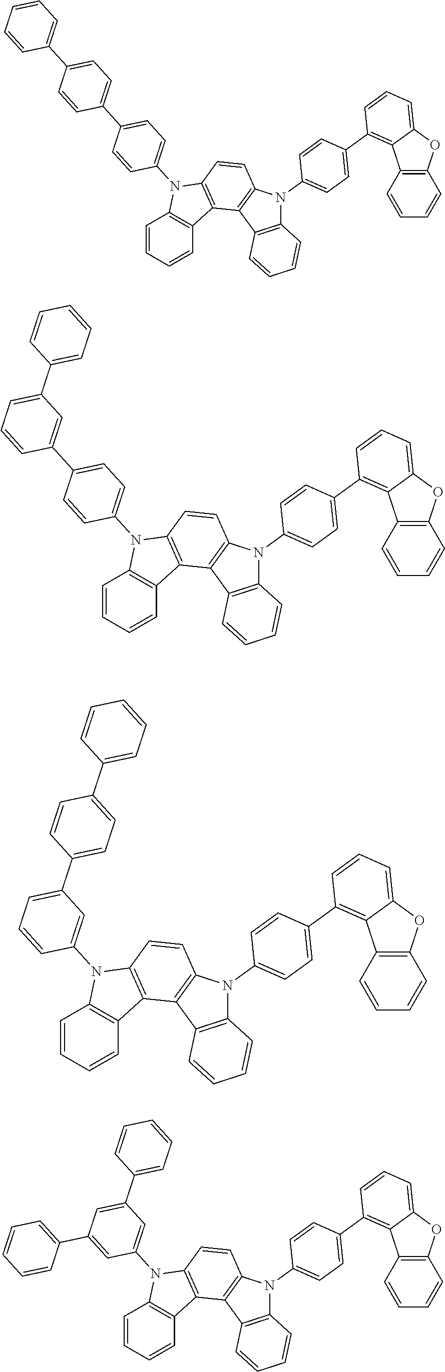 [SMILES: c1ccc(-c2ccc(-c3ccc(-n4c5ccccc5c5c6c7ccccc7n(-c7ccc(-c8cccc9oc%10ccccc%10c89)cc7)c6ccc54)cc3)cc2)cc1 ; c1ccc(-c2cccc(-c3ccc(-n4c5ccccc5c5c6c7ccccc7n(-c7ccc(-c8cccc9oc%10ccccc%10c89)cc7)c6ccc54)cc3)c2)cc1 ; c1ccc(-c2ccc(-c3cccc(-n4c5ccccc5c5c6c7ccccc7n(-c7ccc(-c8cccc9oc%10ccccc%10c89)cc7)c6ccc54)c3)cc2)cc1 ; c1ccc(-c2cc(-c3ccccc3)cc(-n3c4ccccc4c4c5c6ccccc6n(-c6ccc(-c7cccc8oc9ccccc9c78)cc6)c5ccc43)c2)cc1]

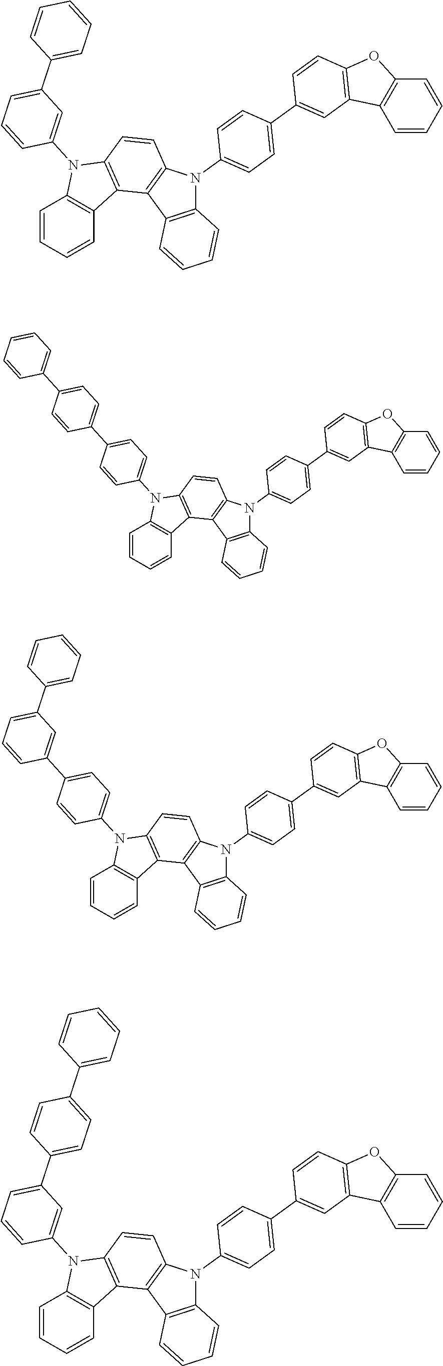 [SMILES: c1ccc(-c2cccc(-n3c4ccccc4c4c5c6ccccc6n(-c6ccc(-c7ccc8oc9ccccc9c8c7)cc6)c5ccc43)c2)cc1 ; c1ccc(-c2ccc(-c3ccc(-n4c5ccccc5c5c6c7ccccc7n(-c7ccc(-c8ccc9oc%10ccccc%10c9c8)cc7)c6ccc54)cc3)cc2)cc1 ; c1ccc(-c2cccc(-c3ccc(-n4c5ccccc5c5c6c7ccccc7n(-c7ccc(-c8ccc9oc%10ccccc%10c9c8)cc7)c6ccc54)cc3)c2)cc1 ; c1ccc(-c2ccc(-c3cccc(-n4c5ccccc5c5c6c7ccccc7n(-c7ccc(-c8ccc9oc%10ccccc%10c9c8)cc7)c6ccc54)c3)cc2)cc1]

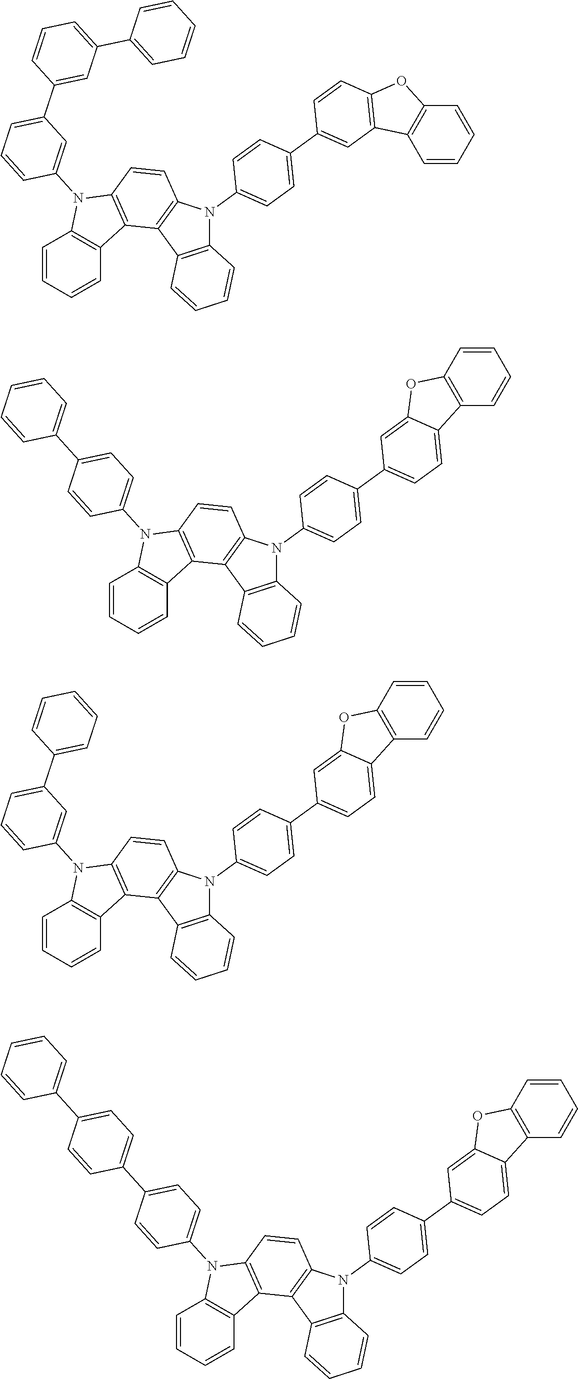 [SMILES: c1ccc(-c2cccc(-c3cccc(-n4c5ccccc5c5c6c7ccccc7n(-c7ccc(-c8ccc9oc%10ccccc%10c9c8)cc7)c6ccc54)c3)c2)cc1 ; c1ccc(-c2ccc(-n3c4ccccc4c4c5c6ccccc6n(-c6ccc(-c7ccc8c(c7)oc7ccccc78)cc6)c5ccc43)cc2)cc1 ; c1ccc(-c2cccc(-n3c4ccccc4c4c5c6ccccc6n(-c6ccc(-c7ccc8c(c7)oc7ccccc78)cc6)c5ccc43)c2)cc1 ; c1ccc(-c2ccc(-c3ccc(-n4c5ccccc5c5c6c7ccccc7n(-c7ccc(-c8ccc9c(c8)oc8ccccc89)cc7)c6ccc54)cc3)cc2)cc1]

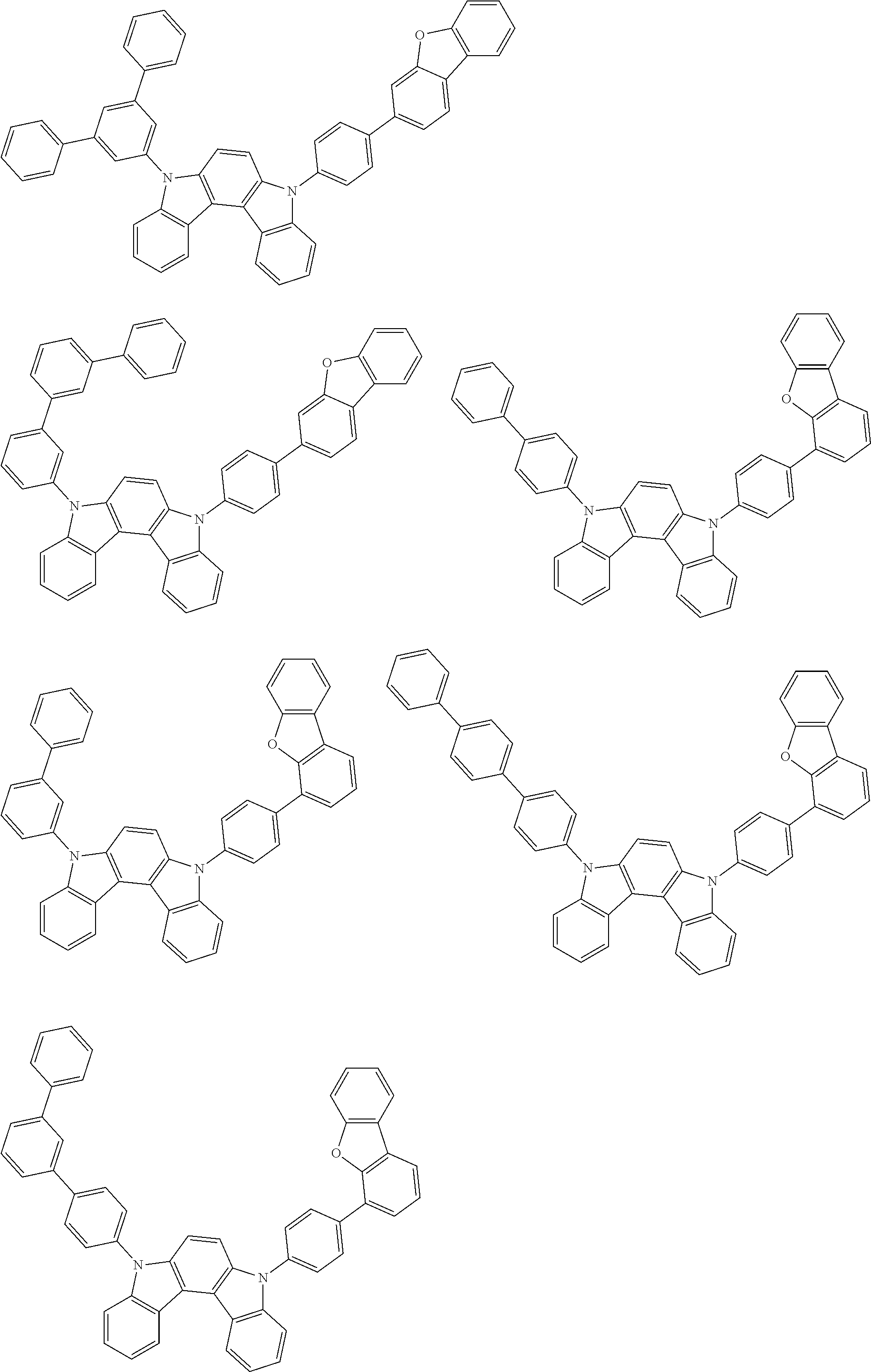

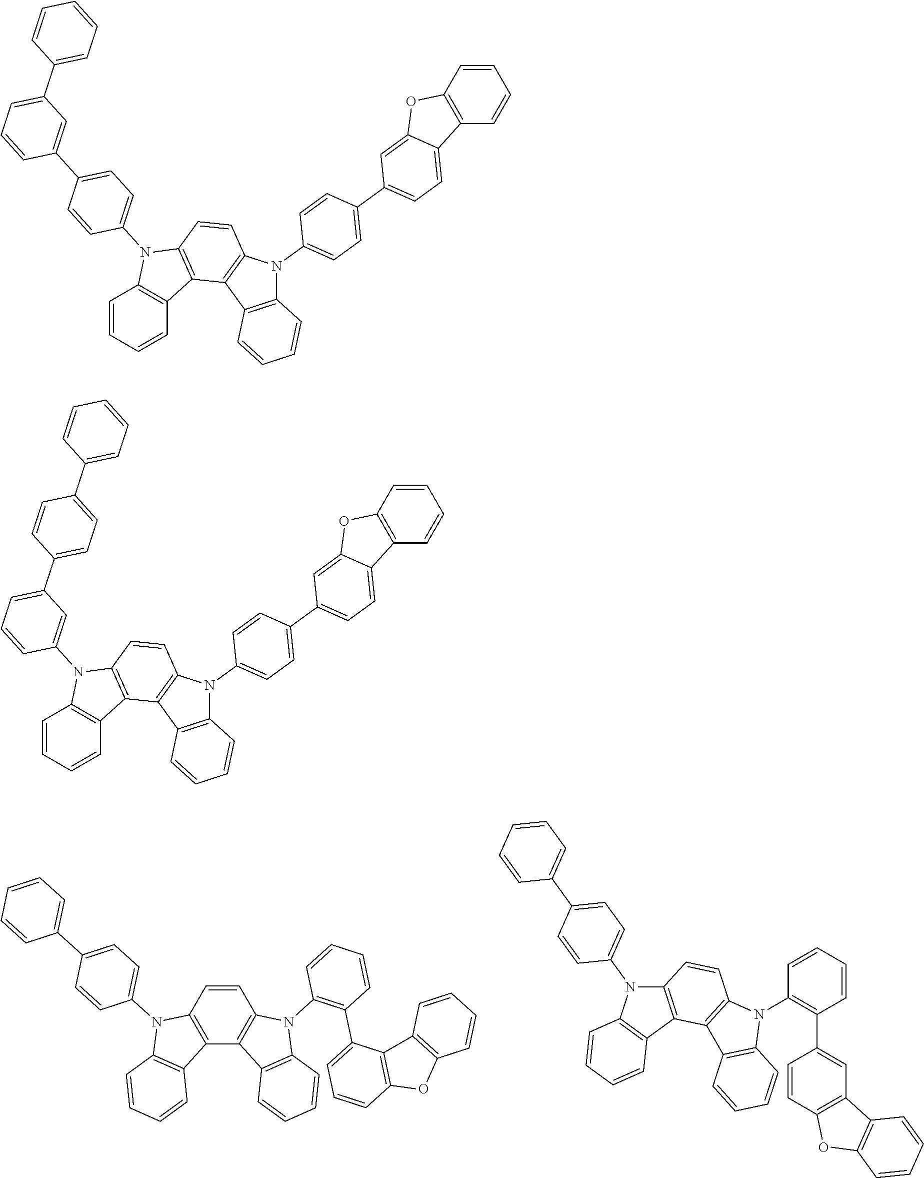 [SMILES: c1ccc(-c2cccc(-c3ccc(-n4c5ccccc5c5c6c7ccccc7n(-c7ccc(-c8ccc9c(c8)oc8ccccc89)cc7)c6ccc54)cc3)c2)cc1 ; c1ccc(-c2ccc(-c3cccc(-n4c5ccccc5c5c6c7ccccc7n(-c7ccc(-c8ccc9c(c8)oc8ccccc89)cc7)c6ccc54)c3)cc2)cc1 ; c1ccc(-c2ccc(-n3c4ccccc4c4c5c6ccccc6n(-c6ccccc6-c6cccc7oc8ccccc8c67)c5ccc43)cc2)cc1 ; c1ccc(-c2ccc(-n3c4ccccc4c4c5c6ccccc6n(-c6ccccc6-c6ccc7oc8ccccc8c7c6)c5ccc43)cc2)cc1]

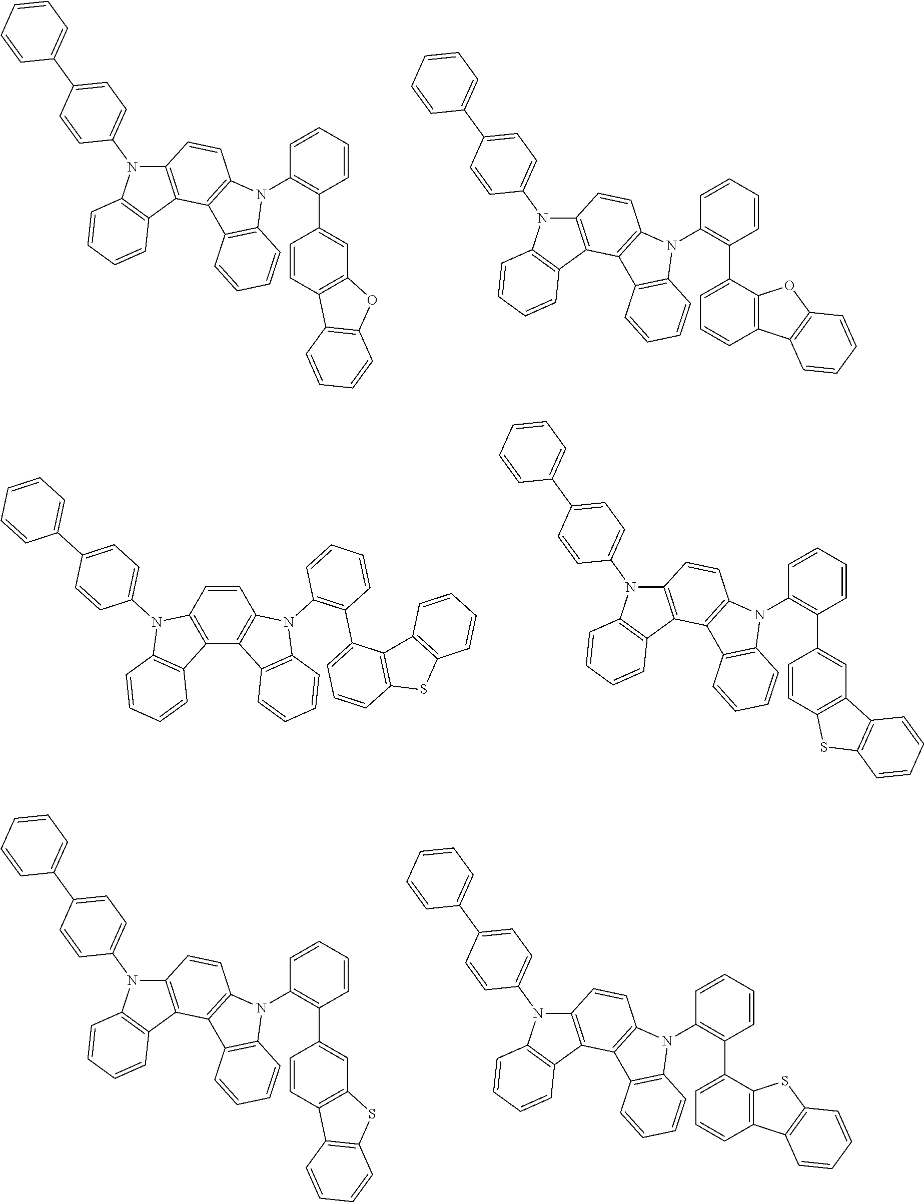

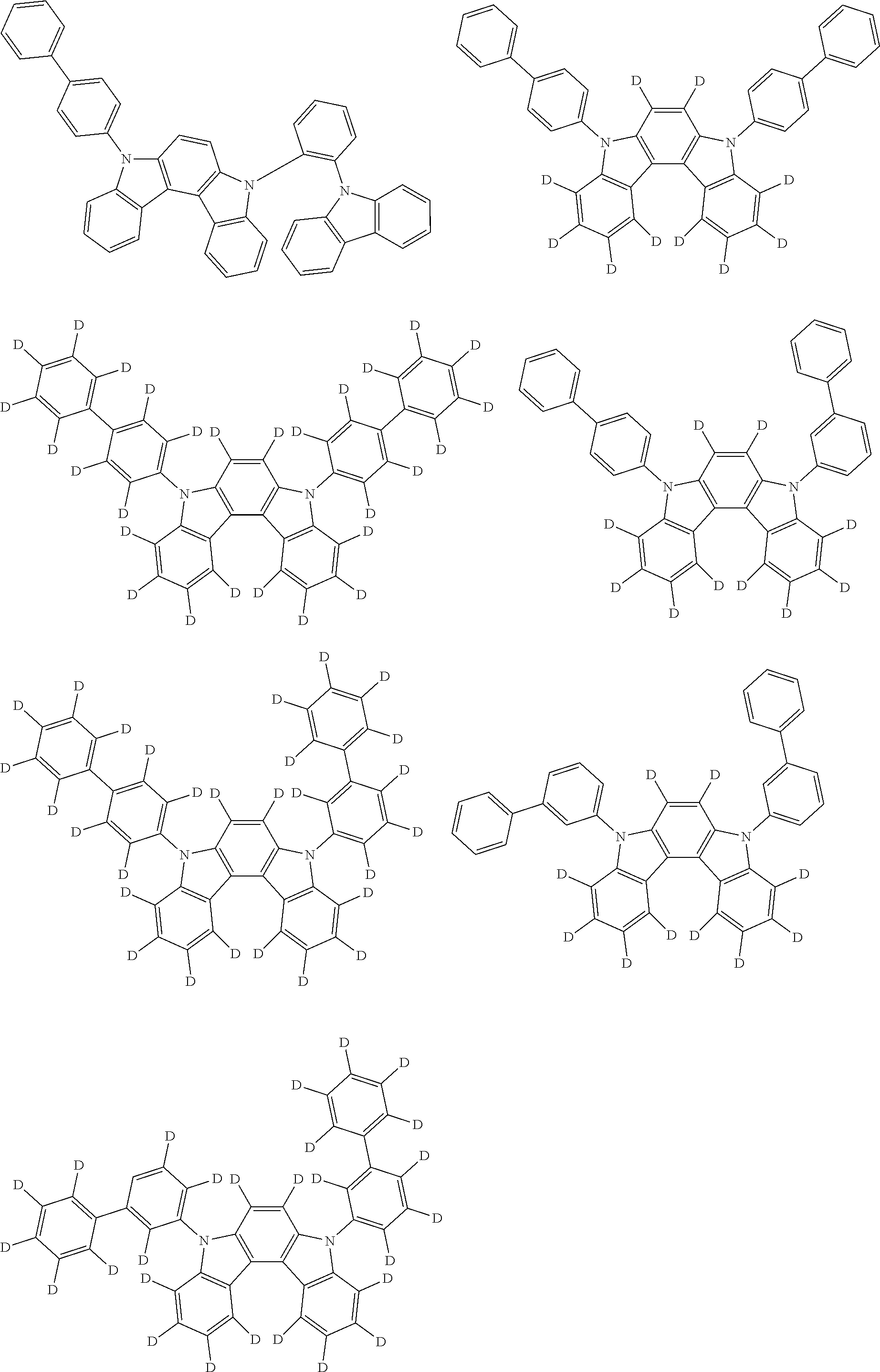

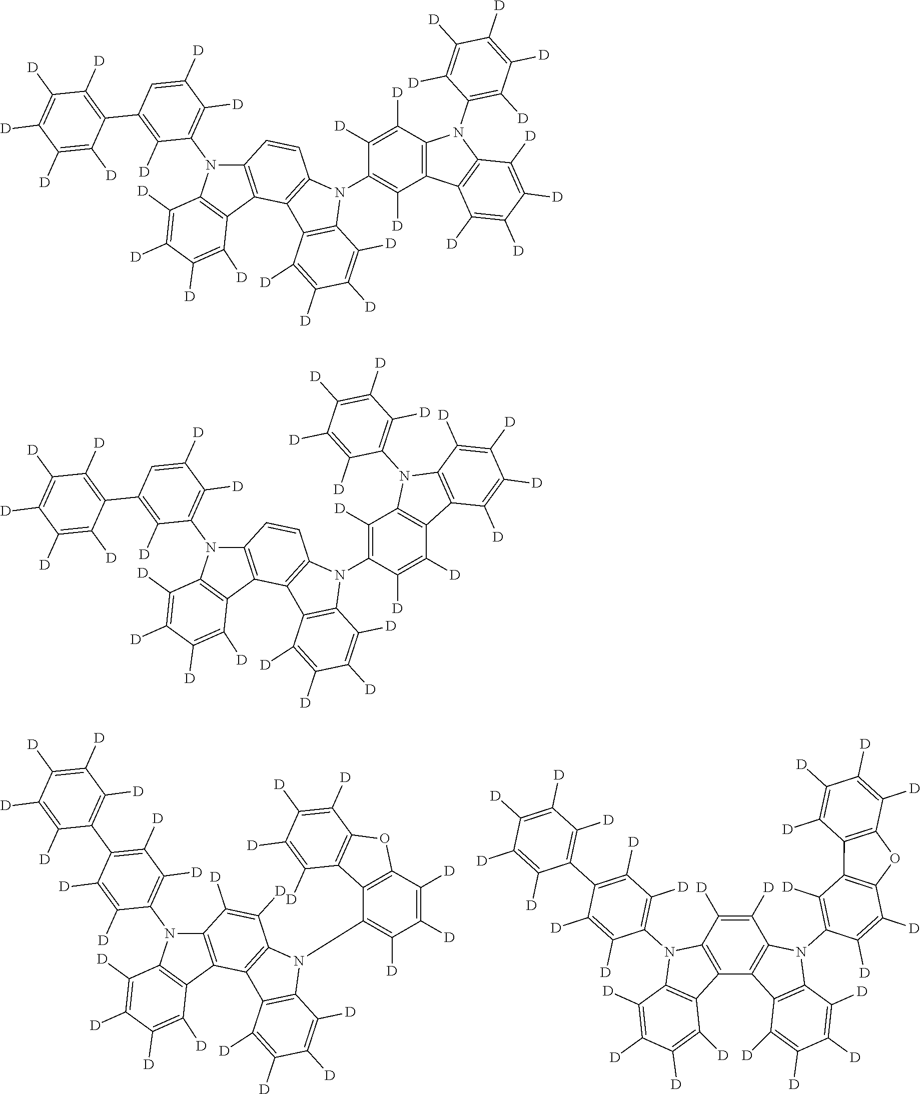

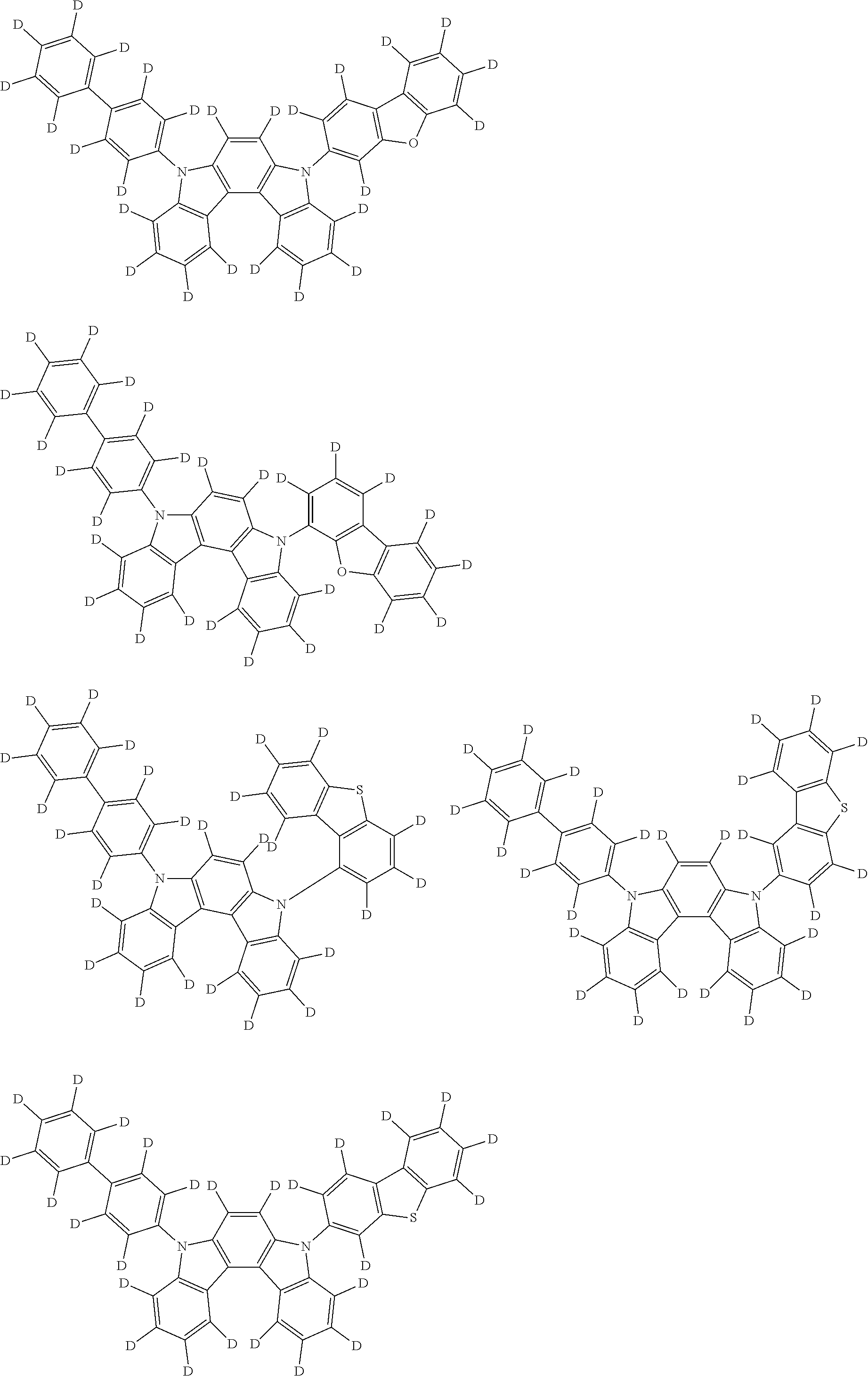

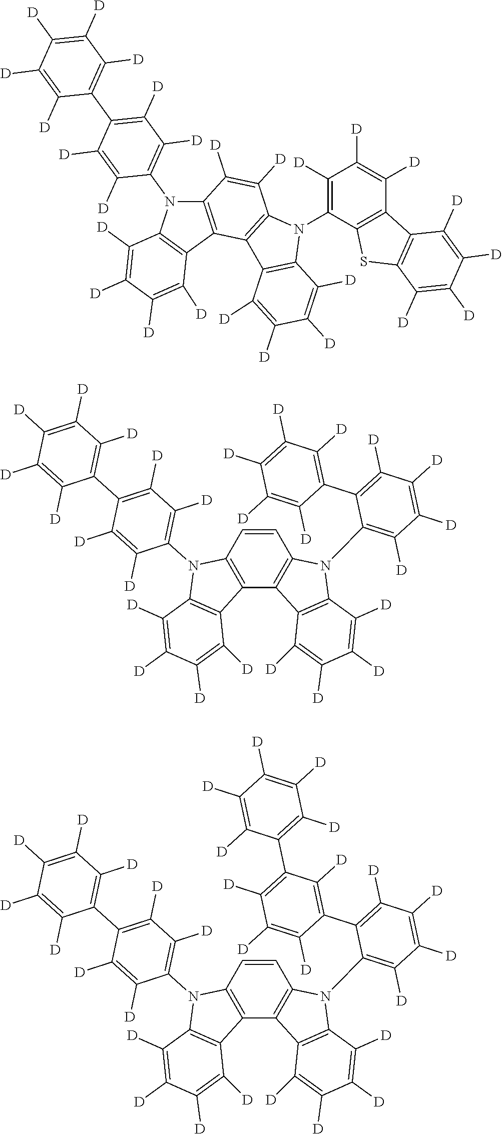

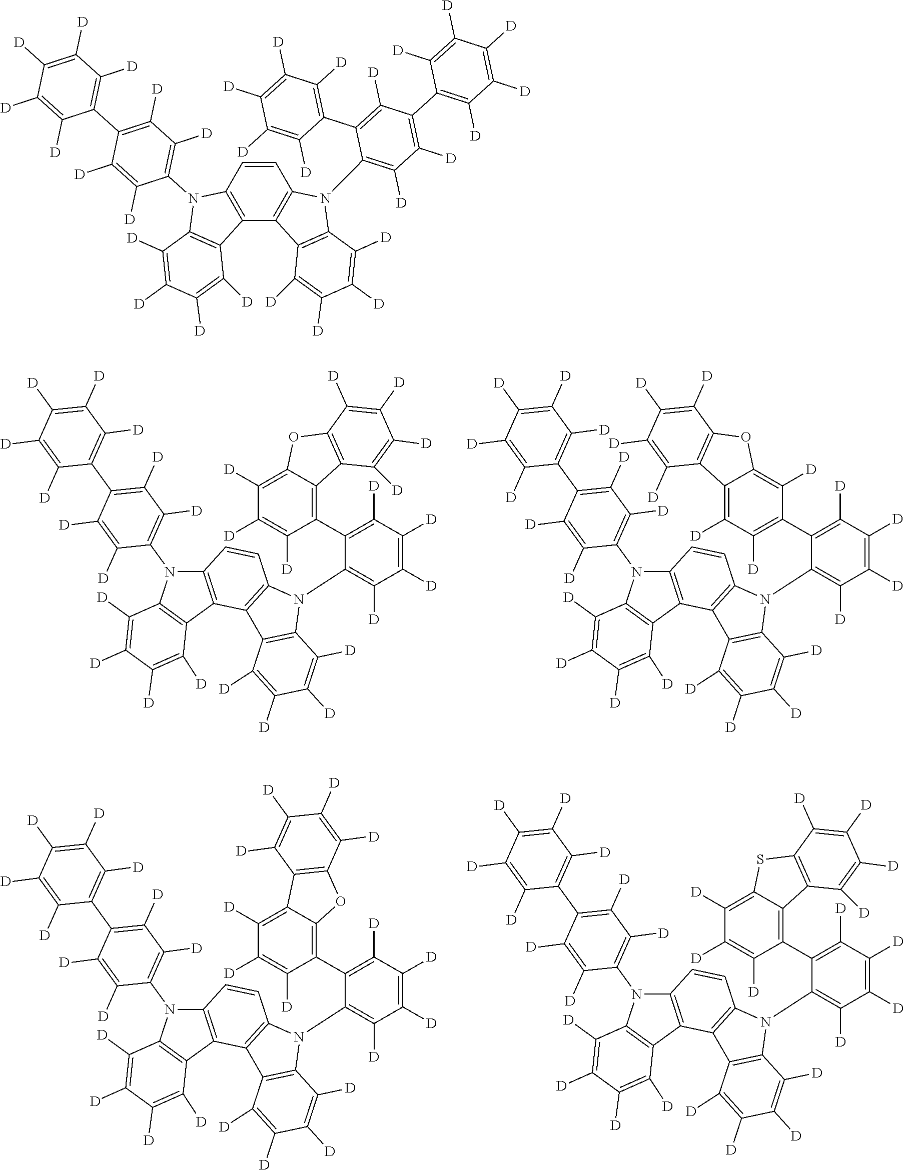

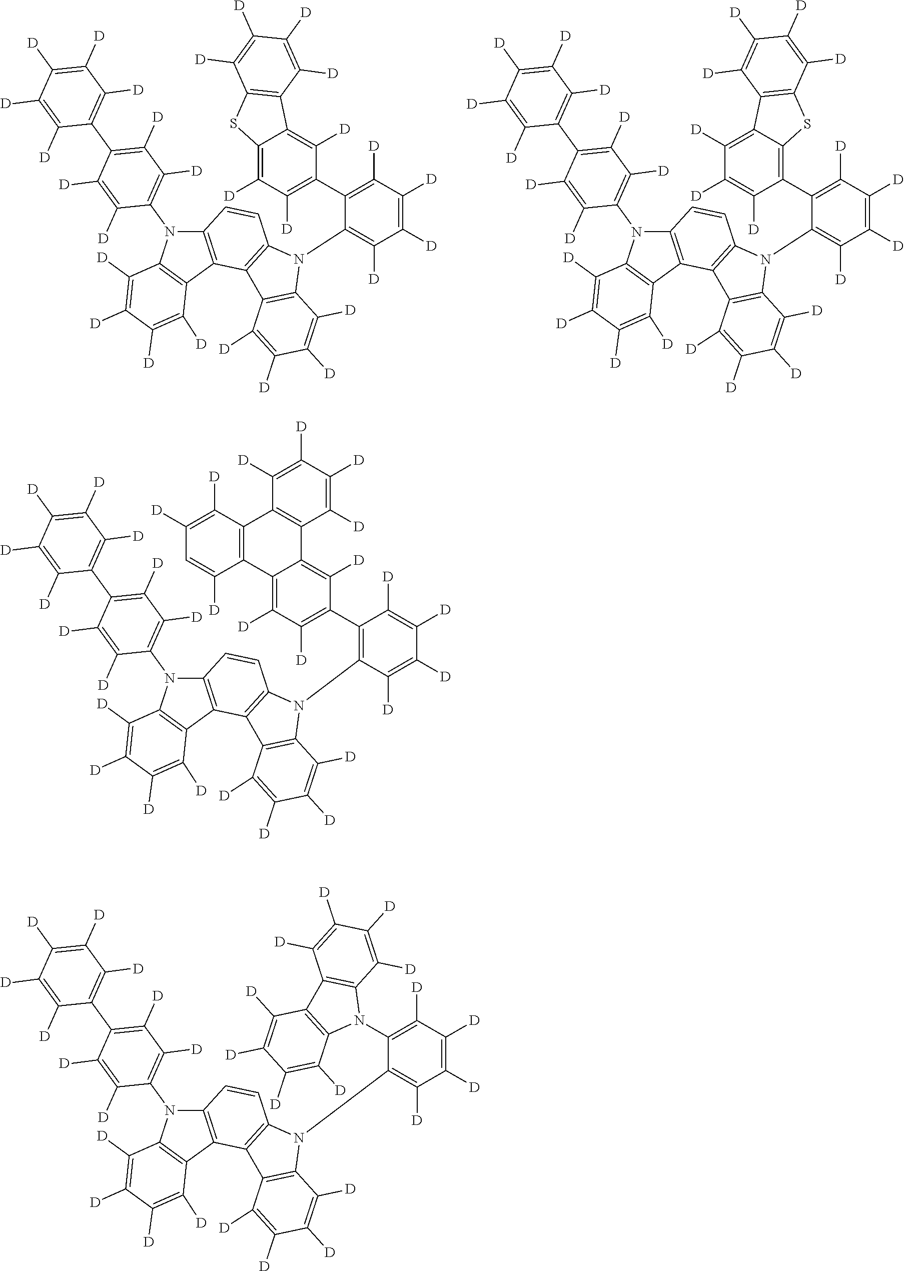

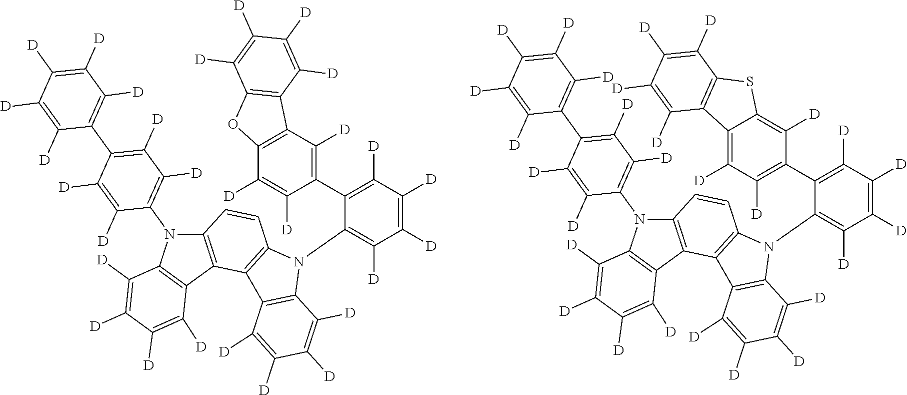 [SMILES: [2H]c1c([2H])c([2H])c(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c6oc7c([2H])c([2H])c([2H])c([2H])c7c6c5[2H])c4c4c([2H])c([2H])c([2H])c([2H])c43)c([2H])c2[2H])c([2H])c1[2H] ; [2H]c1c([2H])c([2H])c(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c6c(sc7c([2H])c([2H])c([2H])c([2H])c76)c5[2H])c4c4c([2H])c([2H])c([2H])c([2H])c43)c([2H])c2[2H])c([2H])c1[2H]]

Meanwhile, the first compound can be prepared by a preparation method as shown in the following Reaction Scheme 1 as an example:

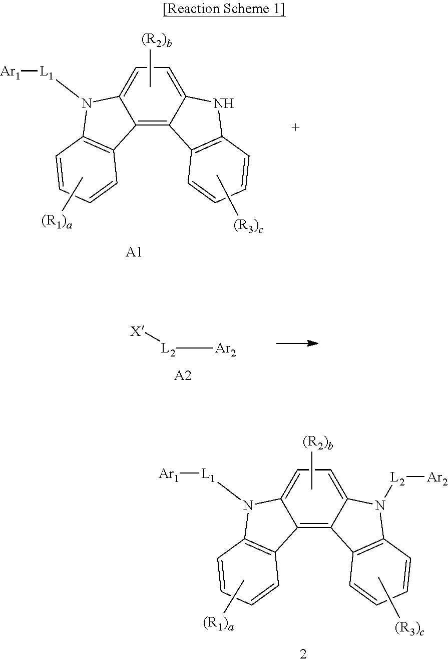

where in Reaction Scheme 1, X′ is halogen, preferably bromo, or chloro, and the definitions of other substituents are the same as described above.

Specifically, the first compound may be prepared by an amine substitution reaction of the starting materials A1 and A2. Such an amine substitution reaction is preferably carried out in the presence of a palladium catalyst and a base, and a reactive group for the amine substitution reaction can be appropriately changed. The preparation method of the first compound can be further embodied in Preparation Examples described hereinafter.

Further, the first compound represented by Chemical Formula 1 having at least one deuterium atom can be prepared by a preparation method as shown in the following Reaction Scheme 1′ as an example:

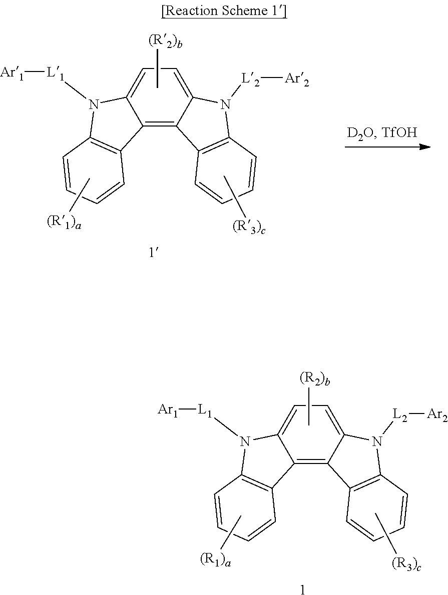

in Reaction Scheme 1, R′₁ to R′₃, L′₁, L′₂, Ar′₁ and Ar′₂ mean R₁ to R₃, L₁, L₂, Ar₁ and Ar₂ substituents which are not substituted with deuterium, respectively, and the definitions of other substituents are the same as described above. Specifically, the first compound represented by Chemical Formula 1 having at least one deuterium atom can be prepared by deuterating a compound not substituted with deuterium. This deuteration reaction can be performed by reacting the non-deuterated compound with TfOH (trifluoromethanesulfonic acid) after introducing it into a deuterated solvent such as deuterium oxide or a benzene-D₆ (C₆D₆) solution. The deuteration rate of the compound can be controlled by varying the reaction time and temperature conditions.

Meanwhile, the compound represented by the above Chemical Formula 1 can be prepared by appropriately modifying the reactants in the above Reaction Scheme 1 and 1′, and their preparation methods can be further specified in the preparation examples described below.

### (The Second Compound)

The second compound is represented by the above Chemical Formula 2. Specifically, the second compound possesses excellent electron transport capability, enabling efficient electron transfer as a dopant material and thereby increasing the probability of electron-hole recombination in the light emitting layer.

Further, Ar may be C₆₋₂₀ aryl unsubstituted or substituted with one or more substituents selected from the group consisting of deuterium, tritium, C₁₋₁₀ alkyl, and C₆₋₁₂ aryl, or unsubstituted or substituted with a substituent to which two or more substituents of the above-exemplified substituents are connected.

For example, Ar may be C₆₋₂₀ aryl unsubstituted, or substituted with one or more substituents selected from the group consisting of deuterium; tritium; methyl; and phenyl substituted or unsubstituted with deuterium or tritium.

More specifically for example, Ar may be phenyl, biphenylyl, terphenylyl, or quaterphenylyl,
wherein, Ar is unsubstituted or substituted with deuterium or tritium.

Meanwhile, R₁₁ to R₁₄ may be each independently hydrogen, deuterium, tritium, or C₆₋₂₀ aryl substituted or unsubstituted with deuterium or tritium; or combined with adjacent substituents to form a substituted or unsubstituted aromatic ring or a substituted or unsubstituted heteroaromatic ring containing at least one heteroatom selected among N, O and S, wherein the aromatic ring is a benzene or naphthalene ring, and the heteroaromatic ring is an indole, benzofuran, or benzothiophene ring.

Further, R₁₁ to R₁₄ may be each independently hydrogen, deuterium, tritium, or phenyl substituted or unsubstituted with deuterium or tritium; or combined with adjacent substituents to form a benzofuran ring substituted or unsubstituted with deuterium or tritium, or a benzothiophene ring substituted or unsubstituted with deuterium or tritium.

Wherein, the aromatic ring and heteroaromatic ring formed by the R₁₁ to R₁₄ combining with adjacent substituents are fused with an adjacent benzene ring.

Wherein, d means the number of R₁₁, and when d is 2 or more, two or more R₁₁ may be the same as or different from each other. Specifically, d is 0, 1, 2, 3, or 4.

Further, e means the number of R₁₂, and when e is 2 or more, two or more R₁₂ may be the same as or different from each other. Specifically, e is 0, 1, 2, 3, or 4.

Further, f means the number of R₁₃, and when f is 2 or more, two or more R₁₃ may be the same as or different from each other. Specifically, f is 0, 1, 2, 3, or 4.

Further, g means the number of R₁₄, and when g is 2 or more, two or more R₁₄ may be the same as or different from each other. Specifically, g is 0, 1, 2, 3, or 4.

Further, h means the number of R₁₅, and when h is 2 or more, two or more R₁₅ may be the same as or different from each other. Specifically, h is 0, 1, 2, 3, or 4.

Further, i means the number of R₁₆, and when i is 2 or more, two or more R₁₆ may be the same as or different from each other. Specifically, i is 0, 1, 2, 3, or 4.

Further, the substituents

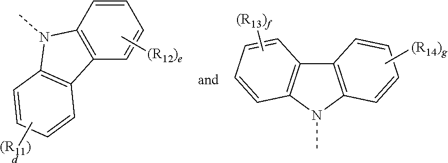

are each independently any one selected from the substituents represented by the following chemical formulas 2-1 to 2-8 and their deuterated or tritiated structures:

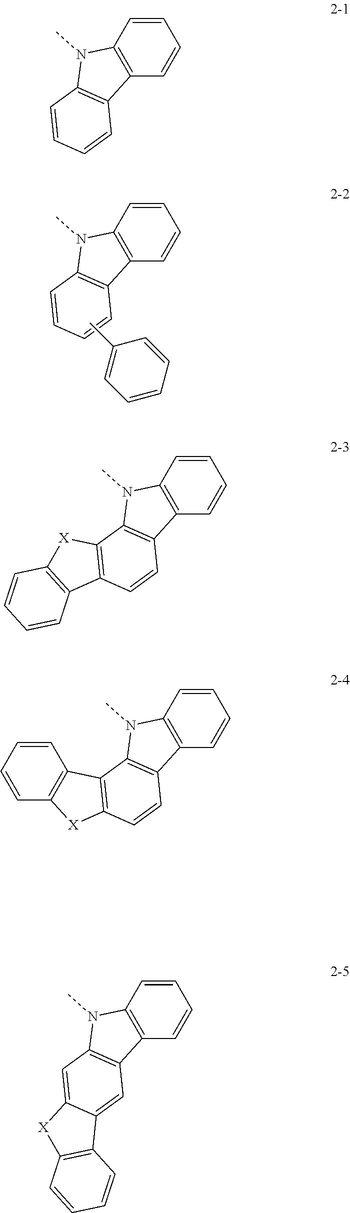

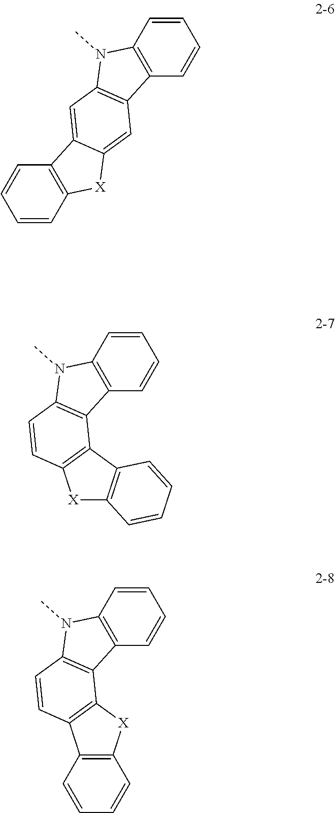

wherein in Chemical Formulas 2-1 to 2-8,
X is O of S.

Further, R₁₅ and R₁₆ may be each independently hydrogen, deuterium, tritium, or phenyl unsubstituted or substituted with deuterium or tritium.

Further, the second compound may not contain deuterium or tritium, or may contain one or more deuterium or tritium atoms.

When the second compound contains deuterium or tritium, the deuterium/tritium substitution rate of the first compound may be from 1% to 100%. Specifically, the deuterium/tritium substitution rate of the second compound may be 5% or more, 10% or more, 20% or more, 30% or more, 40% or more, 50% or more, 60% or more, 70% or more, 75% or more, 80% or more, or 90% or more, and 100% or less.

In one embodiment, the second compound may not contain deuterium or tritium, or may contain 1 to 50 deuterium or tritium atoms. More specifically, the second compound may not contain deuterium or tritium atom, or may contain 1 or more, 2 or more, 3 or more, 4 or more, 5 or more, 6 or more, 7 or more, 8 or more, or 9 or more, and 50 or less, 40 or less, 30 or less, 28 or less, 26 or less, 24 or less, 22 or less, 20 or less, 18 or less, 16 or less, 14 or less, 13 or less, 12 or less, 11 or less, or 10 or less deuterium or tritium atoms.

Meanwhile, representative examples of the second compound are as follows:

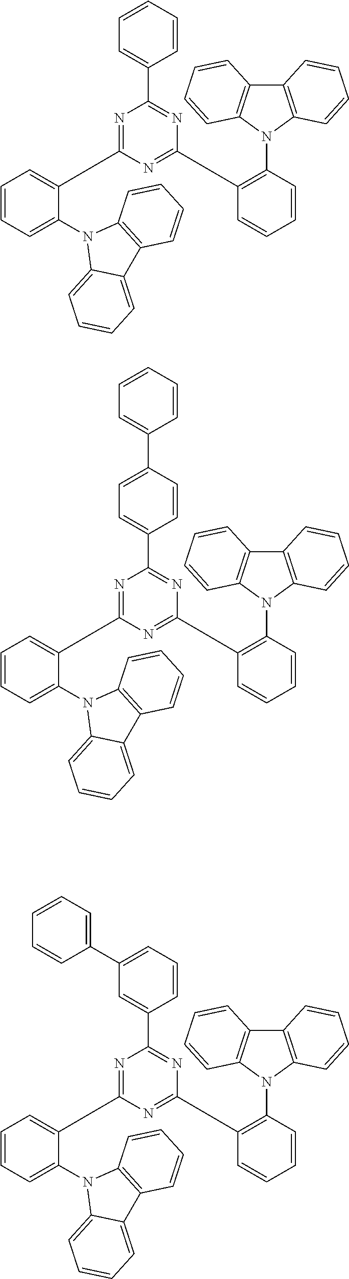 [SMILES: c1ccc(-c2nc(-c3ccccc3-n3c4ccccc4c4ccccc43)nc(-c3ccccc3-n3c4ccccc4c4ccccc43)n2)cc1 ; c1ccc(-c2ccc(-c3nc(-c4ccccc4-n4c5ccccc5c5ccccc54)nc(-c4ccccc4-n4c5ccccc5c5ccccc54)n3)cc2)cc1 ; c1ccc(-c2cccc(-c3nc(-c4ccccc4-n4c5ccccc5c5ccccc54)nc(-c4ccccc4-n4c5ccccc5c5ccccc54)n3)c2)cc1]

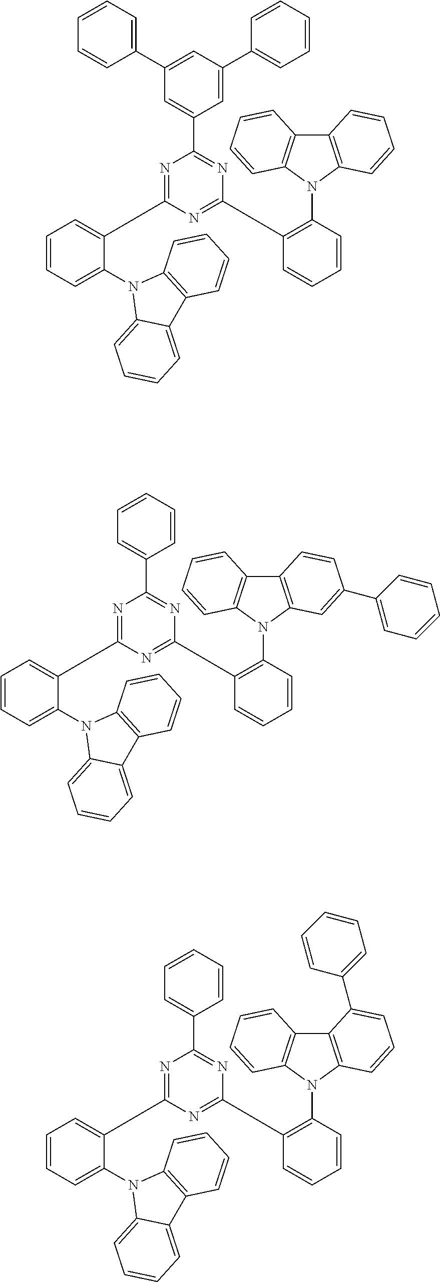 [SMILES: c1ccc(-c2cc(-c3ccccc3)cc(-c3nc(-c4ccccc4-n4c5ccccc5c5ccccc54)nc(-c4ccccc4-n4c5ccccc5c5ccccc54)n3)c2)cc1 ; c1ccc(-c2ccc3c4ccccc4n(-c4ccccc4-c4nc(-c5ccccc5)nc(-c5ccccc5-n5c6ccccc6c6ccccc65)n4)c3c2)cc1 ; c1ccc(-c2nc(-c3ccccc3-n3c4ccccc4c4ccccc43)nc(-c3ccccc3-n3c4ccccc4c4c(-c5ccccc5)cccc43)n2)cc1]

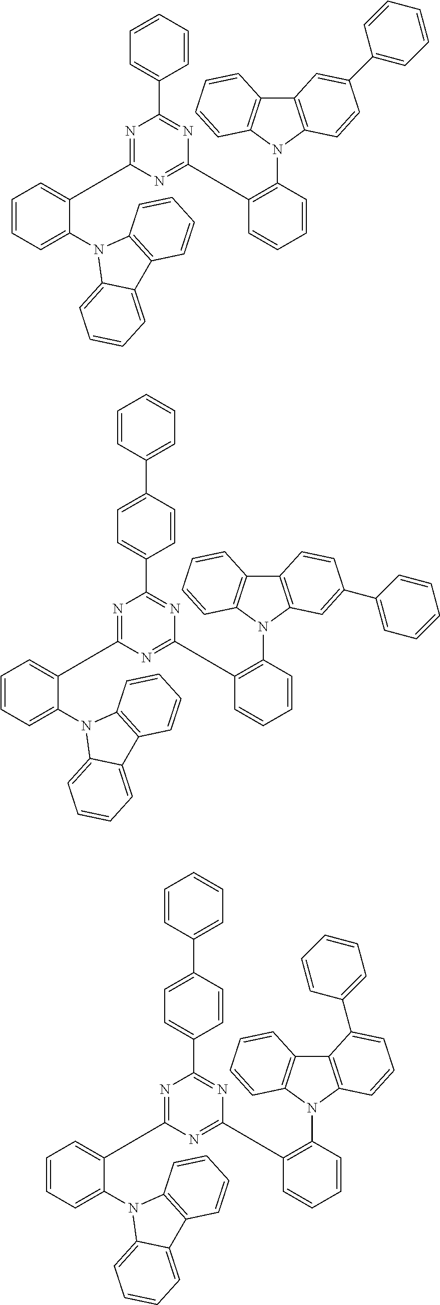 [SMILES: c1ccc(-c2ccc3c(c2)c2ccccc2n3-c2ccccc2-c2nc(-c3ccccc3)nc(-c3ccccc3-n3c4ccccc4c4ccccc43)n2)cc1 ; c1ccc(-c2ccc(-c3nc(-c4ccccc4-n4c5ccccc5c5ccccc54)nc(-c4ccccc4-n4c5ccccc5c5ccc(-c6ccccc6)cc54)n3)cc2)cc1 ; c1ccc(-c2ccc(-c3nc(-c4ccccc4-n4c5ccccc5c5ccccc54)nc(-c4ccccc4-n4c5ccccc5c5c(-c6ccccc6)cccc54)n3)cc2)cc1]

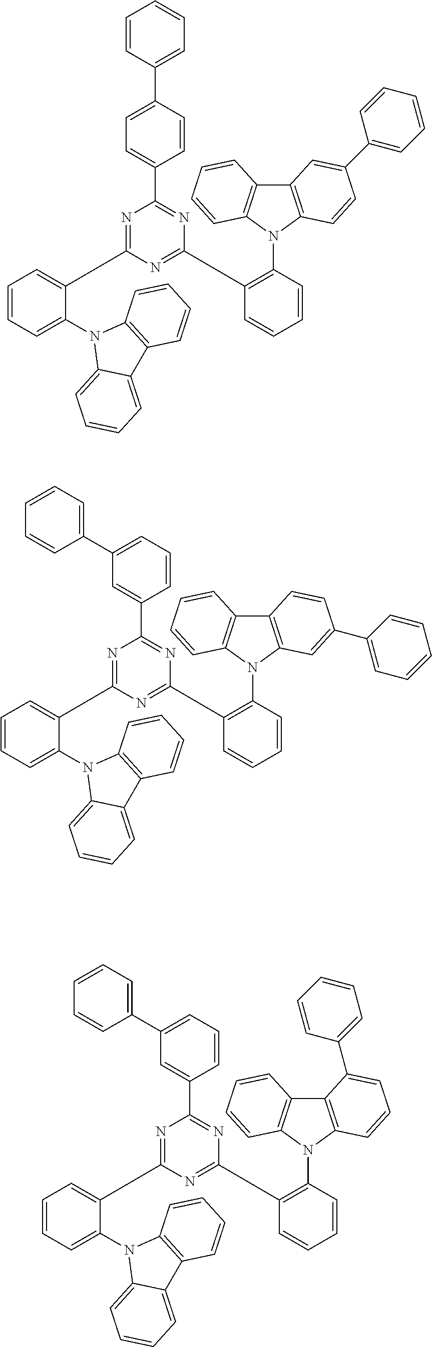 [SMILES: c1ccc(-c2ccc(-c3nc(-c4ccccc4-n4c5ccccc5c5ccccc54)nc(-c4ccccc4-n4c5ccccc5c5cc(-c6ccccc6)ccc54)n3)cc2)cc1 ; c1ccc(-c2cccc(-c3nc(-c4ccccc4-n4c5ccccc5c5ccccc54)nc(-c4ccccc4-n4c5ccccc5c5ccc(-c6ccccc6)cc54)n3)c2)cc1 ; c1ccc(-c2cccc(-c3nc(-c4ccccc4-n4c5ccccc5c5ccccc54)nc(-c4ccccc4-n4c5ccccc5c5c(-c6ccccc6)cccc54)n3)c2)cc1]

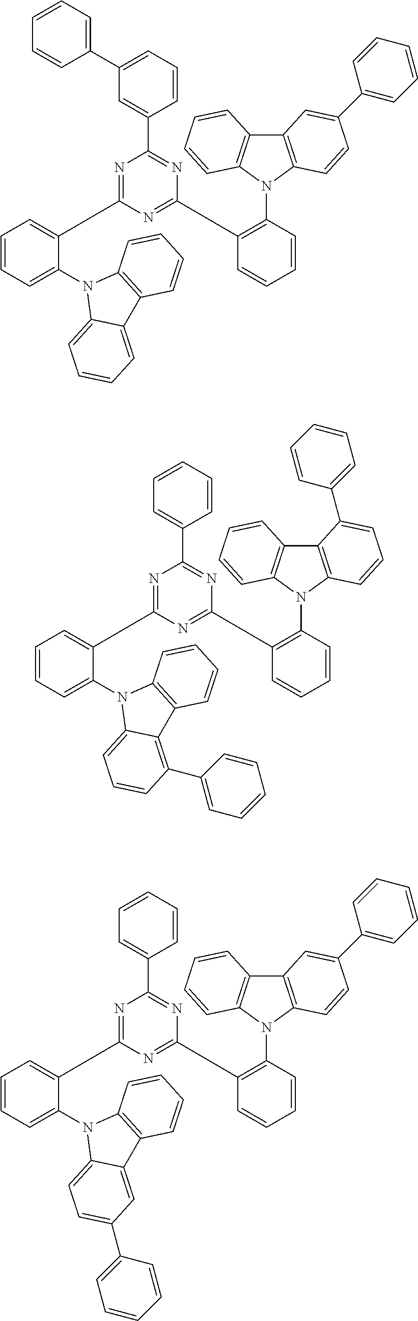 [SMILES: c1ccc(-c2cccc(-c3nc(-c4ccccc4-n4c5ccccc5c5ccccc54)nc(-c4ccccc4-n4c5ccccc5c5cc(-c6ccccc6)ccc54)n3)c2)cc1 ; c1ccc(-c2nc(-c3ccccc3-n3c4ccccc4c4c(-c5ccccc5)cccc43)nc(-c3ccccc3-n3c4ccccc4c4c(-c5ccccc5)cccc43)n2)cc1 ; c1ccc(-c2ccc3c(c2)c2ccccc2n3-c2ccccc2-c2nc(-c3ccccc3)nc(-c3ccccc3-n3c4ccccc4c4cc(-c5ccccc5)ccc43)n2)cc1]

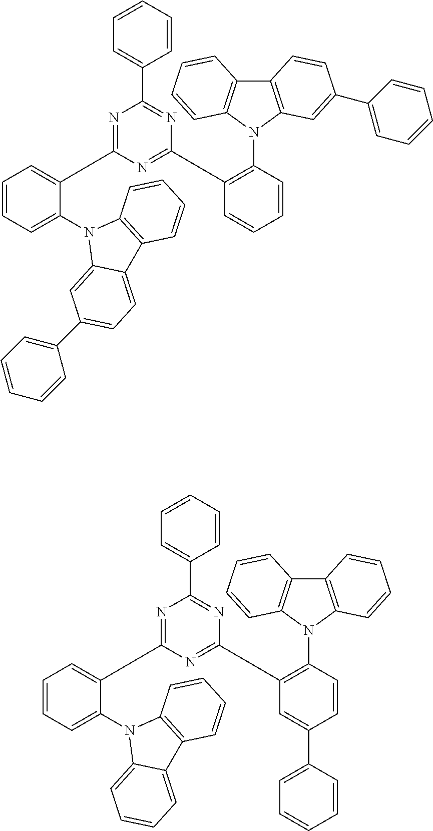 [SMILES: c1ccc(-c2ccc3c4ccccc4n(-c4ccccc4-c4nc(-c5ccccc5)nc(-c5ccccc5-n5c6ccccc6c6ccc(-c7ccccc7)cc65)n4)c3c2)cc1 ; c1ccc(-c2ccc(-n3c4ccccc4c4ccccc43)c(-c3nc(-c4ccccc4)nc(-c4ccccc4-n4c5ccccc5c5ccccc54)n3)c2)cc1]

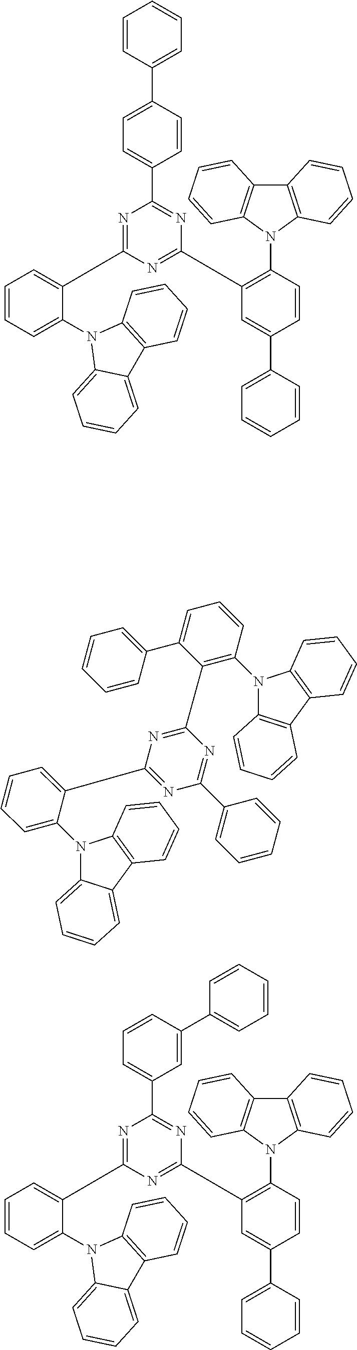 [SMILES: c1ccc(-c2ccc(-c3nc(-c4ccccc4-n4c5ccccc5c5ccccc54)nc(-c4cc(-c5ccccc5)ccc4-n4c5ccccc5c5ccccc54)n3)cc2)cc1 ; c1ccc(-c2nc(-c3ccccc3-n3c4ccccc4c4ccccc43)nc(-c3c(-c4ccccc4)cccc3-n3c4ccccc4c4ccccc43)n2)cc1 ; c1ccc(-c2cccc(-c3nc(-c4ccccc4-n4c5ccccc5c5ccccc54)nc(-c4cc(-c5ccccc5)ccc4-n4c5ccccc5c5ccccc54)n3)c2)cc1]

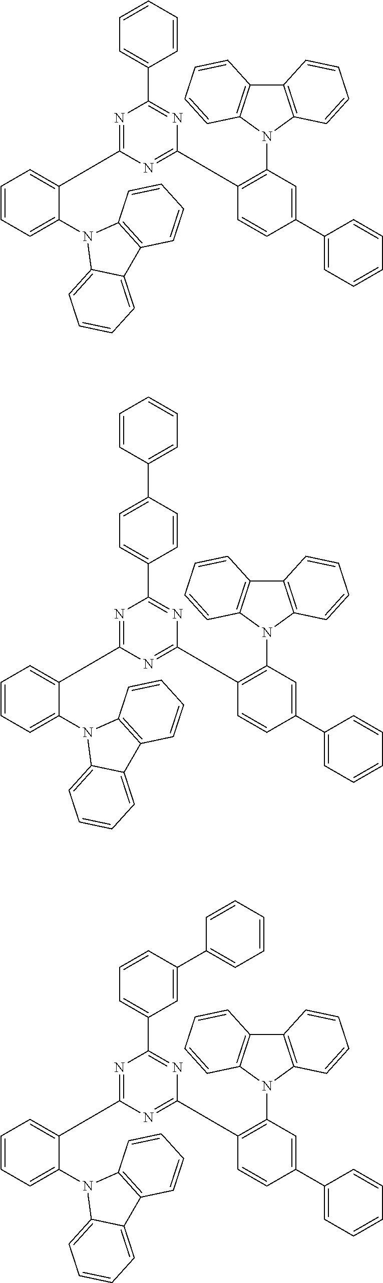 [SMILES: c1ccc(-c2ccc(-c3nc(-c4ccccc4)nc(-c4ccccc4-n4c5ccccc5c5ccccc54)n3)c(-n3c4ccccc4c4ccccc43)c2)cc1 ; c1ccc(-c2ccc(-c3nc(-c4ccccc4-n4c5ccccc5c5ccccc54)nc(-c4ccc(-c5ccccc5)cc4-n4c5ccccc5c5ccccc54)n3)cc2)cc1 ; c1ccc(-c2cccc(-c3nc(-c4ccccc4-n4c5ccccc5c5ccccc54)nc(-c4ccc(-c5ccccc5)cc4-n4c5ccccc5c5ccccc54)n3)c2)cc1]

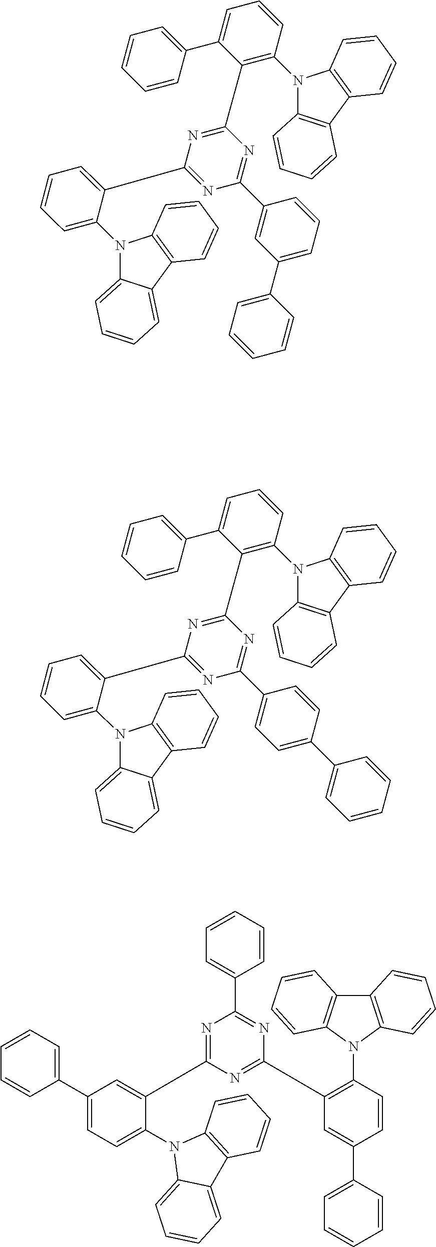 [SMILES: c1ccc(-c2cccc(-c3nc(-c4ccccc4-n4c5ccccc5c5ccccc54)nc(-c4c(-c5ccccc5)cccc4-n4c5ccccc5c5ccccc54)n3)c2)cc1 ; c1ccc(-c2ccc(-c3nc(-c4ccccc4-n4c5ccccc5c5ccccc54)nc(-c4c(-c5ccccc5)cccc4-n4c5ccccc5c5ccccc54)n3)cc2)cc1 ; c1ccc(-c2ccc(-n3c4ccccc4c4ccccc43)c(-c3nc(-c4ccccc4)nc(-c4cc(-c5ccccc5)ccc4-n4c5ccccc5c5ccccc54)n3)c2)cc1]

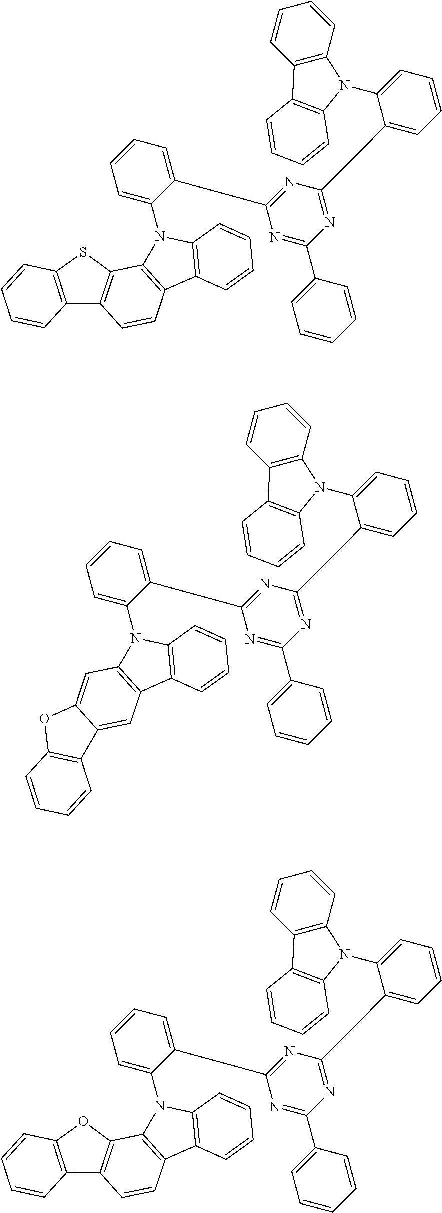 [SMILES: c1ccc(-c2nc(-c3ccccc3-n3c4ccccc4c4ccccc43)nc(-c3ccccc3-n3c4ccccc4c4ccc5c6ccccc6sc5c43)n2)cc1 ; c1ccc(-c2nc(-c3ccccc3-n3c4ccccc4c4ccccc43)nc(-c3ccccc3-n3c4ccccc4c4cc5c(cc43)oc3ccccc35)n2)cc1 ; c1ccc(-c2nc(-c3ccccc3-n3c4ccccc4c4ccccc43)nc(-c3ccccc3-n3c4ccccc4c4ccc5c6ccccc6oc5c43)n2)cc1]

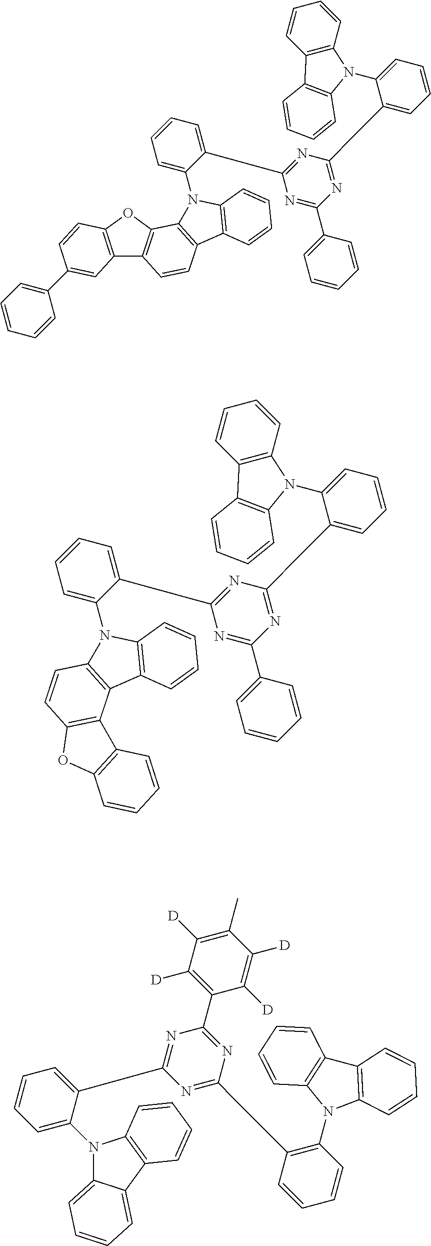 [SMILES: c1ccc(-c2ccc3oc4c(ccc5c6ccccc6n(-c6ccccc6-c6nc(-c7ccccc7)nc(-c7ccccc7-n7c8ccccc8c8ccccc87)n6)c54)c3c2)cc1 ; c1ccc(-c2nc(-c3ccccc3-n3c4ccccc4c4ccccc43)nc(-c3ccccc3-n3c4ccccc4c4c5c(ccc43)oc3ccccc35)n2)cc1 ; [2H]c1c([2H])c(-c2nc(-c3ccccc3-n3c4ccccc4c4ccccc43)nc(-c3ccccc3-n3c4ccccc4c4ccccc43)n2)c([2H])c([2H])c1C]

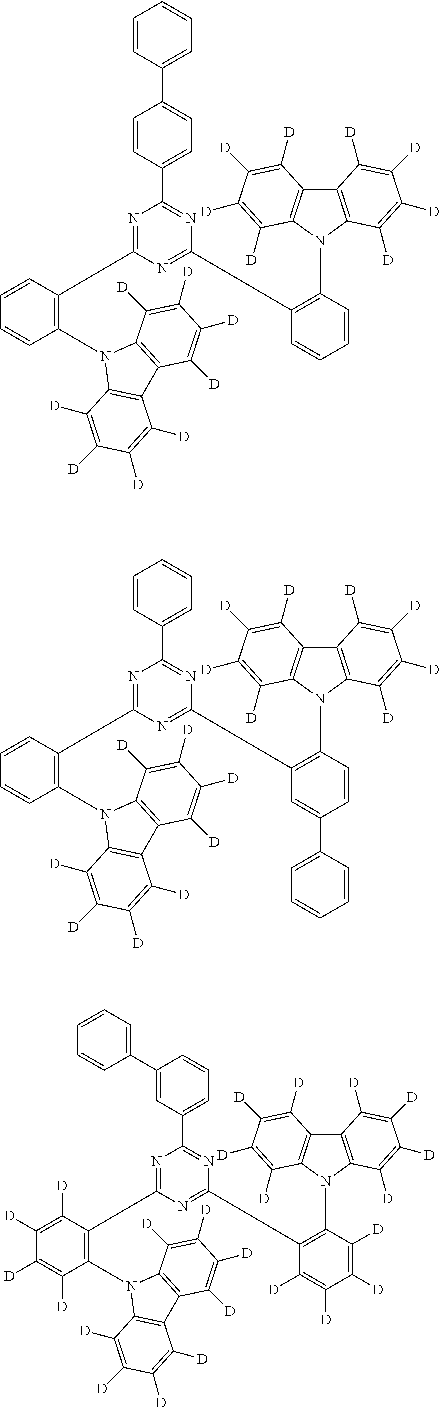

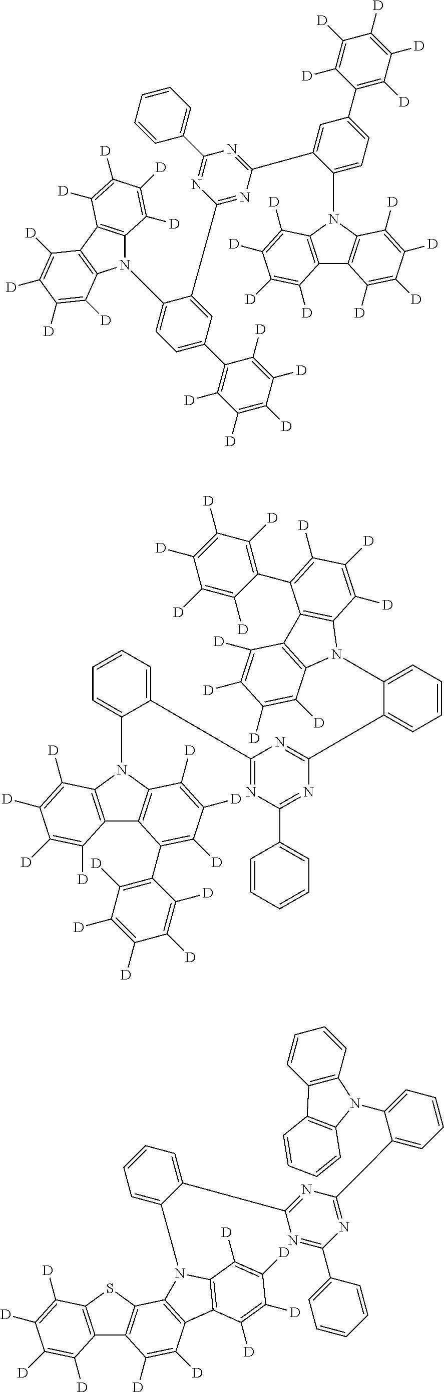

Meanwhile, the second compound can be prepared by a preparation method as shown in the following Reaction Scheme 2 as an example:

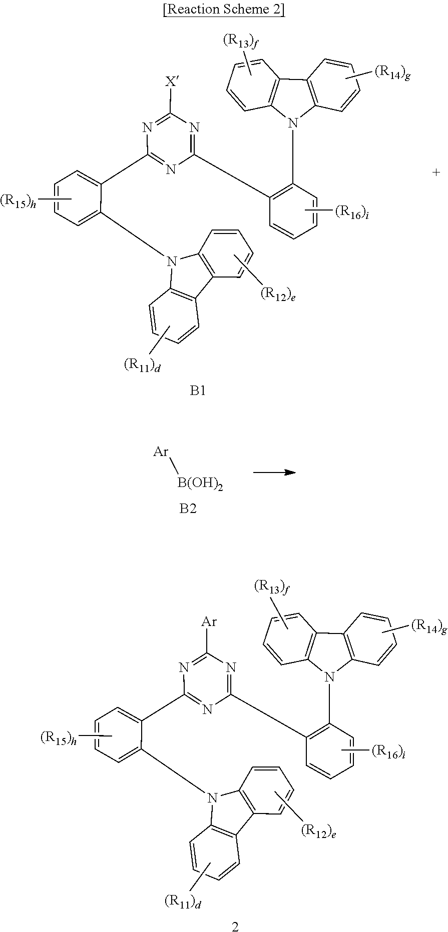

in Reaction Scheme 2, X is halogen, preferably bromo, or chloro, and the definitions of other substituents are the same as described above.

Specifically, the second compound may be prepared by a Suzuki-coupling reaction of the starting materials B1 and B2. Such a Suzuki-coupling reaction is preferably carried out in the presence of a palladium catalyst and a base, and a reactive group for the Suzuki-coupling reaction can be appropriately changed. The preparation method of the second compound can be further embodied in Preparation Examples described hereinafter.

Further, when the second compound has at least one deuterium, the second compound can be prepared by first preparing a compound that is not substituted with deuterium and then deuterizing it. This deuteration reaction can be performed by reacting the non-deuterated compound with TfOH (trifluoromethanesulfonic acid) after introducing it into a deuterated solvent such as deuterium oxide or a benzene-D₆ (C₆D₆) solution.

Further, the substituent L₁-Ar₁ of the first compound and the substituent Ar of the second compound do not contain a fused polycyclic substituent. When the first compound and the second compound simultaneously contain a monocyclic aryl substituent, such as phenyl, biphenylyl, terphenylyl, or quaterphenylyl, the efficiency and lifespan characteristics of an organic light emitting device containing both the first compound and the second compound can be further improved.

Furthermore, the first compound and the second compound may be included in the composition at a weight ratio of 1:99 to 99:1, or a weight ratio of 0.5:1 to 4:1.

Wherein, in terms of appropriately maintaining the ratio of holes and electrons in the light emitting layer, the first compound and the second compound may be included in the composition at a weight ratio of 1:1 to 3:1. More specifically, the first compound may be included at a weight ratio of 1 time or more, 1.1 times or more, 1.2 times or more, 1.3 times or more, 1.4 times or more, 1.5 times or more, 1.6 times or more, 1.7 times or more, 1.8 times or more, 1.9 times or more, or 2 times or more, but 3 times or less, 2.9 times or less, 2.8 times or less, 2.7 times or less, 2.6 times or less, 2.5 times or less, 2.4 times or less, 2.3 times or less, 2.2 times or less, or 2.1 times or less relative to the weight of the second compound. When the first compound is included in an amount less than 1 times the weight of the second compound, hole transfer within the light emitting layer may not be smooth, which may cause problems with the voltage, efficiency, and lifespan of the manufactured device. On the other hand, when the first compound is included in an amount more than 3 times the weight of the second compound, electron transfer within the light emitting layer may not be smooth, which may cause the hole and electron balance to be unbalanced throughout the device.

Further, the composition may be a mixture or an organic alloy.

In one embodiment, the composition may be a mixture in which the compound represented by Chemical Formula 1 and the compound represented by Chemical Formula 2 are simply mixed. This mixture, in which each compound is physically homogeneously mixed without any separate pretreatment, can be prepared using a mixer commonly known in the art.

In this way, when the compound represented by Chemical Formula 1 and the compound represented by Chemical Formula 2 are applied to an organic light emitting device as composition in the form of a mixture, the organic layer is formed by supplying each compound from a single source rather than separate sources. This simplifies the process, eliminating the need for process control steps for multiple sources.

In another embodiment, the composition may be an organic alloy in which the compound represented by Chemical Formula 1 and the compound represented by Chemical Formula 2 have chemical interactions through pretreatment. The pretreatment may, for example, involve heating and/or sublimation of a mixture of the compounds and then cooling them, but is not limited thereto.

Such an organic alloy may exhibit emission wavelengths, colors, glass transition temperatures (Tg), crystallization temperatures (Tc), and melting temperatures (Tm) that differ from those of a mixture in which no chemical interaction exists between the compounds.

Further, when the compound represented by Chemical Formula 1 and the compound represented by Chemical Formula 2 is applied to an organic light emitting device as composition in the form of an organic alloy, all compounds can be supplied from a single source during the formation of the organic layer, simplifying the process and ensuring uniformity and consistency of the deposited material. Accordingly, when forming multiple organic layers in a continuous process, organic layers having components in substantially the same ratio can be continuously produced, and thus the reproducibility and reliability of the organic layers can be improved.

### Organic Light Emitting Device

Meanwhile, according to the present disclosure, there is provided an organic light emitting device comprising a first electrode; a second electrode that is provided opposite to the first electrode; and one or more organic material layers that are provided between the first electrode and the second electrode, wherein one or more layers of the organic material layers comprises the composition for an organic light emitting device. In such an organic light emitting device, the composition may be supplied via a single source during the formation of the organic layer.

Wherein, the organic layer comprising the composition may be a light emitting layer.

Furthermore, the first electrode may be an anode, and the second electrode may be a cathode. Alternatively, the first electrode may be a cathode, and the second electrode may be an anode.

Further, according to the present disclosure, there is provided an organic light emitting device comprising an anode; a cathode which is provided opposite to the anode; and a light emitting layer which is interposed between the anode and the cathode, wherein the light emitting layer includes the first compound represented by the following Chemical Formula 1, and the second compound represented by the following Chemical Formula 2.

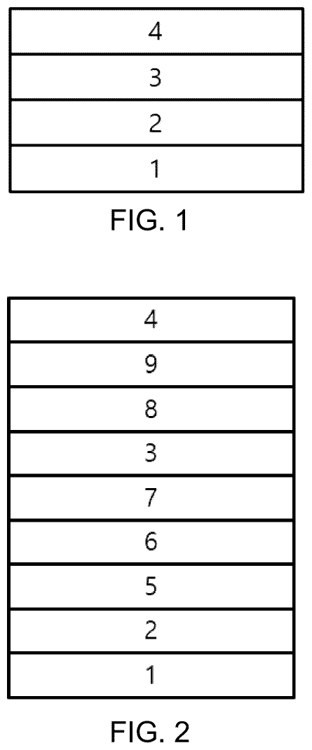

The organic light emitting device according to the present disclosure is illustrated in FIG. 1. FIG. 1 shows an example of an organic light emitting device comprising a substrate 1, an anode 2, a light emitting layer 3, and a cathode 4. In such a structure, the first compound and the second compound can be included in the light emitting layer.

FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron injection and transport layer 9, and a cathode 4. In such a structure, the first compound and the second compound can be included in the light emitting layer.

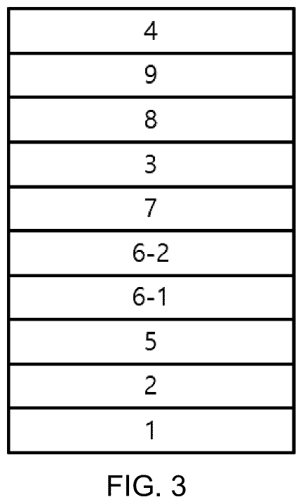

FIG. 3 shows an example of an organic light emitting device comprising a substrate 1, an anode 2, a hole injection layer 5, a first hole transport layer 6-1, a second hole transport layer 6-2, an electron blocking layer 7, a light emitting layer 3, a hole blocking layer 8, an electron injection and transport layer 9, and a cathode 4. In such a structure, the first compound and the second compound can be included in the light emitting layer.

The organic light emitting device according to the present disclosure can be manufactured by sequentially stacking the above-described structures. In this case, the organic light emitting device may be manufactured by depositing a metal, metal oxides having conductivity, or an alloy thereof on the substrate by using a PVD (physical vapor deposition) method such as a sputtering method or an e-beam evaporation method to form the anode, forming the respective layers described above thereon, and then depositing a material that can be used as the cathode thereon. In addition to such a method, the organic light emitting device can be manufactured by sequentially depositing from the cathode material to the anode material on a substrate. Further, the light emitting layer may be formed by subjecting hosts and dopants to a vacuum deposition method and a solution coating method. Herein, the solution coating method means a spin coating, a dip coating, a doctor blading, an inkjet printing, a screen printing, a spray method, a roll coating, or the like, but is not limited thereto.

In addition to such a method, the organic light emitting device can be manufactured by sequentially depositing a cathode material, an organic material layer and an anode material on a substrate (International Publication WO2003/012890). However, the manufacturing method is not limited thereto.

The organic light emitting device according to the present disclosure may be a bottom emission type device, a top emission type device, or a double side emission type device, and in particular, it may be a bottom emission type light emitting device that requires relatively high luminous efficiency.

The preparation of the compound represented by Chemical Formula 1, the compound represented by Chemical Formula 2 and the organic light emitting device including the same will be specifically described in the following Examples. However, the following Examples are provided for illustrative purposes only, and are not intended to limit the scope of the present disclosure.

Hereinafter, each component of the organic light emitting device is described in detail.

### (Anode and Cathode)

As the anode material, generally, a material having a large work function is preferably used so that holes can be smoothly injected into the organic material layer. Specific examples of the anode material include metals such as vanadium, chrome, copper, zinc, and gold, or an alloy thereof; metal oxides such as zinc oxides, indium oxides, indium tin oxides (ITO), and indium zinc oxides (IZO); a combination of metals and oxides, such as ZnO:Al or SnO₂:Sb; conductive polymers such as poly(3-methylthiophene), poly[3,4-(ethylene-1,2-dioxy)thiophene](PEDOT), polypyrrole, and polyaniline, and the like, but are not limited thereto.

As the cathode material, generally, a material having a small work function is preferably used so that electrons can be easily injected into the organic material layer. Specific examples of the cathode material include metals such as magnesium, calcium, sodium, potassium, titanium, indium, yttrium, lithium, gadolinium, aluminum, silver, tin, and lead, or an alloy thereof; a multilayered structure material such as LiF/Al or LiO₂/Al, and the like, but are not limited thereto.

### (Hole Injection Layer)

The organic light emitting device according to the present disclosure may include a hole injection layer between an anode and a hole transport layer described hereinafter, if necessary.

The hole injection layer is a layer that is located on the anode and injects holes from the anode, which includes a hole injection material. The hole injection material is preferably a compound which has a capability of transporting the holes, a hole injection effect in the anode and an excellent hole injection effect to the light emitting layer or the light emitting material, prevents movement of an exciton generated in the light emitting layer to the electron injection layer or the electron injection material, and has an excellent thin film forming ability. In particular, it is suitable that a HOMO (highest occupied molecular orbital) of the hole injection material is between the work function of the anode material and a HOMO of a peripheral organic material layer.

Specific examples of the hole injection material include metal porphyrin, oligothiophene, an arylamine-based organic material, a hexanitrile-hexaazatriphenylene-based organic material, a quinacridone-based organic material, a perylene-based organic material, anthraquinone, polyaniline and polythiophene-based conductive polymer, and the like, but are not limited thereto.

### (Hole Transport Layer)

The organic light emitting device according to the present disclosure may include a hole transport layer between the anode and the light emitting layer. The hole transport layer is a layer that receives holes from an anode or a hole injection layer formed on the anode and transports the holes to the light emitting layer, which includes a hole transport material. The hole transport material is suitably a material having large mobility to the holes, which may receive holes from the anode or the hole injection layer and transfer the holes to the light emitting layer. Specific examples thereof may include an arylamine-based organic material, a conductive polymer, a block copolymer in which a conjugate portion and a non-conjugate portion are present together, and the like, but are not limited thereto.

### (Electron Blocking Layer)

The organic light emitting device according to the present disclosure may include an electron blocking layer between the hole transport layer and the light emitting layer, if necessary. The electron blocking layer refers to a layer which is formed on the hole transport layer, preferably provided in contact with the light emitting layer, and serves to adjust the hole mobility, prevent excessive movement of electrons, and increase the probability of hole-electron coupling, thereby improving the efficiency of the organic light emitting device. The electron blocking layer includes an electron blocking material, and examples of such an electron blocking material may include an arylamine-based organic material or the like, but is not limited thereto.

### (Light Emitting Layer)

The organic light emitting device according to the present disclosure may include a light emitting layer between an anode and a cathode, and the light emitting layer includes the first compound and the second compound as the host material Specifically, the first compound can function as a P-type host material in which an electron transport capability is superior to a hole transport capability, and the second compound can function as an N-type host material in which a hole transport capability is superior to an electron transport capability, and thus can properly maintain the ratio of holes to electrons in the light emitting layer. Accordingly, excitons emit light evenly throughout the light emitting layer, so that the light emitting efficiency and lifetime characteristics of the organic light emitting device can be improved at the same time.

In particular, the second compound does not have a “cyano group” as a substituent for Ar. More specifically, the second compound does not have a cyano group. When the second compound has a cyano group, the stability in a radical state may be reduced due to the cyano group, and the lifespan of an organic light emitting device using such a compound may be drastically reduced.

On the other hand, the light emitting layer may further include a dopant material in addition to the two types of host materials of the first compound and the second compound. Such a dopant material includes an aromatic amine derivative, a styrylamine compound, a boron complex, a fluoranthene compound, a metal complex, and the like. Specific examples of the aromatic amine derivative include substituted or unsubstituted fused aromatic ring derivatives having a substituted or unsubstituted arylamino group, examples of which include pyrene, anthracene, chrysene, and periflanthene having the arylamino group, and the like. The styrylamine compound is a compound where at least one arylvinyl group is substituted in a substituted or unsubstituted arylamine, in which one or two or more substituent groups selected from the group consisting of an aryl group, a silyl group, an alkyl group, a cycloalkyl group, and an arylamino group are substituted or unsubstituted. Specific examples thereof include styrylamine, styryldiamine, styryltriamine, styryltetramine, and the like, but are not limited thereto. Further, examples of the metal complex include an iridium complex, a platinum complex, and the like, but are not limited thereto.

More specifically, the light emitting layer further includes a dopant material, and the dopant material may include an iridium complex compound.

For example, the following compounds may be used as the dopant material, but are not limited thereto:

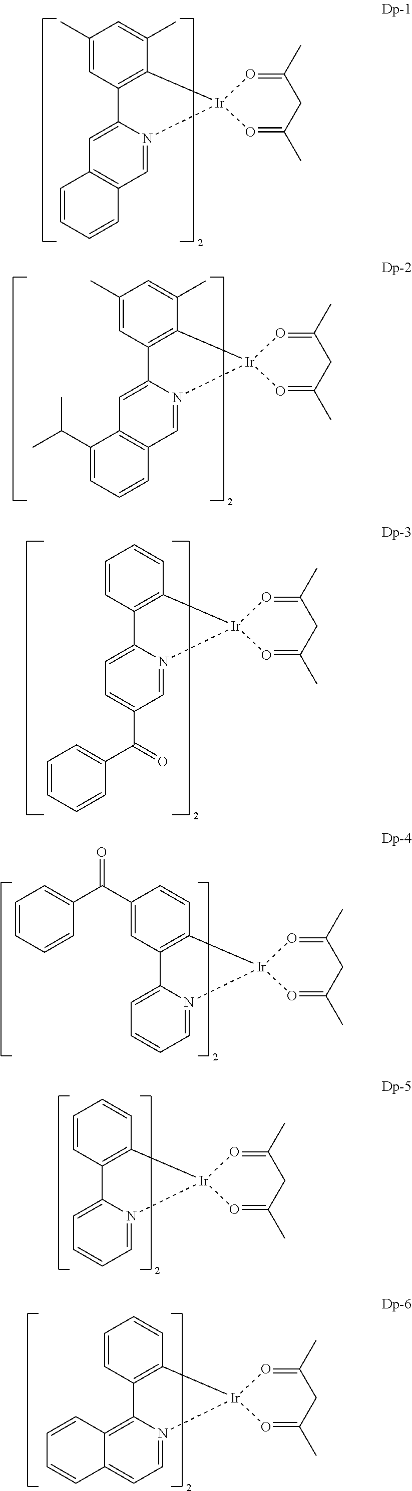

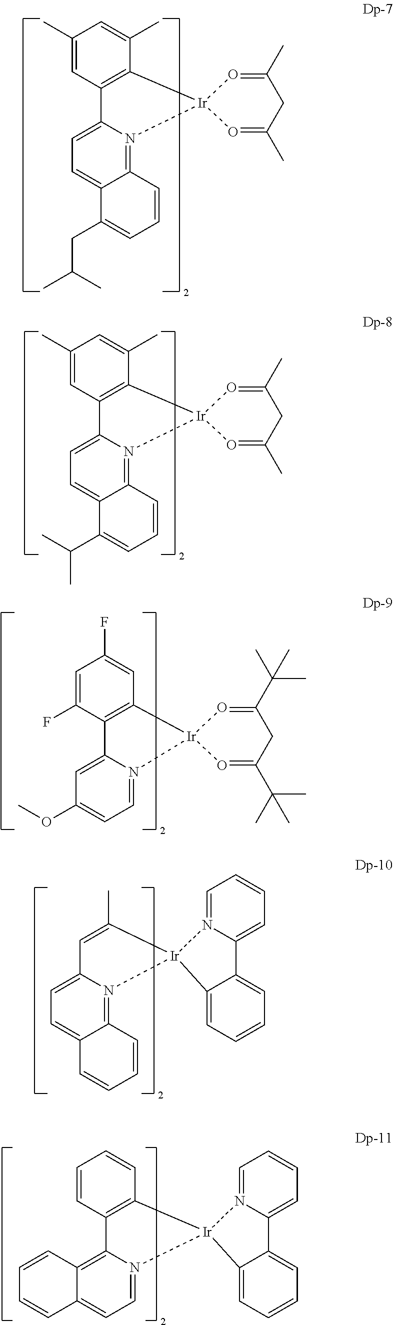

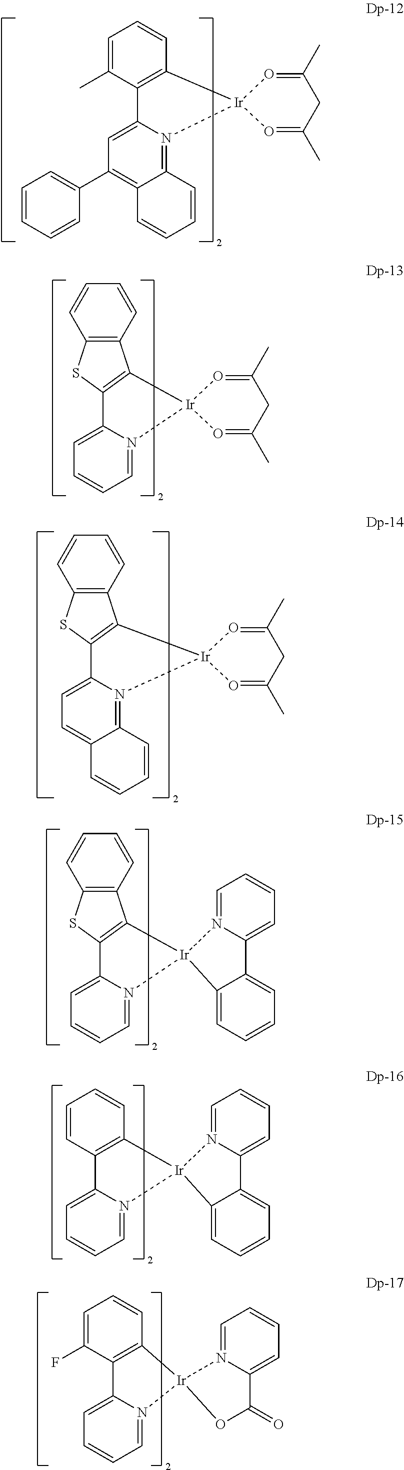

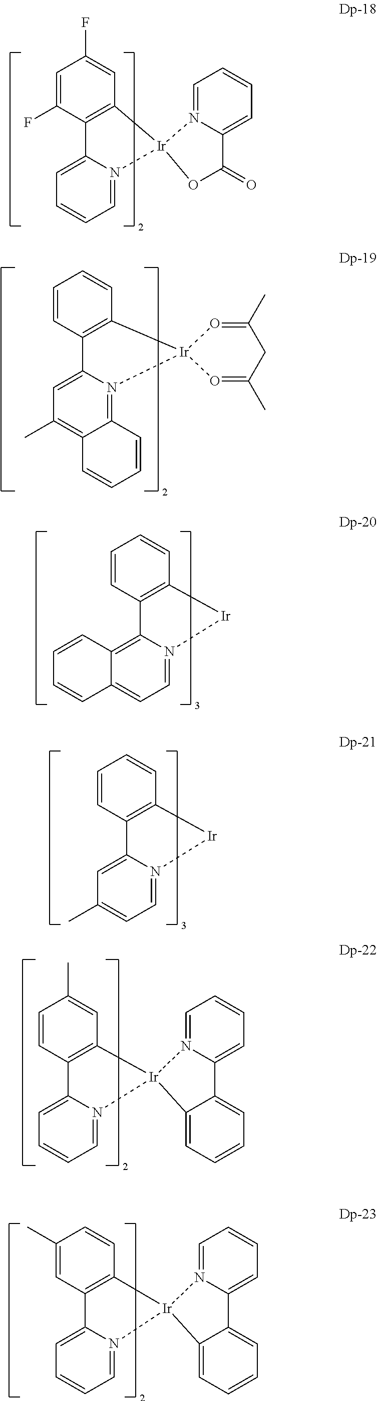

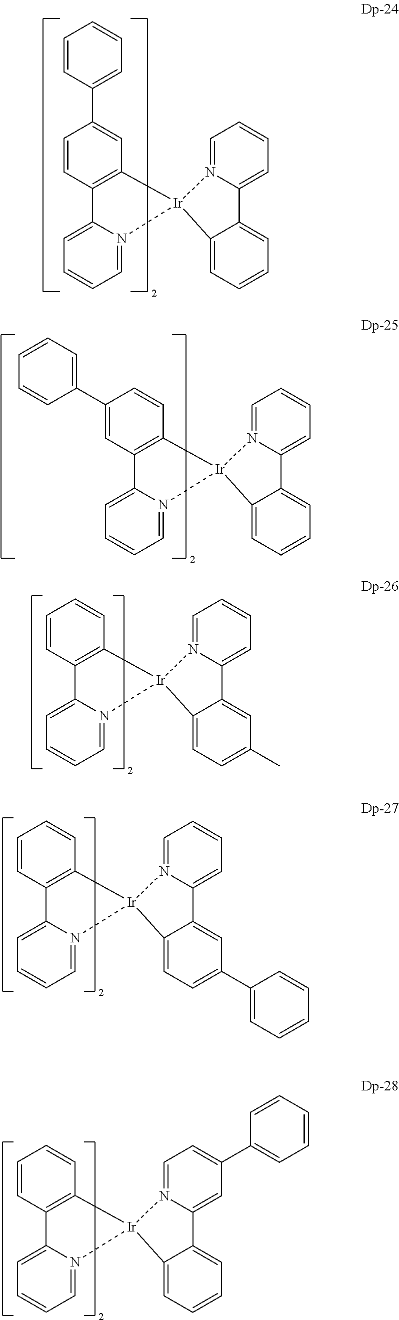

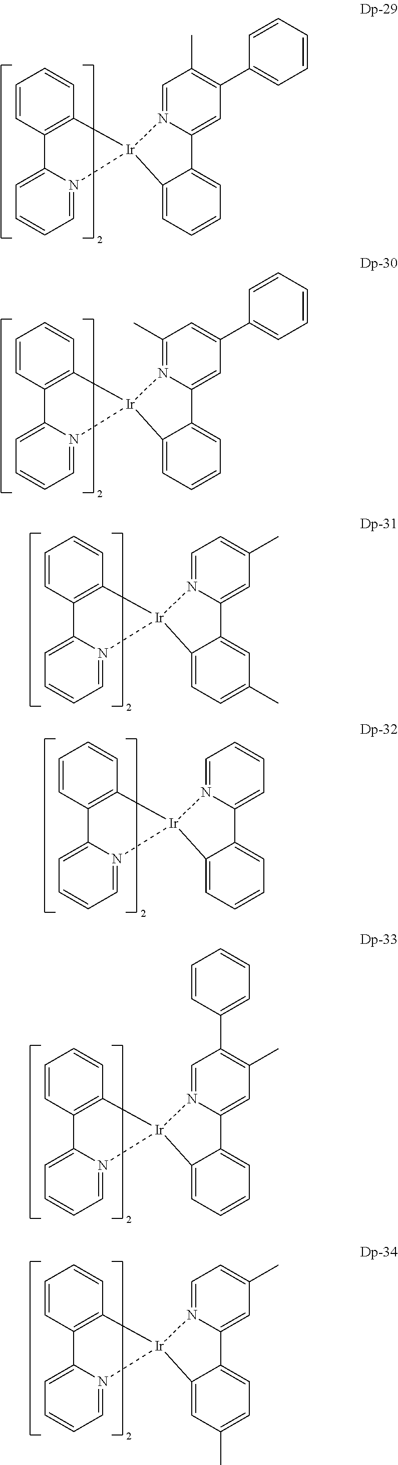

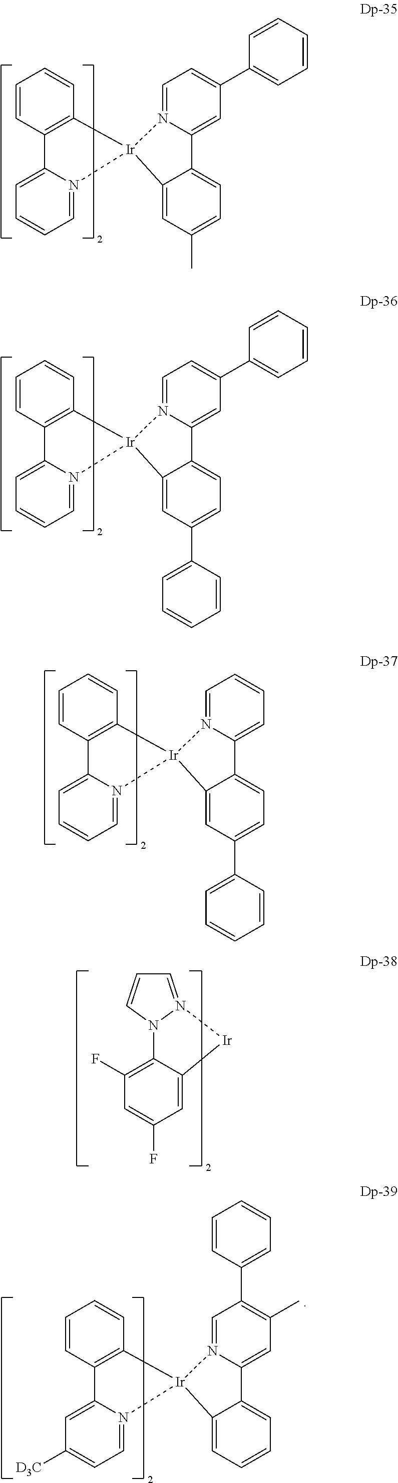

At this time, the ratio of (the sum of the weights of the first compound and the second compound) and (the weight of the dopant material) may be 99:1 to 90:10. More specifically, the ratio of (the sum of the weights of the first compound and the second compound) and (the weight of the dopant material) may be 97:3 to 93:7, or 95:5.

### Hole Blocking Layer

The organic light emitting device according to the present disclosure may include a hole blocking layer between the light emitting layer and an electron transport layer described hereinafter, if necessary. The hole blocking layer refers to a layer which is formed on the light emitting layer, preferably provided in contact with the light emitting layer, and serves to adjust the electron mobility, prevent excessive movement of holes, and increase the probability of hole-electron coupling, thereby improving the efficiency of the organic light emitting device. The hole blocking layer includes a hole blocking material, and examples of such hole blocking material may include a compound having an electron withdrawing group introduced therein, such as azine derivatives including triazine; triazole derivatives; oxadiazole derivatives; phenanthroline derivatives; phosphine oxide derivatives, but is not limited thereto.

### Electron Injection and Transport Layer

The electron injection and transport layer is a layer for simultaneously performing the roles of an electron transport layer and an electron injection layer that inject electrons from an electrode and transport the received electrons up to the light emitting layer, and is formed on the light emitting layer or the hole blocking layer. The electron injection and transport material is suitably a material which can receive electrons well from a cathode and transfer the electrons to a light emitting layer, and has a large mobility for electrons. Specific examples of the electron injection and transport material include: an Al complex of 8-hydroxyquinoline; a complex including Alq₃; an organic radical compound; a hydroxyflavone-metal complex, a triazine derivative, and the like, but are not limited thereto. Alternatively, it may be used together with fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like, but are not limited thereto.

The electron injection and transport layer may also be formed as a separate layer such as an electron injection layer and an electron transport layer. In such a case, the electron transport layer is formed on the light emitting layer or the hole blocking layer, and the above-mentioned electron injection and transport material may be used as the electron transport material included in the electron transport layer. In addition, the electron injection layer is formed on the electron transport layer, and examples of the electron injection material included in the electron injection layer include LiF, NaCl, CsF, Li₂O, BaO, fluorenone, anthraquinodimethane, diphenoquinone, thiopyran dioxide, oxazole, oxadiazole, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like.

Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-hydroxyquinolinato)(2-naphtholato)gallium, and the like, but are not limited thereto.

The preparation of the compound represented by Chemical Formula 1, the compound represented by Chemical Formula 2 and the organic light emitting device including the same will be specifically described in the following Examples. However, the following Examples are provided for illustrative purposes only, and are not intended to limit the scope of the present disclosure.

### Preparation Example

### Preparation Example 1: Preparation of Compound 1-1

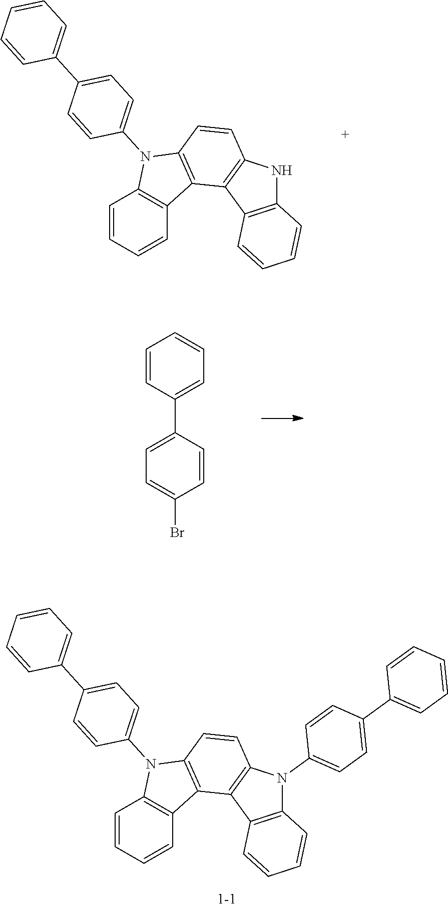 [SMILES: c1ccc(-c2ccc(-n3c4ccccc4c4c5c(ccc43)[nH]c3ccccc35)cc2)cc1 ; Brc1ccc(-c2ccccc2)cc1 ; c1ccc(-c2ccc(-n3c4ccccc4c4c5c6ccccc6n(-c6ccc(-c7ccccc7)cc6)c5ccc43)cc2)cc1]

5-([1,1′-biphenyl]-4-yl)-5,8-dihydroindolo[2,3-c]carbazole (10 g, 24.5 mmol) and 4-bromo-1,1′-biphenyl (5.7 g, 24.5 mmol) were added to 200 mL of xylene under a nitrogen atmosphere, and the mixture was stirred and refluxed. Then, sodium tert-butoxide (7.1 g, 73.4 mmol) was added thereto, stirred sufficiently, and bis(tri-tert-butylphosphine)palladium (0.4 g, 0.7 mmol) was added thereto. After 3 hours of reaction, the mixture was cooled to room temperature and the resulting solid was filtered. The solid was dissolved in 412 mL of chloroform, washed twice with water, and the organic layer was distilled under reduced pressure. Then, Anhydrous magnesium sulfate was added thereto and stirred, and then filtering, and the filtrate was distilled under reduced pressure. The concentrated compound was recrystallized from chloroform and ethyl acetate to produce a white solid compound 1-1 (8.6 g, 63%, MS: [M+H]⁺=561.7)

### Preparation Example 2: Preparation of Compound 1-2

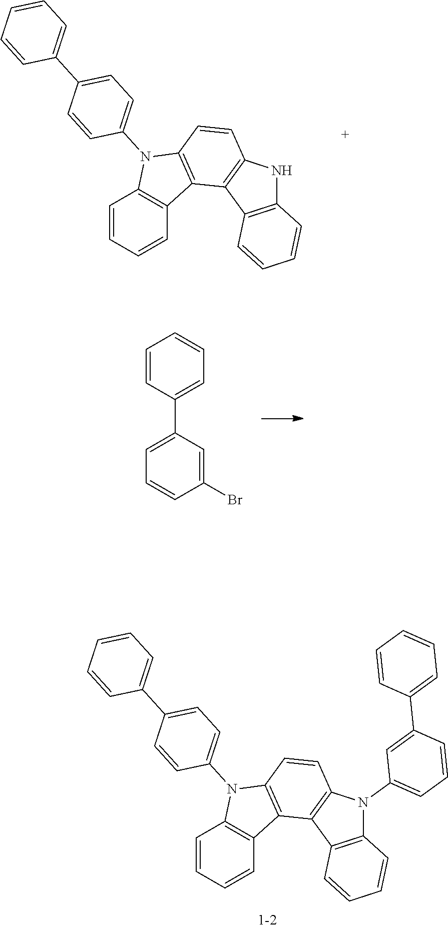 [SMILES: c1ccc(-c2ccc(-n3c4ccccc4c4c5c(ccc43)[nH]c3ccccc35)cc2)cc1 ; Brc1cccc(-c2ccccc2)c1 ; c1ccc(-c2ccc(-n3c4ccccc4c4c5c6ccccc6n(-c6cccc(-c7ccccc7)c6)c5ccc43)cc2)cc1]

A white solid compound 1-2 was prepared in the same manner as in Preparation Example 1, except that 3-bromo-1,1′-biphenyl was used instead of 4-bromo-1,1′-biphenyl (6.6 g, 48%, MS: [M+H]⁺=561.7).

### Preparation Example 3: Preparation of Compound 1-3

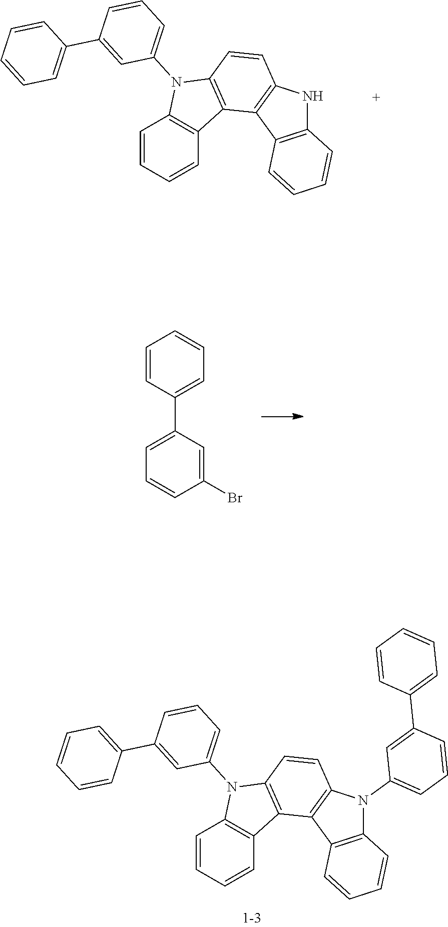 [SMILES: c1ccc(-c2cccc(-n3c4ccccc4c4c5c(ccc43)[nH]c3ccccc35)c2)cc1 ; Brc1cccc(-c2ccccc2)c1 ; c1ccc(-c2cccc(-n3c4ccccc4c4c5c6ccccc6n(-c6cccc(-c7ccccc7)c6)c5ccc43)c2)cc1]

A white solid compound 1-3 was prepared in the same manner as in Preparation Example 1, except that 5-([1,1′-biphenyl]-4-yl)-5,8-dihydroindolo[2,3-c]carbazole was used instead of 5-([1,1′-biphenyl]-3-yl)-5,8-dihydroindolo[2,3-c]carbazole and 3-bromo-1,1′-biphenyl was used instead of 4-bromo-1,1′-biphenyl (7.5 g, 55%, MS: [M+H]⁺=561.7)

### Preparation Example 4: Preparation of Compound 1-4

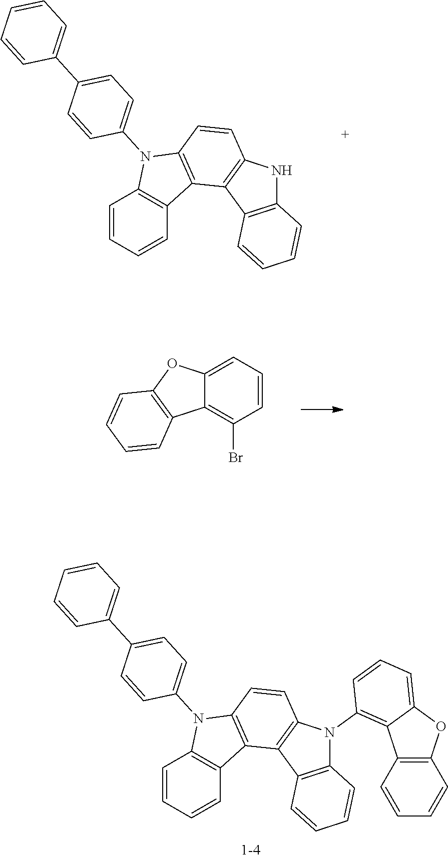 [SMILES: c1ccc(-c2ccc(-n3c4ccccc4c4c5c(ccc43)[nH]c3ccccc35)cc2)cc1 ; Brc1cccc2oc3ccccc3c12 ; c1ccc(-c2ccc(-n3c4ccccc4c4c5c6ccccc6n(-c6cccc7oc8ccccc8c67)c5ccc43)cc2)cc1]

A white solid compound 1-4 was prepared in the same manner as in Preparation Example 1, except that 1-bromodibenzo[b,d]furan was used instead of 4-bromo-1,1′-biphenyl (8.6 g, 61%, MS: [M+H]⁺=575.7).

### Preparation Example 5: Preparation of Compound 1-5

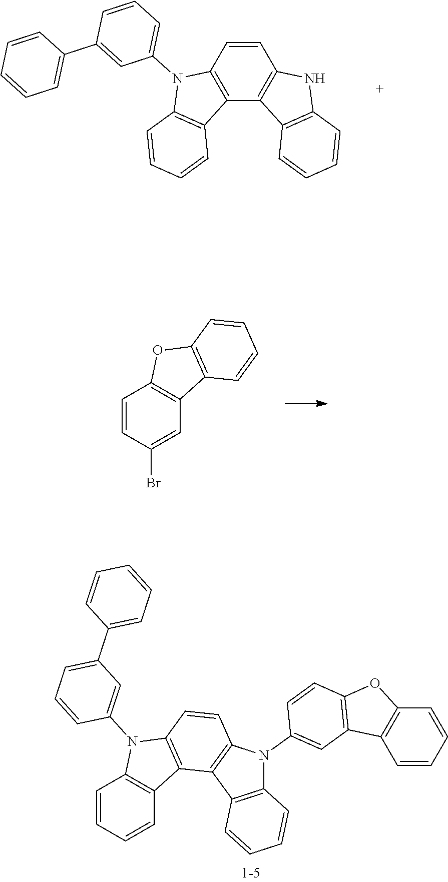 [SMILES: c1ccc(-c2cccc(-n3c4ccccc4c4c5c(ccc43)[nH]c3ccccc35)c2)cc1 ; Brc1ccc2oc3ccccc3c2c1 ; c1ccc(-c2cccc(-n3c4ccccc4c4c5c6ccccc6n(-c6ccc7oc8ccccc8c7c6)c5ccc43)c2)cc1]

A white solid compound 1-5 was prepared in the same manner as in Preparation Example 1, except that 5-([1,1′-biphenyl]-3-yl)-5,8-dihydroindolo[2,3-c]carbazole was used instead of 5-([1,1′-biphenyl]-4-yl)-5,8-dihydroindolo[2,3-c]carbazole, and 2-bromodibenzo[b,d]furan was used instead of 4-bromo-1,1′-biphenyl (5.8 g, 41%, MS: [M+H]⁺=575.7)

### Preparation Example 6: Preparation of Compound 1-6

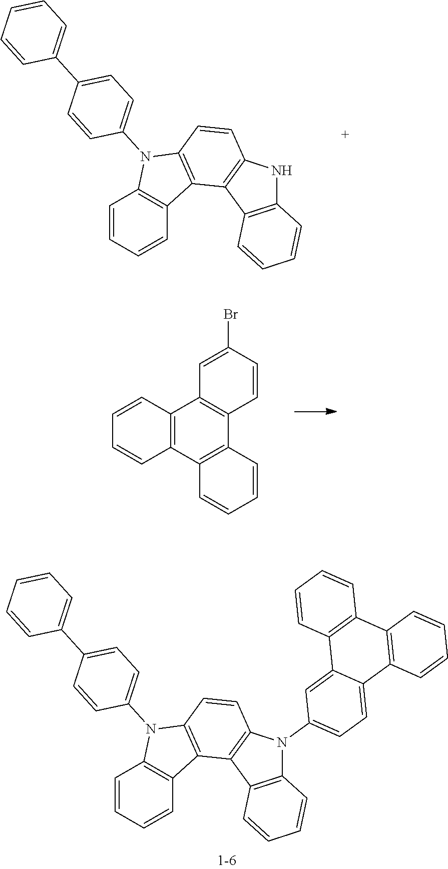 [SMILES: c1ccc(-c2ccc(-n3c4ccccc4c4c5c(ccc43)[nH]c3ccccc35)cc2)cc1 ; Brc1ccc2c3ccccc3c3ccccc3c2c1 ; c1ccc(-c2ccc(-n3c4ccccc4c4c5c6ccccc6n(-c6ccc7c8ccccc8c8ccccc8c7c6)c5ccc43)cc2)cc1]

A white solid compound 1-6 was prepared in the same manner as in Preparation Example 1, except that 2-bromotriphenylene was used instead of 4-bromo-1,1′-biphenyl (11 g, 71%, MS: [M+H]⁺=635.8).

### Preparation Example 7: Preparation of Compound 1-7

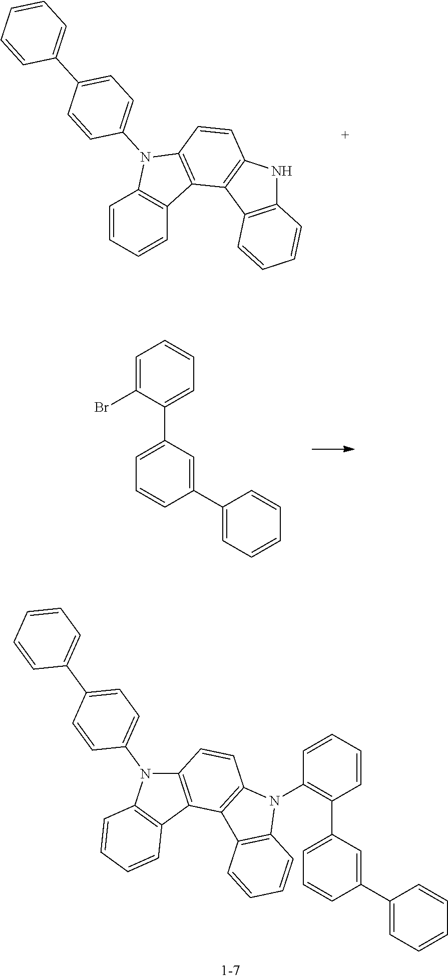 [SMILES: c1ccc(-c2ccc(-n3c4ccccc4c4c5c(ccc43)[nH]c3ccccc35)cc2)cc1 ; Brc1ccccc1-c1cccc(-c2ccccc2)c1 ; c1ccc(-c2ccc(-n3c4ccccc4c4c5c6ccccc6n(-c6ccccc6-c6cccc(-c7ccccc7)c6)c5ccc43)cc2)cc1]

A white solid compound 1-7 was prepared in the same manner as in Preparation Example 1, except that 2-bromo-1,1′: 3′,1″-terphenyl was used instead of 4-bromo-1,1′-biphenyl (8.3 g, 53%, MS: [M+H]⁺=637.8).

### Preparation Example 8: Preparation of Compound 1-8

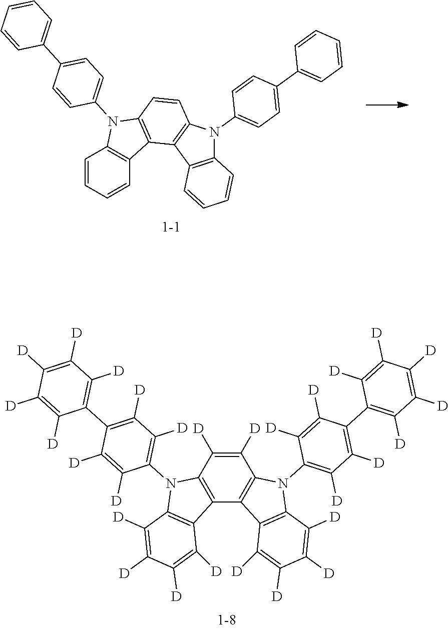 [SMILES: c1ccc(-c2ccc(-n3c4ccccc4c4c5c6ccccc6n(-c6ccc(-c7ccccc7)cc6)c5ccc43)cc2)cc1 ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c(-c7c([2H])c([2H])c([2H])c([2H])c7[2H])c([2H])c6[2H])c5c([2H])c([2H])c43)c([2H])c2[2H])c([2H])c1[2H]]

Compound 1-1 (10 g, 17.8 mmol) and TfOH (2 mL) were added to C₆D₆ (100 mL) and stirred at 40° C. for 4 hours under a nitrogen atmosphere, and the mixture was stirred. After the reaction was completed, the temperature was lowered to room temperature, D₂O (20 mL) was added thereto, stirred for 30 minutes, and then trimethylamine (2.4 mL) was added dropwise. The reaction solution was transferred to a separatory funnel, extracted with water and chloroform, then anhydrous magnesium sulfate was added thereto and stirred, and then filtering, and the filtrate was distilled under reduced pressure. The concentrated compound was recrystallized from chloroform and ethyl acetate to produce a white solid compound 1-8 (7.9 g, 76%, MS: [M+H]⁺=587).

### Preparation Example 9: Preparation of Compound 1-9

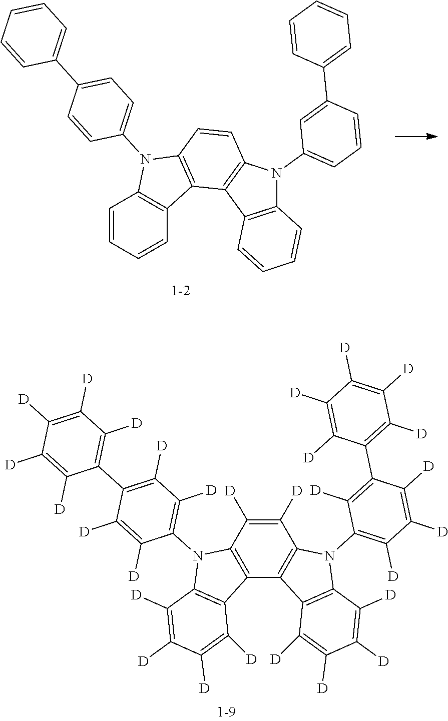 [SMILES: c1ccc(-c2ccc(-n3c4ccccc4c4c5c6ccccc6n(-c6cccc(-c7ccccc7)c6)c5ccc43)cc2)cc1 ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c([2H])c(-c7c([2H])c([2H])c([2H])c([2H])c7[2H])c6[2H])c5c([2H])c([2H])c43)c([2H])c2[2H])c([2H])c1[2H]]

A white solid compound 1-9 was prepared in the same manner as in Preparation Example 8, except that 1-2 was used instead of compound 1-1 (7.4 g, 71%, MS: [M+H]⁺=587).

### Preparation Example 10: Preparation of Compound 1-10

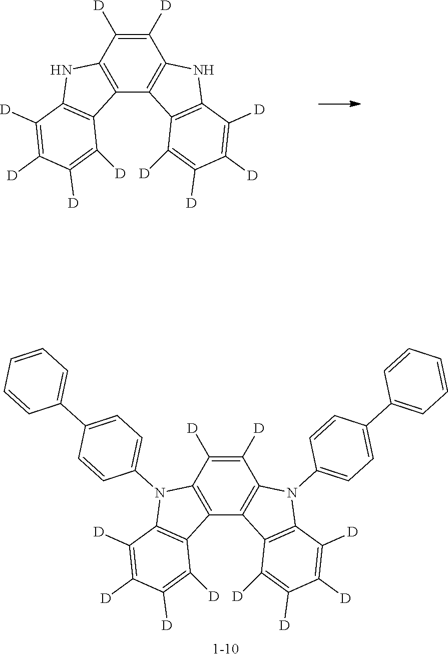 [SMILES: [2H]c1c([2H])c([2H])c2c([nH]c3c([2H])c([2H])c4[nH]c5c([2H])c([2H])c([2H])c([2H])c5c4c32)c1[2H] ; [2H]c1c([2H])c([2H])c2c(c1[2H])c1c3c4c([2H])c([2H])c([2H])c([2H])c4n(-c4ccc(-c5ccccc5)cc4)c3c([2H])c([2H])c1n2-c1ccc(-c2ccccc2)cc1]

5,8-dihydroindolo[2,3-c]carbazole-1,2,3,4,6,7,9,10,11,12-d10 (10 g, 37.8 mmol) and 4-bromo-1,1′-biphenyl (17.6 g, 75.6 mmol) were added to 200 mL of xylene under a nitrogen atmosphere, and the mixture was stirred and refluxed. Then, sodium tert-butoxide (21.8 g, 227.0 mmol) was added thereto, stirred sufficiently, and bis(tri-tert-butylphosphine)palladium (2 g, 3.8 mmol) was added thereto. After 3 hours of reaction, the mixture was cooled to room temperature and the resulting solid was filtered. The solid was dissolved in 645 mL of chloroform, washed twice with water, and the organic layer was separate. Then, Anhydrous magnesium sulfate was added thereto and stirred, and then filtering, and the filtrate was distilled under reduced pressure. The concentrated compound was recrystallized from chloroform and ethyl acetate to produce a white solid compound 1-10 (17.2 g, 80%, MS: [M+H]⁺=569.8).

### Preparation Example 11: Preparation of Compound 1-11

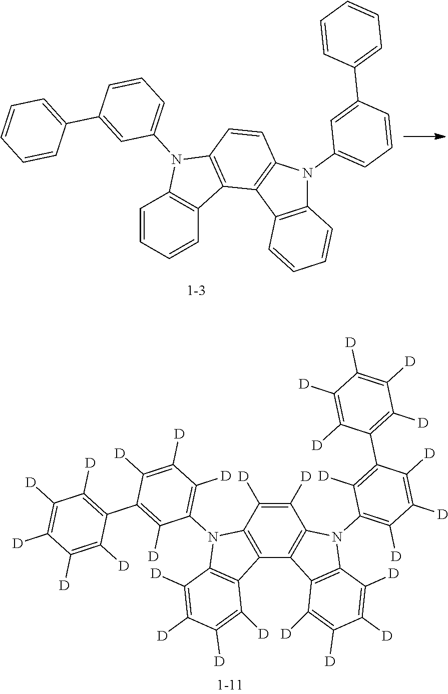 [SMILES: c1ccc(-c2cccc(-n3c4ccccc4c4c5c6ccccc6n(-c6cccc(-c7ccccc7)c6)c5ccc43)c2)cc1 ; [2H]c1c([2H])c([2H])c(-c2c([2H])c([2H])c([2H])c(-n3c4c([2H])c([2H])c([2H])c([2H])c4c4c5c6c([2H])c([2H])c([2H])c([2H])c6n(-c6c([2H])c([2H])c([2H])c(-c7c([2H])c([2H])c([2H])c([2H])c7[2H])c6[2H])c5c([2H])c([2H])c43)c2[2H])c([2H])c1[2H]]

Compound 1-3 (10 g, 17.8 mmol) and TfOH (2 mL) were added to C₆D₆ (100 mL) under a nitrogen atmosphere, and the mixture was stirred at 40° C. for 3 hours. After the reaction was completed, the temperature was lowered to room temperature, D₂O (20 mL) was added thereto, stirred for 30 minutes, and then trimethylamine (2.4 mL) was added dropwise. The reaction solution was transferred to a separatory funnel, extracted with water and chloroform, and then anhydrous magnesium sulfate was added thereto and stirred, and then filtering, and the filtrate was distilled under reduced pressure. The concentrated compound was recrystallized from chloroform and hexane to produce a white solid compound 1-11 (7.4 g, 71%, MS: [M+H]⁺=587).

### Preparation Example 12: Preparation of Compound 2-1

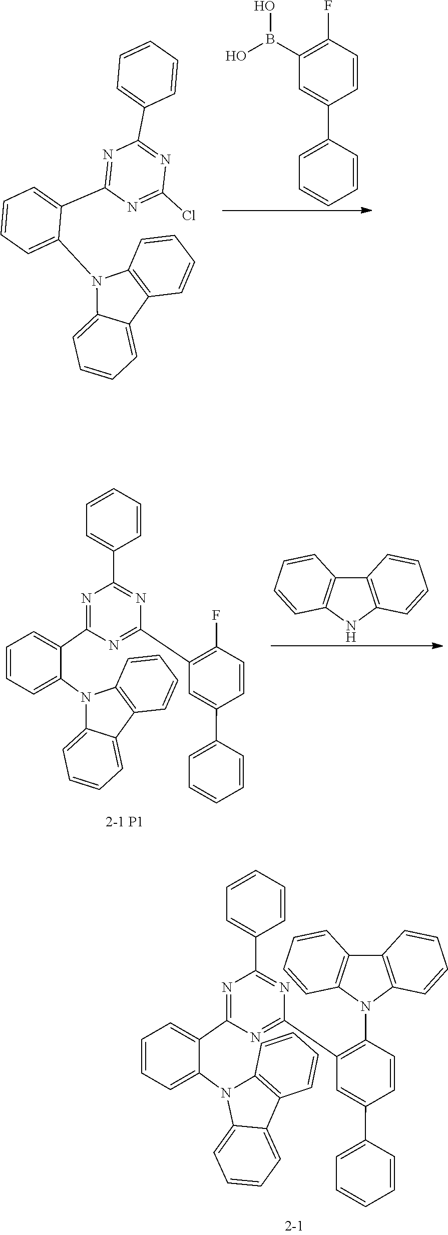 [SMILES: Clc1nc(-c2ccccc2)nc(-c2ccccc2-n2c3ccccc3c3ccccc32)n1 ; OB(O)c1cc(-c2ccccc2)ccc1F ; Fc1ccc(-c2ccccc2)cc1-c1nc(-c2ccccc2)nc(-c2ccccc2-n2c3ccccc3c3ccccc32)n1 ; c1ccc2c(c1)[nH]c1ccccc12 ; c1ccc(-c2ccc(-n3c4ccccc4c4ccccc43)c(-c3nc(-c4ccccc4)nc(-c4ccccc4-n4c5ccccc5c5ccccc54)n3)c2)cc1]

### (Preparation Example 12-1) Preparation of Compound 2-1 P1

9-(2-(4-chloro-6-phenyl-1,3,5-triazin-2-yl)phenyl)-9H-carbazole (30 g, 69.3 mmol) and (4-fluoro-[1,1′-biphenyl]-3-yl)boronic acid (15 g, 69.3 mmol) were added to 600 mL of tetrahydrofuran under a nitrogen atmosphere, and the mixture was stirred and refluxed. Then, potassium carbonate (28.7 g, 207.9 mmol) dissolved in 29 mL of water was added thereto, stirred sufficiently, and tetrakistriphenyl-phosphinopalladium (2.4 g, 2.1 mmol) was added thereto. After 1 hour of reaction, the mixture was cooled to room temperature and the resulting solid was filtered. The solid was added to 1970 mL of chloroform, dissolved, washed twice with water, and the organic layer was separated. Then, Anhydrous magnesium sulfate was added thereto and stirred, and then filtering, and the filtrate was distilled under reduced pressure. The concentrated compound was recrystallized from chloroform and ethyl acetate to produce a white solid compound 2-1 P1 (25.6 g, 65%, MS: [M+H]⁺=569.7).

### (Preparation Example 12-2) Preparation of Compound 2-1

2-1 P1 (10 g, 17.6 mmol) and 9H-carbazole (2.9 g, 17.6 mmol) were added to 100 mL of dimethylformamide under a nitrogen atmosphere, and the mixture was stirred and refluxed. After confirming complete dissolution, potassium triphosphate (11.2 g, 52.8 mmol) was added thereto. After 4 hours of reaction, the mixture was cooled to room temperature and the resulting solid was filtered. The solid was dissolved in 378 mL of chloroform, washed twice with water, and the organic layer was separated. Anhydrous magnesium sulfate was added thereto, stirred, and then filtering, and the filtrate was distilled under reduced pressure. The concentrated compound was purified through a silica column using chloroform and ethyl acetate to produce a yellow solid compound 2-1 (6.8 g, 54%, MS: [M+H]⁺=716.9).

### Preparation Example 13: Preparation of Compound 2-2

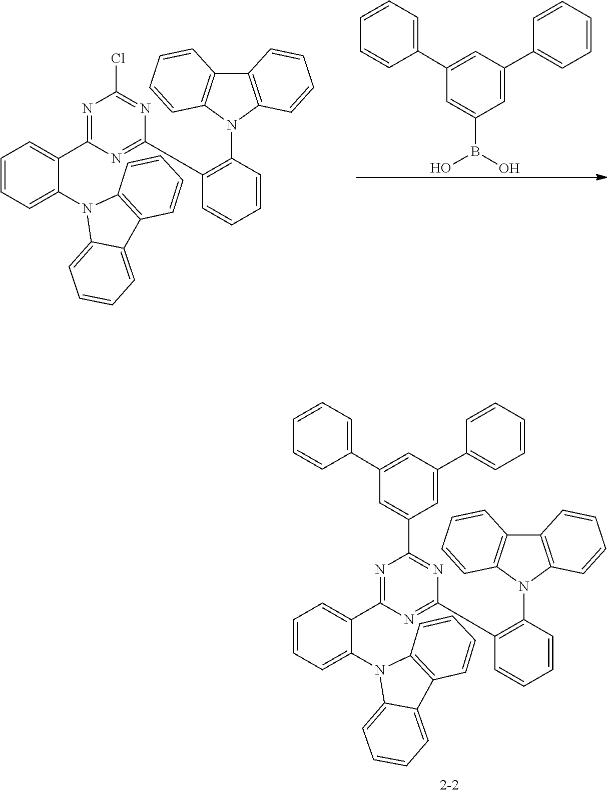 [SMILES: Clc1nc(-c2ccccc2-n2c3ccccc3c3ccccc32)nc(-c2ccccc2-n2c3ccccc3c3ccccc32)n1 ; OB(O)c1cc(-c2ccccc2)cc(-c2ccccc2)c1 ; c1ccc(-c2cc(-c3ccccc3)cc(-c3nc(-c4ccccc4-n4c5ccccc5c5ccccc54)nc(-c4ccccc4-n4c5ccccc5c5ccccc54)n3)c2)cc1]

9,9′-((6-chloro-1,3,5-triazine-2,4-diyl)bis(2,1-phenylene))bis(9H-carbazole) (30 g, 50.2 mmol) and [1,1′: 3′,1″-terphenyl]-5′-ylboronic acid (13.7 g, 50.2 mmol) were added to 600 mL of tetrahydrofuran under a nitrogen atmosphere, and the mixture was stirred and refluxed. Then, potassium carbonate (20.8 g, 150.5 mmol) dissolved in 21 mL of water was added, and after sufficient stirring, tetrakistriphenyl-phosphinopalladium (1.7 g, 1.5 mmol) was added thereto. After 1 hour of reaction, the mixture was cooled to room temperature and the resulting solid was filtered. The solid was dissolved in 1986 mL of chloroform, washed twice with water, the organic layer was separated, anhydrous magnesium sulfate was added thereto and stirred, and then filtering, and the filtrate was distilled under reduced pressure. The concentrated compound was recrystallized from chloroform and ethyl acetate to produce a yellow solid compound 2-2 (30.6 g, 77%, MS: [M+H]⁺=793).

### Preparation Example 14: Preparation of Compound 2-3

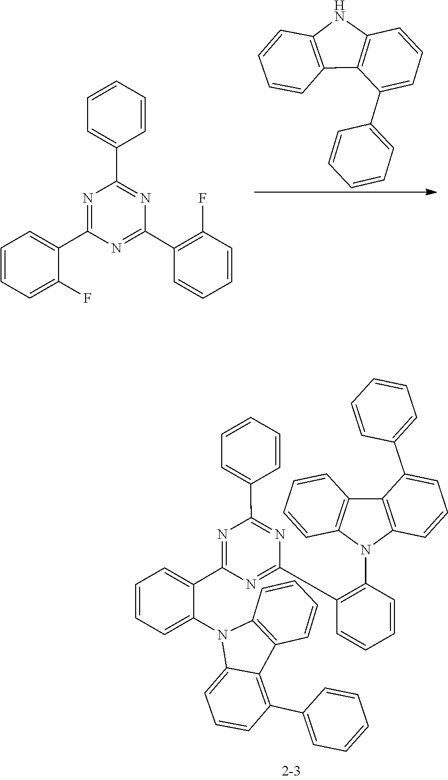 [SMILES: Fc1ccccc1-c1nc(-c2ccccc2)nc(-c2ccccc2F)n1 ; c1ccc(-c2cccc3[nH]c4ccccc4c23)cc1 ; c1ccc(-c2nc(-c3ccccc3-n3c4ccccc4c4c(-c5ccccc5)cccc43)nc(-c3ccccc3-n3c4ccccc4c4c(-c5ccccc5)cccc43)n2)cc1]

2,4-bis(2-fluorophenyl)-6-phenyl-1,3,5-triazine (10 g, 29 mmol) and 4-phenyl-9H-carbazole (7 g, 29 mmol) were added to 100 mL of dimethylformamide under a nitrogen atmosphere, and the mixture was stirred and refluxed. After confirming complete dissolution, potassium triphosphate (18.4 g, 86.9 mmol) was added thereto. After 2 hours of reaction, the mixture was cooled to room temperature and the resulting solid was filtered. The solid was dissolved in 688 mL of chloroform, washed twice with water, and the organic layer was separated. Anhydrous magnesium sulfate was added thereto, stirred, and then filtering, and the filtrate was distilled under reduced pressure. The concentrated compound was purified through a silica column using chloroform and ethyl acetate to produce a yellow solid compound 2-3 (11.5 g, 50%, MS: [M+H]⁺=793).

### Preparation Example 15: Preparation of Compound 2-4

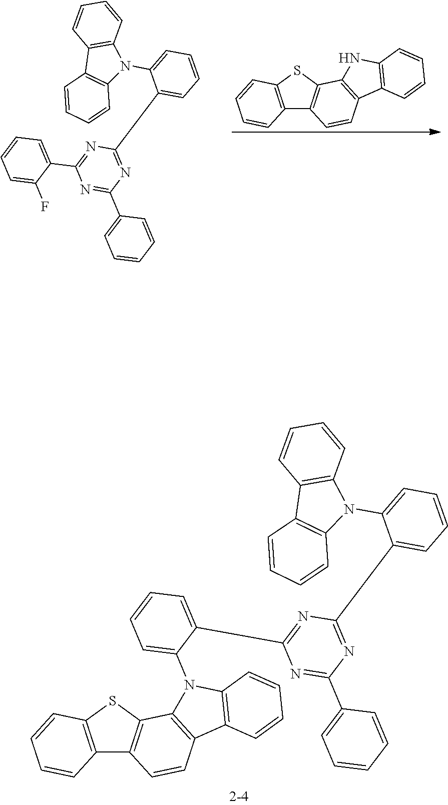

9-(2-(4-(2-fluorophenyl)-6-phenyl-1,3,5-triazin-2-yl)phenyl)-9H-carbazole (10 g, 20.3 mmol) and 12H-benzo[4,5]thieno[2,3-a]carbazole (5.5 g, 20.3 mmol) were added to 100 mL of dimethylformamide under a nitrogen atmosphere, and the mixture was stirred and refluxed. After confirming complete dissolution, potassium triphosphate (12.9 g, 60.9 mmol) was added thereto. After 3 hours of reaction, the mixture was cooled to room temperature and the resulting solid was filtered. The solid was dissolved in 454 mL of chloroform, washed twice with water, and the organic layer was separated. Anhydrous magnesium sulfate was added thereto, stirred, and then filtering, and the filtrate was distilled under reduced pressure. The concentrated compound was purified through a silica column using chloroform and ethyl acetate to produce yellow solid compound 2-4 (12 g, 79%, MS: [M+H]⁺=746.9).

### Preparation Example 16: Preparation of Compound 2-5

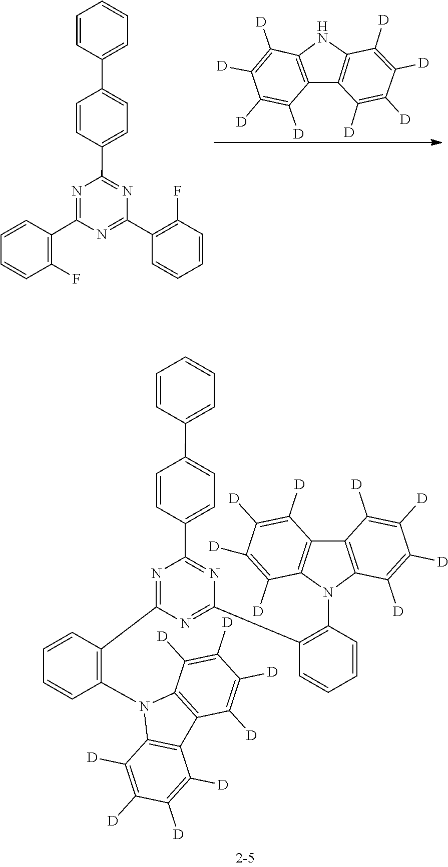 [SMILES: Fc1ccccc1-c1nc(-c2ccc(-c3ccccc3)cc2)nc(-c2ccccc2F)n1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccccc1-c1nc(-c2ccc(-c3ccccc3)cc2)nc(-c2ccccc2-n2c3c([2H])c([2H])c([2H])c([2H])c3c3c([2H])c([2H])c([2H])c([2H])c32)n1]

2-([1,1′-biphenyl]-4-yl)-4,6-bis(2-fluorophenyl)-1,3,5-triazine (10 g, 23.7 mmol) and 9H-carbazole-1,2,3,4,5,6,7,8-d8 (4.29 g, 23.7 mmol) were added to 100 mL of dimethylformamide under a nitrogen atmosphere, and the mixture was stirred and refluxed. After confirming complete dissolution, potassium triphosphate (15.1 g, 71.2 mmol) was added thereto. After 2 hours of reaction, the mixture was cooled to room temperature and the resulting solid was filtered. The solid was dissolved in 521 mL of chloroform, washed twice with water, and the organic layer was separated. Anhydrous magnesium sulfate was added thereto, stirred, and then filtering, and the filtrate was distilled under reduced pressure. The concentrated compound was purified through a silica column using chloroform and ethyl acetate to produce yellow solid compound 2-5 (10.9 g, 63%, MS: [M+H]⁺=733).

### EXAMPLES

### Example 1

A glass substrate on which ITO (indium tin oxide) was coated as a thin film to a thickness of 100 nm was put into distilled water in which a detergent was dissolved, and ultrasonically cleaned. A product manufactured by Fischer Co. was used as the detergent, and as the distilled water, distilled water filtered twice using a filter manufactured by Millipore Co. was used. After the ITO was cleaned for 30 minutes, ultrasonic cleaning was repeated twice using distilled water for 30 minutes. After the cleaning with distilled water was completed, the substrate was ultrasonically cleaned with solvents of isopropyl alcohol, acetone, and methanol, dried, and then transferred to a plasma cleaner. In addition, the substrate was cleaned for 5 minutes using oxygen plasma and then transferred to a vacuum depositor.

On the prepared ITO transparent electrode, the following compound HI-A was thermally and vacuum-deposited to a thickness of 60 nm to form a hole injection layer.

The following compound HAT was vacuum-deposited on the hole injection layer to form a first hole transport layer with a thickness of 5 nm, and the following compound HT-A was vacuum-deposited on the first hole transport layer to form a second hole transport layer with a thickness of 50 nm.

On the hole transport layer, the following compound HT-B was thermally and vacuum-deposited to a thickness of 45 nm to form an electron blocking layer.

On the electron blocking layer, a composition was prepared by mixing previously prepared Compound 1-1 and Compound 2-1 at a weight ratio of 2:1 was vacuum-deposited with the following compound GD in a weight ratio of 95:5 to form a 40 nm thick light emitting layer.

On the light emitting layer, the following compound ET-A was vacuum-deposited to a thickness of 5 nm to form a hole blocking layer.

On the hole-blocking layer, the following compound ET-B and the following compound LiQ were vacuum-deposited at a weight ratio of 1:1 to form an electron injection and transport layer with a thickness of 35 nm.

After lithium fluoride (LiF) was deposited on the electron injection and transport layer to a thickness of 1 nm, aluminum was subsequently deposited to a thickness of 100 nm to form a cathode, thereby fabricating an organic light emitting device.

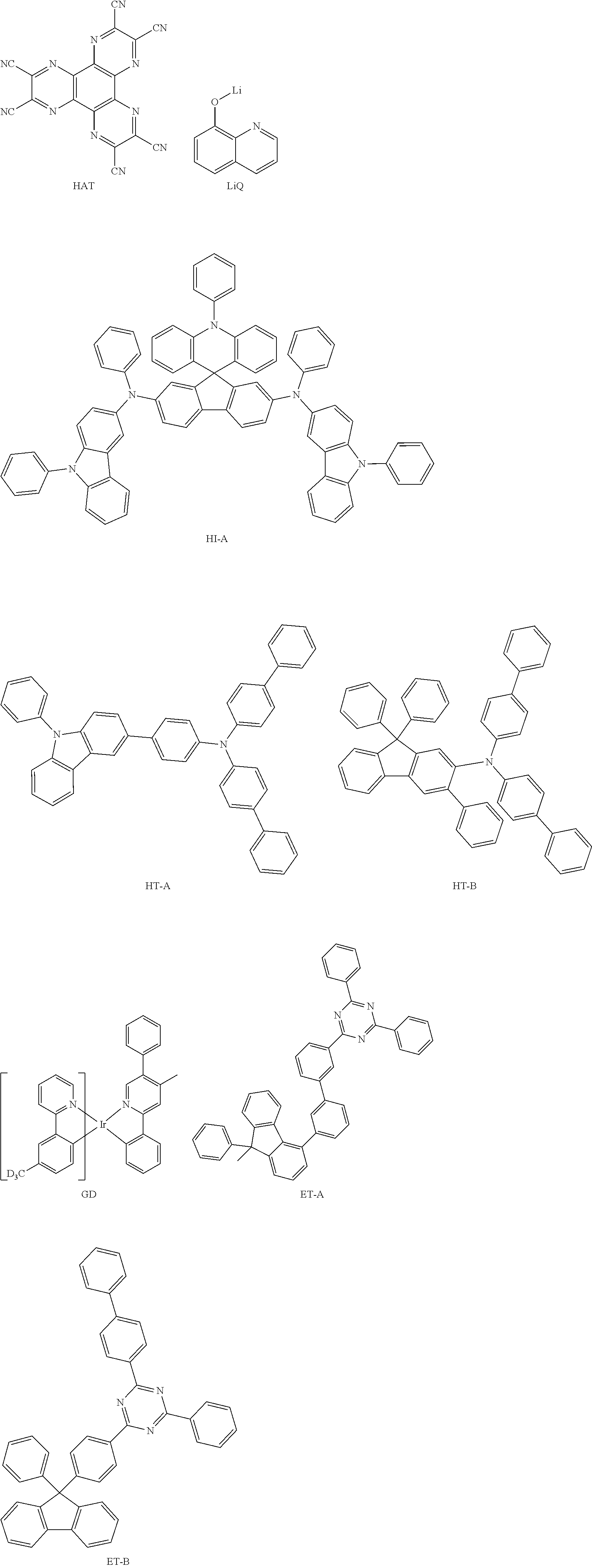

In the above-mentioned processes, the deposition rate of the organic material was maintained at 0.04 nm/sec to 0.09 nm/sec, the deposition rate of lithium fluoride was maintained at 0.03 nm/sec, and the deposition rate of aluminum was maintained at 0.2 nm/sec. The vacuum during deposition was maintained at 1×10⁻⁷ torr to 5×10⁻⁵ torr.

### Examples 2 to 26

The organic light emitting device was manufactured in the same manner as in Example 1, except that the compounds listed in Table 1 were used instead of Compound 1-1 and the compounds listed in Table 1 were used instead of Compound 2-1. The structures of the compounds used in the examples are summarized below.

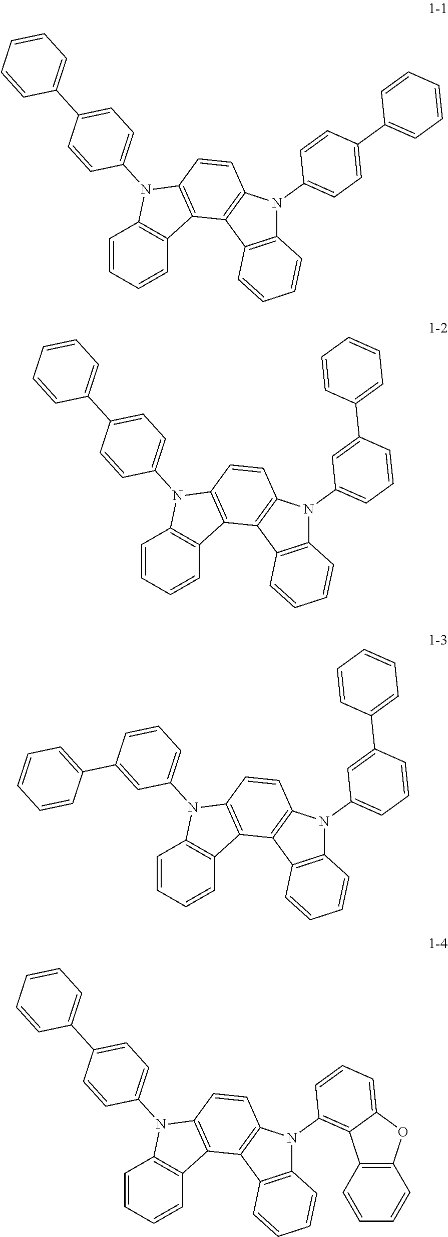 [SMILES: c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6cccc(-c7ccccc7)c6)c5ccc43)c2)cc1 ; c1ccc(-c2ccc(-n3c4ccccc4c4c5c6ccccc6n(-c6cccc7oc8ccccc8c67)c5ccc43)cc2)cc1]

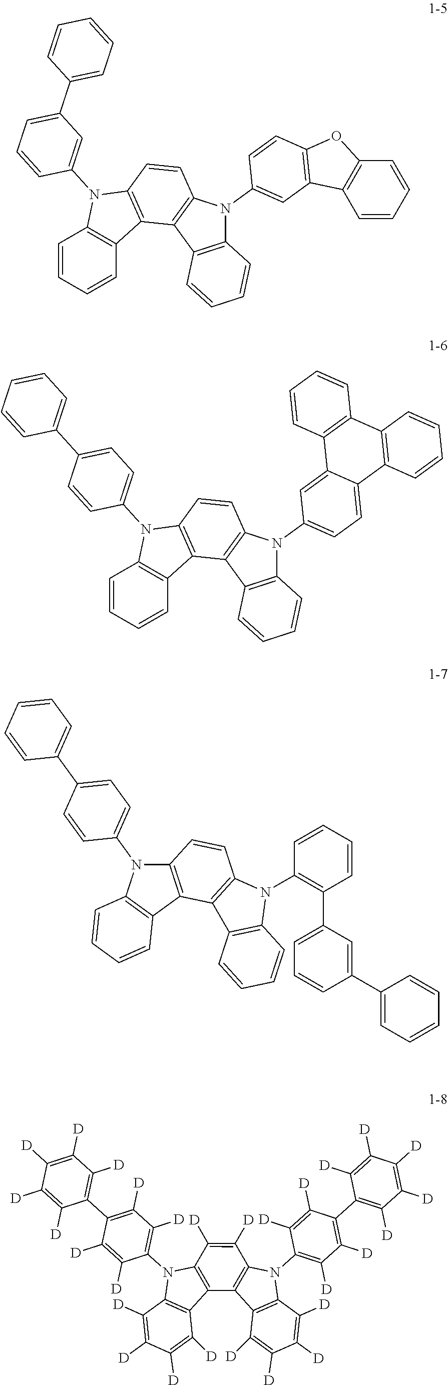 [SMILES: c1ccc(-c2cccc(-n3c4ccccc4c4c5c6ccccc6n(-c6ccc7oc8ccccc8c7c6)c5ccc43)c2)cc1 ; c1ccc(-c2ccc(-n3c4ccccc4c4c5c6ccccc6n(-c6ccc7c8ccccc8c8ccccc8c7c6)c5ccc43)cc2)cc1 ; c1ccc(-c2ccc(-n3c4ccccc4c4c5c6ccccc6n(-c6ccccc6-c6cccc(-c7ccccc7)c6)c5ccc43)cc2)cc1 ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c(-c7c([2H])c([2H])c([2H])c([2H])c7[2H])c([2H])c6[2H])c5c([2H])c([2H])c43)c([2H])c2[2H])c([2H])c1[2H]]

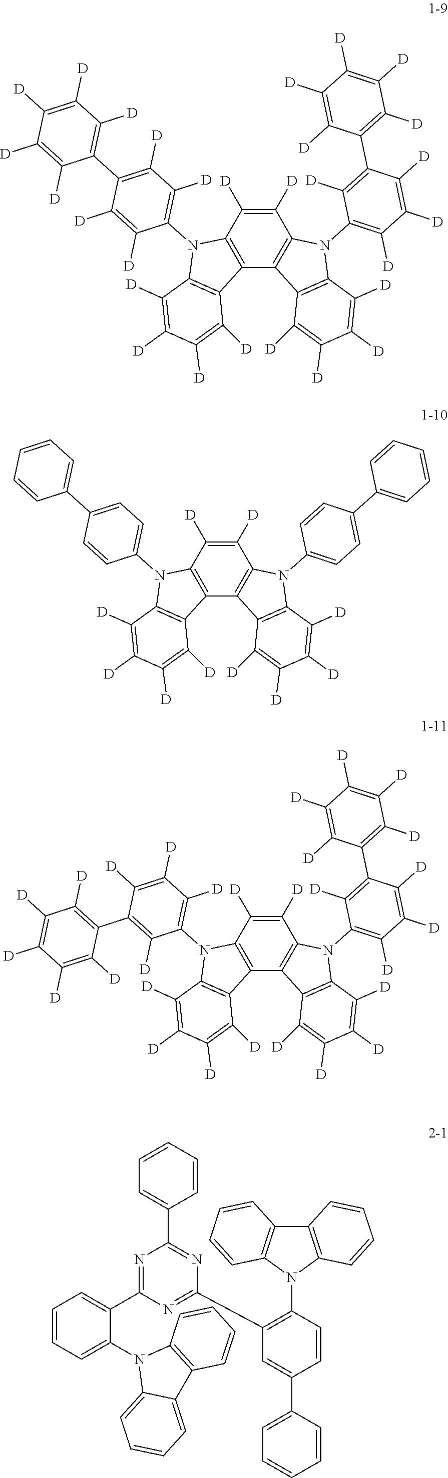

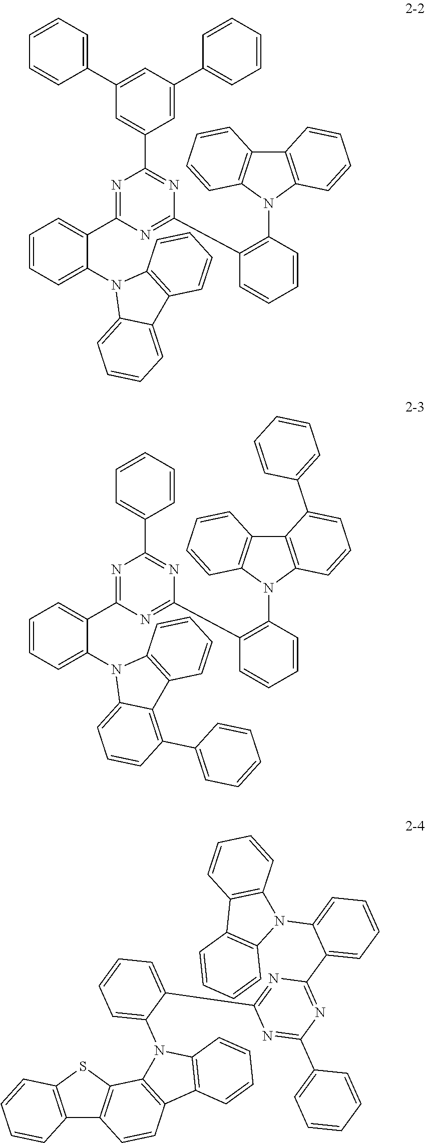 [SMILES: c1ccc(-c2cc(-c3ccccc3)cc(-c3nc(-c4ccccc4-n4c5ccccc5c5ccccc54)nc(-c4ccccc4-n4c5ccccc5c5ccccc54)n3)c2)cc1 ; c1ccc(-c2nc(-c3ccccc3-n3c4ccccc4c4c(-c5ccccc5)cccc43)nc(-c3ccccc3-n3c4ccccc4c4c(-c5ccccc5)cccc43)n2)cc1 ; c1ccc(-c2nc(-c3ccccc3-n3c4ccccc4c4ccccc43)nc(-c3ccccc3-n3c4ccccc4c4ccc5c6ccccc6sc5c43)n2)cc1]

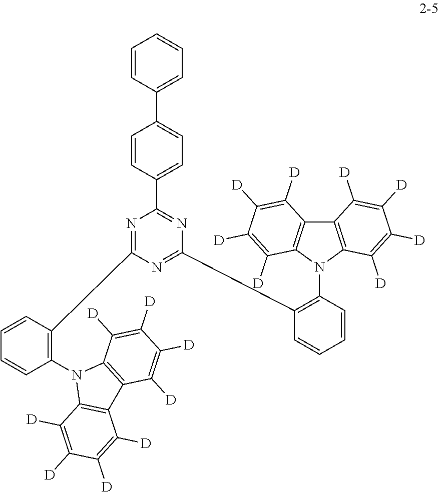 [SMILES: [2H]c1c([2H])c([2H])c2c(c1[2H])c1c([2H])c([2H])c([2H])c([2H])c1n2-c1ccccc1-c1nc(-c2ccc(-c3ccccc3)cc2)nc(-c2ccccc2-n2c3c([2H])c([2H])c([2H])c([2H])c3c3c([2H])c([2H])c([2H])c([2H])c32)n1]

### Comparative Examples 1 to 11

The organic light emitting device was manufactured in the same manner as n Example 1, except that the compound described in Table 1 was used instead of Compound 1-1, or the compound described in Table 1 was used instead of Compound 2-1. The structures of Compound 3-1 and Compounds 4-1 to 4-4 used in the Comparative Examples are as follows.

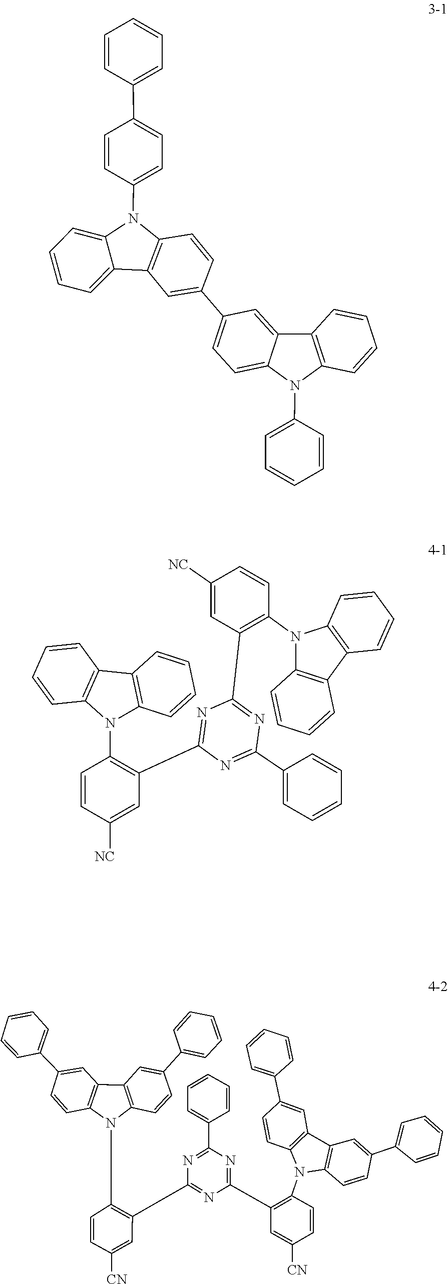 [SMILES: c1ccc(-c2ccc(-n3c4ccccc4c4cc(-c5ccc6c(c5)c5ccccc5n6-c5ccccc5)ccc43)cc2)cc1 ; N#Cc1ccc(-n2c3ccccc3c3ccccc32)c(-c2nc(-c3ccccc3)nc(-c3cc(C#N)ccc3-n3c4ccccc4c4ccccc43)n2)c1 ; N#Cc1ccc(-n2c3ccc(-c4ccccc4)cc3c3cc(-c4ccccc4)ccc32)c(-c2nc(-c3ccccc3)nc(-c3cc(C#N)ccc3-n3c4ccc(-c5ccccc5)cc4c4cc(-c5ccccc5)ccc43)n2)c1]

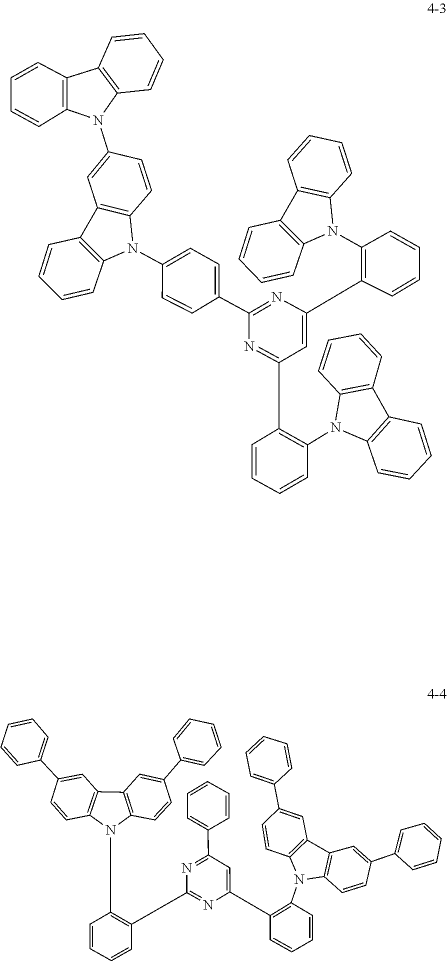 [SMILES: c1ccc(-n2c3ccccc3c3ccccc32)c(-c2cc(-c3ccccc3-n3c4ccccc4c4ccccc43)nc(-c3ccc(-n4c5ccccc5c5cc(-n6c7ccccc7c7ccccc76)ccc54)cc3)n2)c1 ; c1ccc(-c2ccc3c(c2)c2cc(-c4ccccc4)ccc2n3-c2ccccc2-c2cc(-c3ccccc3)nc(-c3ccccc3-n3c4ccc(-c5ccccc5)cc4c4cc(-c5ccccc5)ccc43)n2)cc1]

### Experimental Example

The voltage, efficiency, luminous color, and lifetime (T95) were measured by applying a current to the organic light emitting devices manufactured in the Examples 1 to 26 and Comparative Examples 1 to 11, and the results are shown in Table 1 below. At this time, the voltage and efficiency were measured at a current density of 10 mA/cm², and T95 represents the time (hr) until the initial luminance decreased to 95% at a current density of 20 mA/cm².

TABLE 1

| | First | Second | [symbol] riving voltage | Efficiency | | |
|---|---|---|---|---|---|---|
| | [symbol] ompound | [symbol] ompound | (V) | (cd/A) | [symbol] uminous | T₉₅(hr) |
| Category | [symbol] First host) | (Second host) | [symbol] @10 mA/cm²) | [symbol] @10 mA/cm²) | color | [symbol] @20 mA/cm²) |
| Example 1 | 1-1 | 2-1 | 3.54 | 89.0 | Green | 150 |
| Example 2 | 1-2 | 2-1 | 3.60 | 91.4 | Green | 145 |
| Example 3 | 1-3 | 2-1 | 3.67 | 91.6 | Green | 136 |
| Example 4 | 1-6 | 2-1 | 3.63 | 92.0 | Green | 120 |
| Example 5 | 1-8 | 2-1 | 3.55 | 89.1 | Green | 205 |
| Example 6 | 1-2 | 2-2 | 3.59 | 90.4 | Green | 140 |
| Example 7 | 1-5 | 2-2 | 3.63 | 91.1 | Green | 133 |
| Example 8 | 1-6 | 2-2 | 3.70 | 91.3 | Green | 131 |
| Example 9 | 1-7 | 2-2 | 3.74 | 92.7 | Green | 116 |
| Example 10 | 1-10 | 2-2 | 3.52 | 90.0 | Green | 180 |
| Example 11 | 1-1 | 2-3 | 3.65 | 91.1 | Green | 178 |
| Example 12 | 1-3 | 2-3 | 3.77 | 92.4 | Green | 170 |
| Example 13 | 1-4 | 2-3 | 3.66 | 91.5 | Green | 160 |
| Example 14 | 1-5 | 2-3 | 3.68 | 91.8 | Green | 155 |
| Example 15 | 1-6 | 2-3 | 3.74 | 92.0 | Green | 175 |
| Example 16 | 1-2 | 2-4 | 3.52 | 90.4 | Green | 144 |
| Example 17 | 1-3 | 2-4 | 3.60 | 91.1 | Green | 140 |
| Example 18 | 1-7 | 2-4 | 3.67 | 92.3 | Green | 128 |
| Example 19 | 1-9 | 2-4 | 3.53 | 90.3 | Green | 180 |
| Example 20 | 1-10 | 2-4 | 3.49 | 89.9 | Green | 170 |
| Example 21 | 1-1 | 2-5 | 3.54 | 92.2 | Green | 160 |
| Example 22 | 1-2 | 2-5 | 3.61 | 93.7 | Green | 155 |
| Example 23 | 1-7 | 2-5 | 3.74 | 94.0 | Green | 125 |
| Example 24 | 1-8 | 2-5 | 3.55 | 92.1 | Green | 210 |
| Example 25 | 1-9 | 2-5 | 3.60 | 93.5 | Green | 204 |
| Example 26 | 1-11 | 2-5 | 3.62 | 95.9 | Green | 230 |
| Comparative | 3-1 | 2-1 | 4.14 | 87.5 | Green | 110 |
| Example 1 | | | | | | |
| Comparative | 3-1 | 2-3 | 4.07 | 86.4 | Green | 104 |
| Example 2 | | | | | | |
| Comparative | 3-1 | 2-5 | 4.10 | 87.0 | Green | 100 |
| Example 3 | | | | | | |
| Comparative | 1-1 | 4-1 | 3.74 | 58.3 | Green | 12 |
| Example 4 | | | | | | |
| Comparative | 1-2 | 4-1 | 3.78 | 59.9 | Green | 10 |
| Example 5 | | | | | | |
| Comparative | 1-1 | 4-2 | 3.90 | 60.4 | Green | 18 |
| Example 6 | | | | | | |
| Comparative | 1-3 | 4-2 | 3.99 | 61.1 | Green | 16 |
| Example 7 | | | | | | |
| Comparative | 1-1 | 4-3 | 3.70 | 71.0 | Green | 105 |
| Example 8 | | | | | | |
| Comparative | 1-2 | 4-3 | 3.71 | 71.3 | Green | 100 |
| Example 9 | | | | | | |
| Comparative | 1-1 | 4-4 | 3.84 | 77.4 | Green | 114 |
| Example 10 | | | | | | |
| Comparative | 1-3 | 4-4 | 3.97 | 79.1 | Green | 102 |
| Example 11 | | | | | | |

[symbol]

indicates data missing or illegible when filed

As shown in Table 1, the organic light emitting device of Example, which simultaneously used the first compound represented by Chemical Formula 1 and the second compound represented by Chemical Formula 2 as host materials in the light emitting layer, exhibited superior operating voltage, luminous efficiency, and lifespan characteristics compared to the organic light emitting devices of Comparative Examples, which used only one of the first or second compounds.

In particular, the organic light emitting device of Example, which used the first compound as the first host, exhibited reduced operating voltage, improved luminous efficiency, and improved lifespan characteristics compared to the organic light emitting devices of Comparative Examples 1 to 3, which did not use the first compound. This is believed to be due to the first compound's indolocarbazole structure, which exhibits excellent hole transport properties.

Further, the organic light emitting device of Example, which used the first compound simultaneously with the second compound, exhibited a structure in which the second compound simultaneously contained two carbazolyl substituents that assist hole injection characteristics and a triazinyl group that contributes to rapid electron injection and transport characteristics. This structure resulted in an electron-hole rich state within the light emitting layer while maintaining an excellent electron-hole balance, resulting in low-voltage/high-efficiency characteristics and improved device lifespan.

On the other hand, the organic light emitting devices of Comparative Examples 4 to 7, which used Compounds 4-1 or 4-2 as the second host, exhibited a rapid decrease in lifespan due to reduced stability in the radical state caused by the cyano groups in Compounds 4-1 or 4-2.

Further, the organic light emitting devices of Comparative Examples 8 and 9, which used Compound 4-3 as the second host, exhibited reduced efficiency due to the excessive introduction of additional electron-donating substituents to the carbazolyl group in Compound 4-3. Further, the organic light emitting devices of Comparative Examples 10 and 11, which used Compound 4-4 as the second host, exhibited poor electron injection and transport characteristics due to the lack of a triazinyl group within Compound 4-4, resulting in poor device performance.

Therefore, it was confirmed that simultaneously employing the first and second compounds as host materials in an organic light emitting device improved the operating voltage, luminous efficiency, and lifetime characteristics of the device. Considering that luminous efficiency and lifetime characteristics of organic light emitting devices generally exhibit a trade-off relationship, the organic light emitting device employing the combination of compounds of the present invention exhibits significantly improved device characteristics compared to the device of the Comparative Example.

[Description of Symbols]

| | |
|---|---|
| 1: substrate | 2: anode |
| 3: light emitting layer | 4: cathode |
| 5: hole injection layer | 6: hole transport layer |
| 6-1: first hole transport layer | 6-2: second hole transport layer |
| 7: electron blocking layer | 8: hole blocking layer |
| 9: electron injection and | |
| transport layer | |

1. A composition for an organic light emitting device, comprising a first compound represented by the following Chemical Formula 1 and a second compound represented by the following Chemical Formula 2: 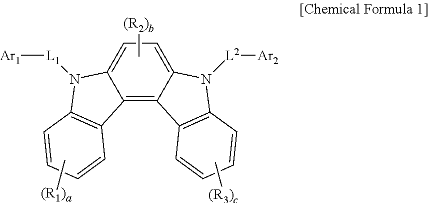
wherein in Chemical Formula 1,
L₁ and L₂ are each independently a single bond, or a substituted or unsubstituted C₆₋₆₀ arylene,
Ar₁ is a substituted or unsubstituted C₆₋₆₀ aryl,
Ar₂ is a substituted or unsubstituted C₆₋₆₀ aryl, or a substituted or unsubstituted C₂₋₆₀ heteroaryl containing at least one heteroatom selected among N, O and S, provided that the case where Ar₂ is a monocyclic containing one or more N atoms is excluded,
R₁ to R₃ are each independently hydrogen, deuterium, or tritium,
a and b are each independently an integer from 0 to 4, and
b is an integer from 0 to 2, 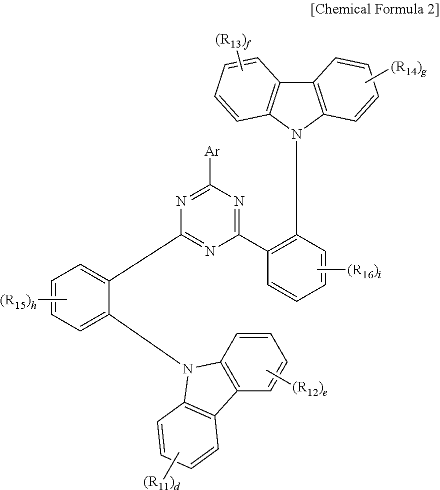
wherein in Chemical Formula 2,
Ar is C₆₋₆₀ aryl unsubstituted or substituted with one or more substituents selected from the group consisting of deuterium, tritium, alkyl, and aryl, or unsubstituted or substituted with a substituent to which two or more substituents of the above-exemplified substituents are connected,
R₁₁ to R₁₄ are each independently hydrogen, deuterium, tritium, or a substituted or unsubstituted C₆₋₆₀ aryl; or are combined with adjacent substituents to form a substituted or unsubstituted C₆₋₆₀ aromatic ring or a substituted or unsubstituted C₂₋₆₀ heteroaromatic ring containing at least one heteroatom selected among N, O and S,
R₁₅ and R₁₆ are each independently hydrogen, deuterium, tritium, or a substituted or unsubstituted C₆₋₆₀ aryl, and
d to i are each independently an integer from 0 to 4.

2. The composition for an organic light emitting device of claim 1, wherein:
L₁ and L₂ are each independently a single bond, or phenylene substituted or unsubstituted with deuterium.

3. The composition for an organic light emitting device of claim 1, wherein:
Ar₁ is phenyl, biphenylyl, terphenylyl, or quaterphenylyl,
wherein, Ar₁ is unsubstituted, or substituted with one or more substituents selected from the group consisting of deuterium; tritium; C₁₋₁₀ alkyl substituted or unsubstituted with deuterium or tritium; and C₆₋₂₀ aryl substituted or unsubstituted with deuterium or tritium.

4. The composition for an organic light emitting device of claim 1, wherein:
Ar₂ is phenyl, biphenylyl, terphenylyl, quaterphenylyl, dibenzofuranyl, dibenzothiophenyl, phenanthryl, triphenylenyl, benzonaphthofuranyl, benzonaphthothiophenyl, carbazolyl, or 9-phenylcarbazolyl,
wherein, Ar₂ is unsubstituted, or substituted with one or more substituents selected from the group consisting of deuterium; tritium; C₁₋₁₀ alkyl substituted or unsubstituted with deuterium or tritium; and C₆₋₂₀ aryl substituted or unsubstituted with deuterium or tritium.

5. The composition for an organic light emitting device of claim 1, wherein:
R₁, R₂ and R₃ are all hydrogen; or
R₁, R₂ and R₃ are all deuterium; or
R₁ and R₃ are deuterium, R₂ is hydrogen.

6. The composition for an organic light emitting device of claim 1, wherein:
a+b+c is 0, 8, or 10.

7. The composition for an organic light emitting device of claim 1, wherein:
the first compound is any one selected from the group consisting of the following compounds:

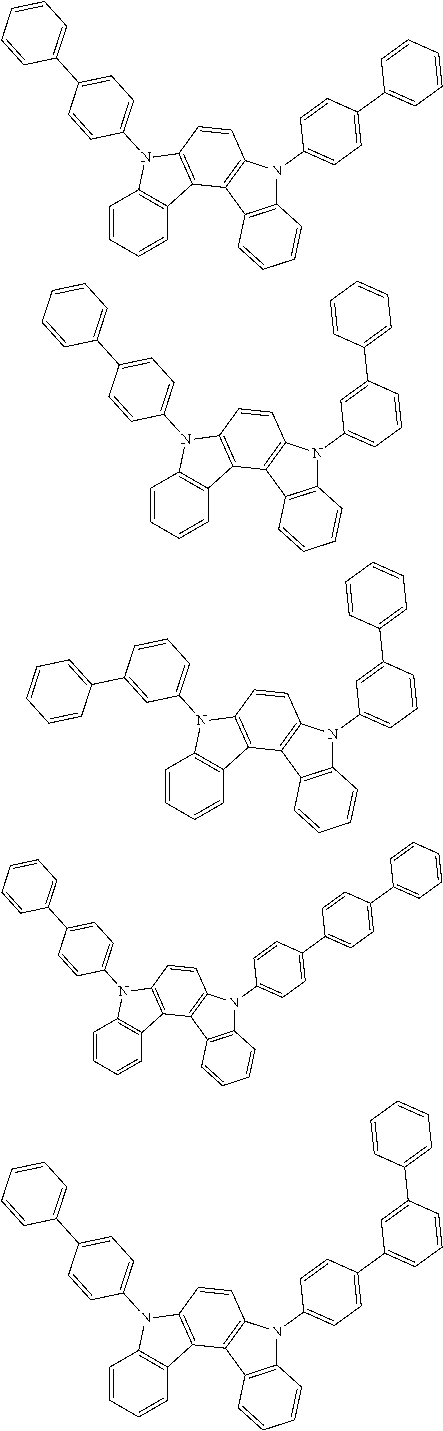

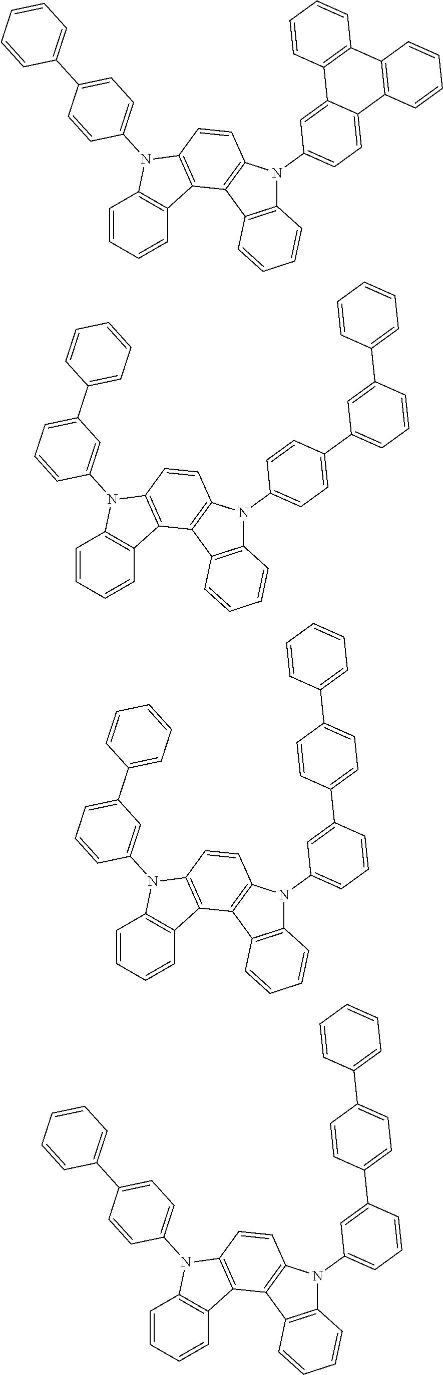

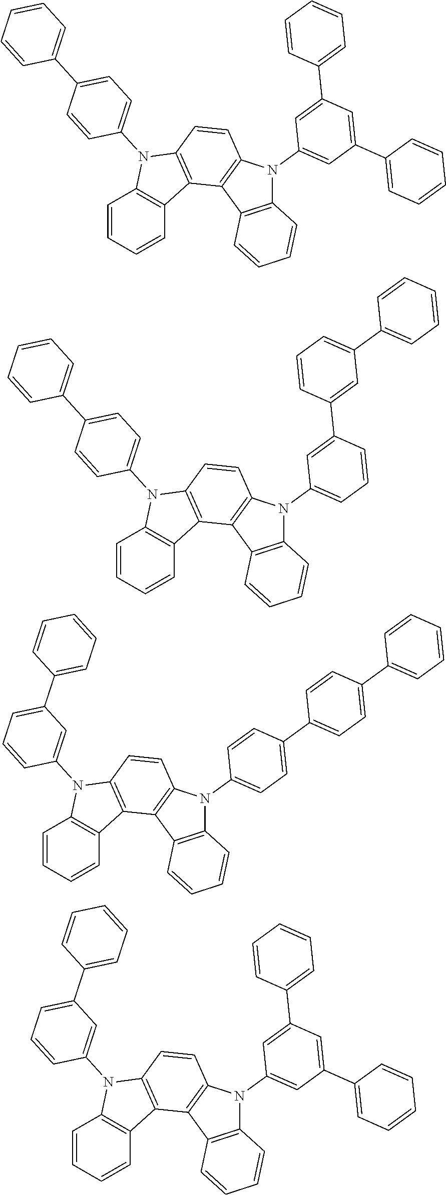

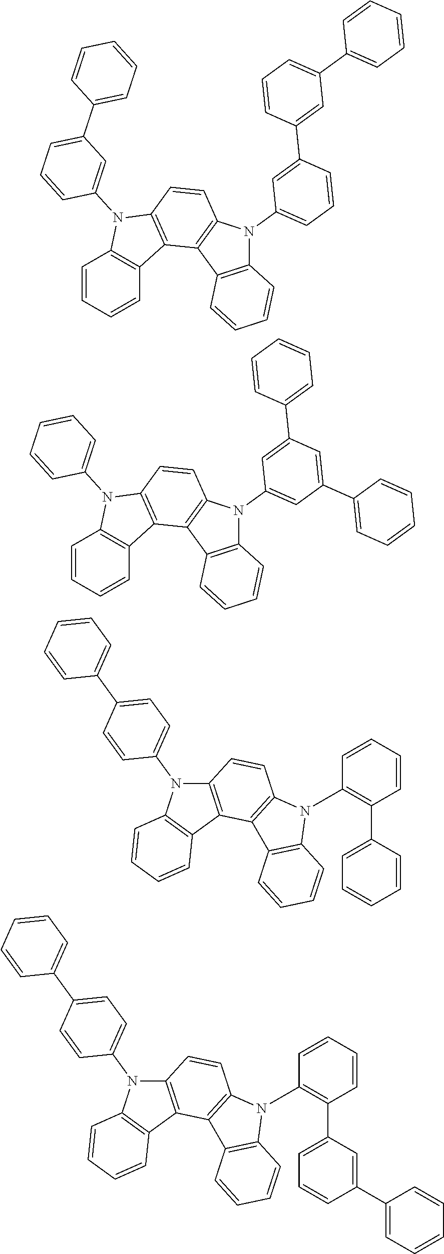

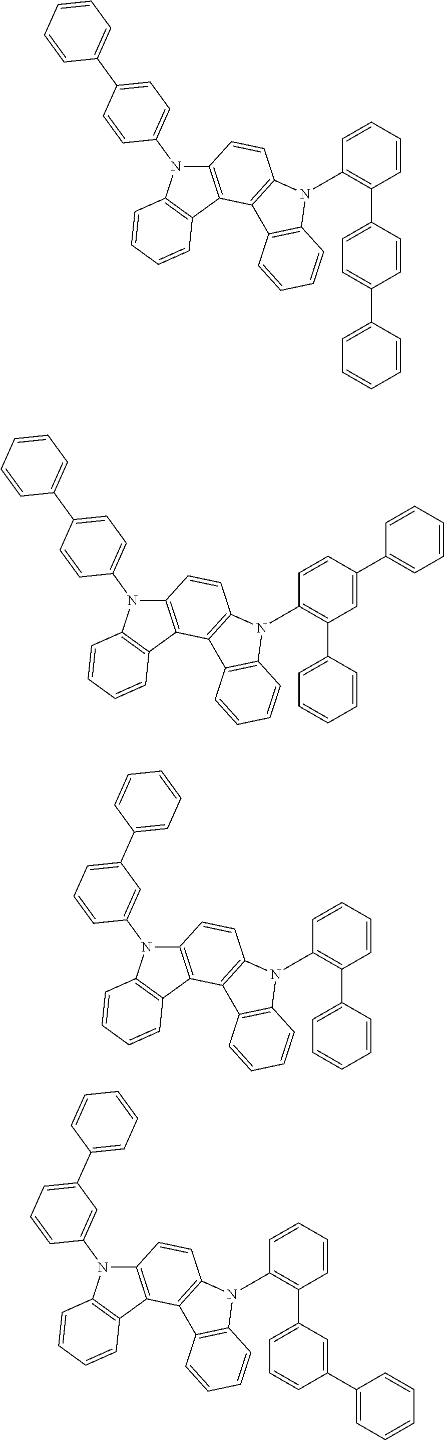 [SMILES: c1ccc(-c2ccc(-c3ccccc3-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6ccc(-c7ccccc7)cc6-c6ccccc6)c5ccc43)cc2)cc1 ; c1ccc(-c2cccc(-n3c4ccccc4c4c5c6ccccc6n(-c6ccccc6-c6ccccc6)c5ccc43)c2)cc1 ; c1ccc(-c2cccc(-c3ccccc3-n3c4ccccc4c4c5c6ccccc6n(-c6cccc(-c7ccccc7)c6)c5ccc43)c2)cc1]

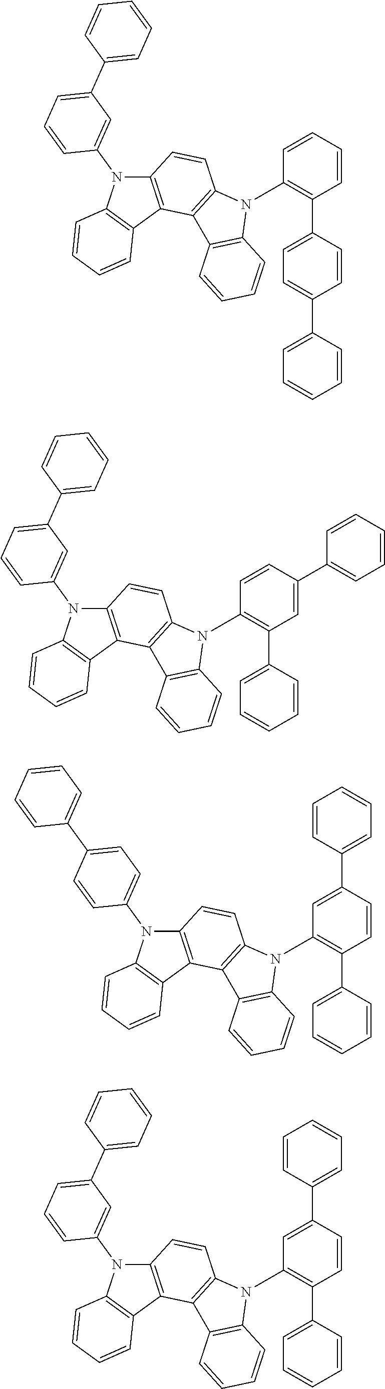 [SMILES: c1ccc(-c2ccc(-c3ccccc3-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6ccc(-c7ccccc7)cc6-c6ccccc6)c5ccc43)c2)cc1 ; c1ccc(-c2ccc(-n3c4ccccc4c4c5c6ccccc6n(-c6cc(-c7ccccc7)ccc6-c6ccccc6)c5ccc43)cc2)cc1 ; c1ccc(-c2cccc(-n3c4ccccc4c4c5c6ccccc6n(-c6cc(-c7ccccc7)ccc6-c6ccccc6)c5ccc43)c2)cc1]

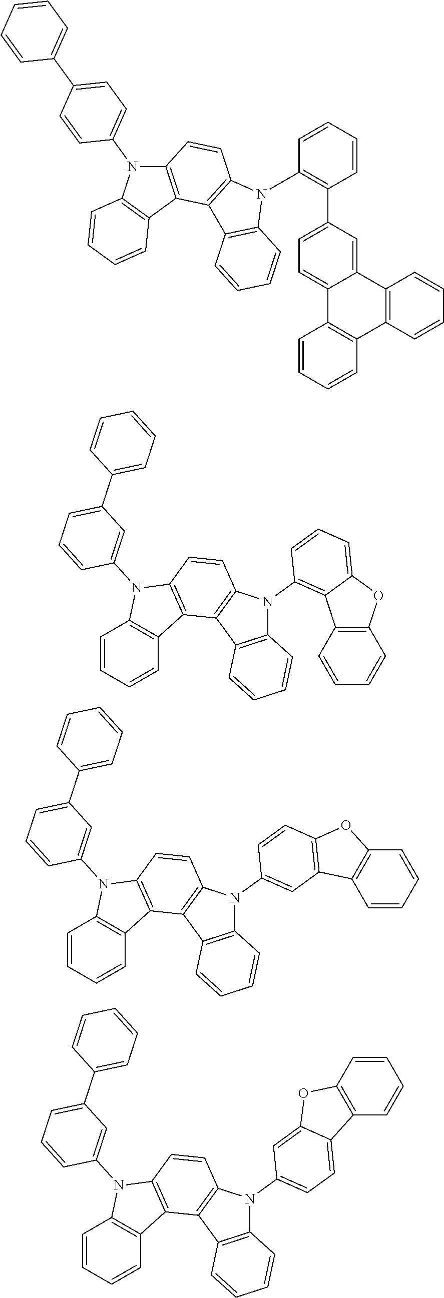

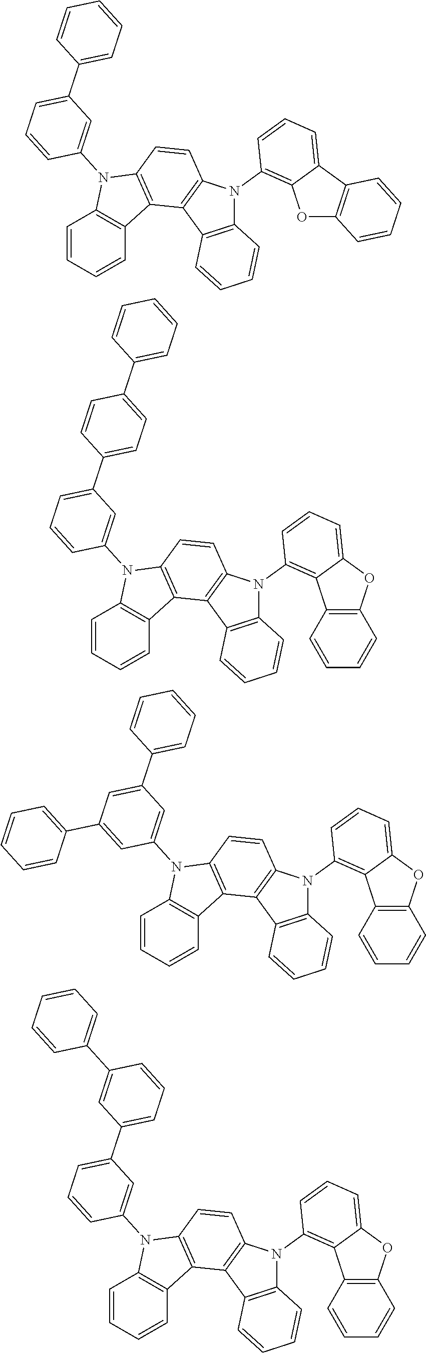

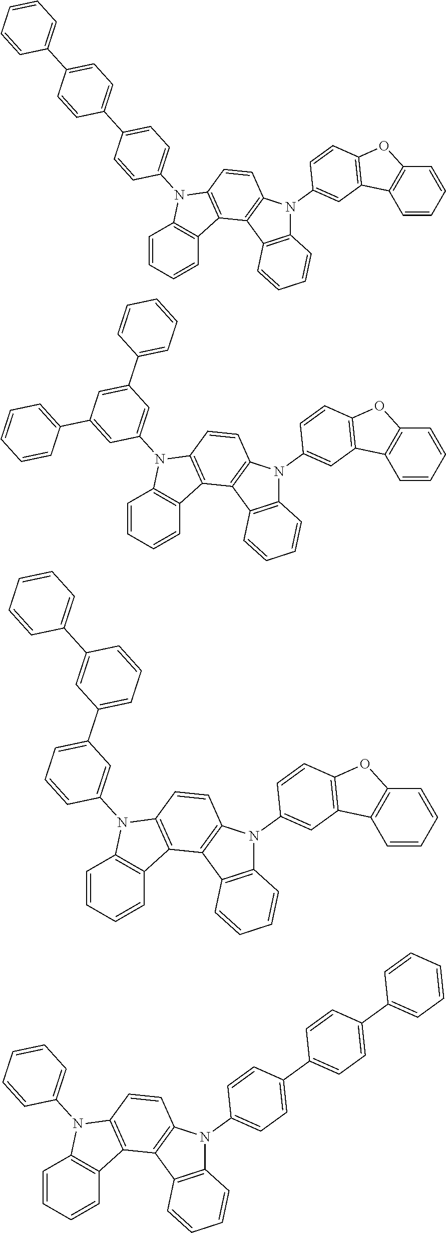

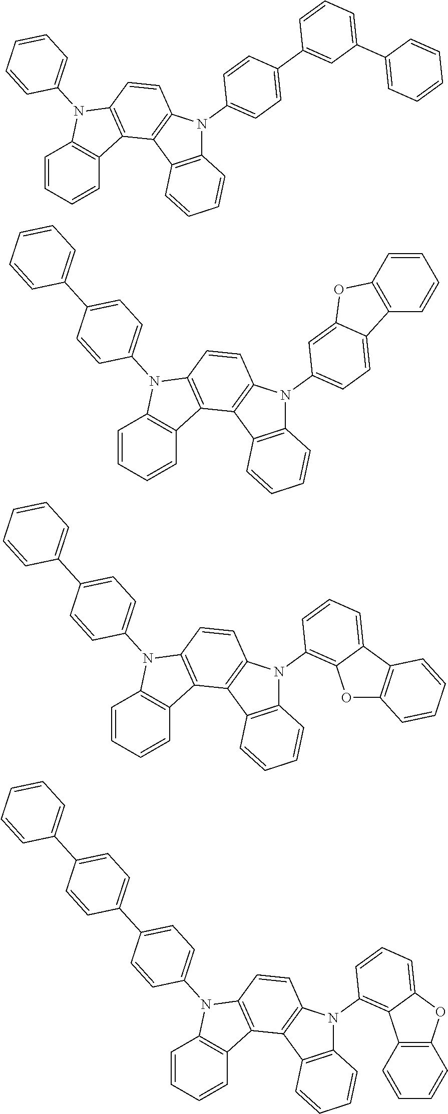

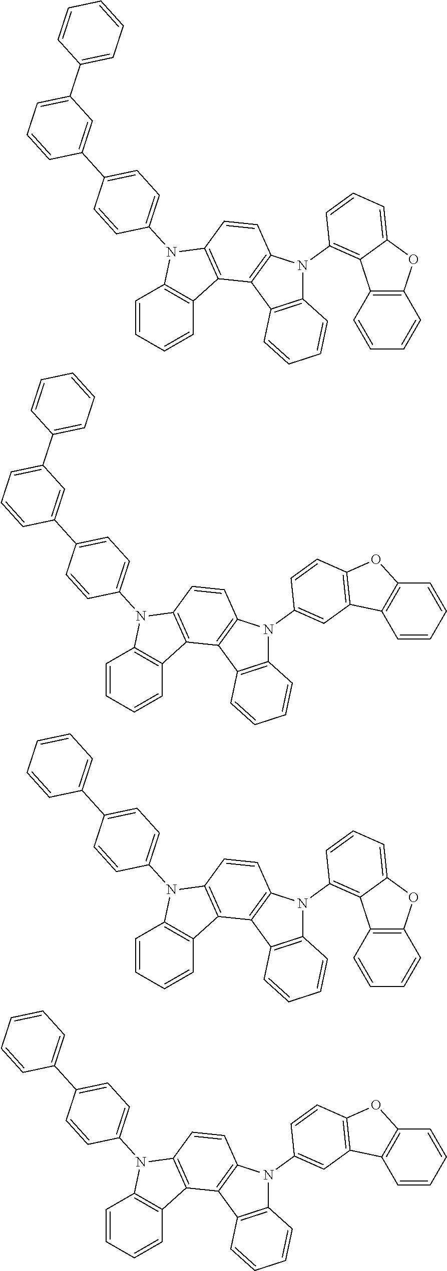 [SMILES: c1ccc(-c2cccc(-c3ccc(-n4c5ccccc5c5c6c7ccccc7n(-c7cccc8oc9ccccc9c78)c6ccc54)cc3)c2)cc1 ; c1ccc(-c2cccc(-c3ccc(-n4c5ccccc5c5c6c7ccccc7n(-c7ccc8oc9ccccc9c8c7)c6ccc54)cc3)c2)cc1 ; c1ccc(-c2ccc(-n3c4ccccc4c4c5c6ccccc6n(-c6cccc7oc8ccccc8c67)c5ccc43)cc2)cc1 ; c1ccc(-c2ccc(-n3c4ccccc4c4c5c6ccccc6n(-c6ccc7oc8ccccc8c7c6)c5ccc43)cc2)cc1]

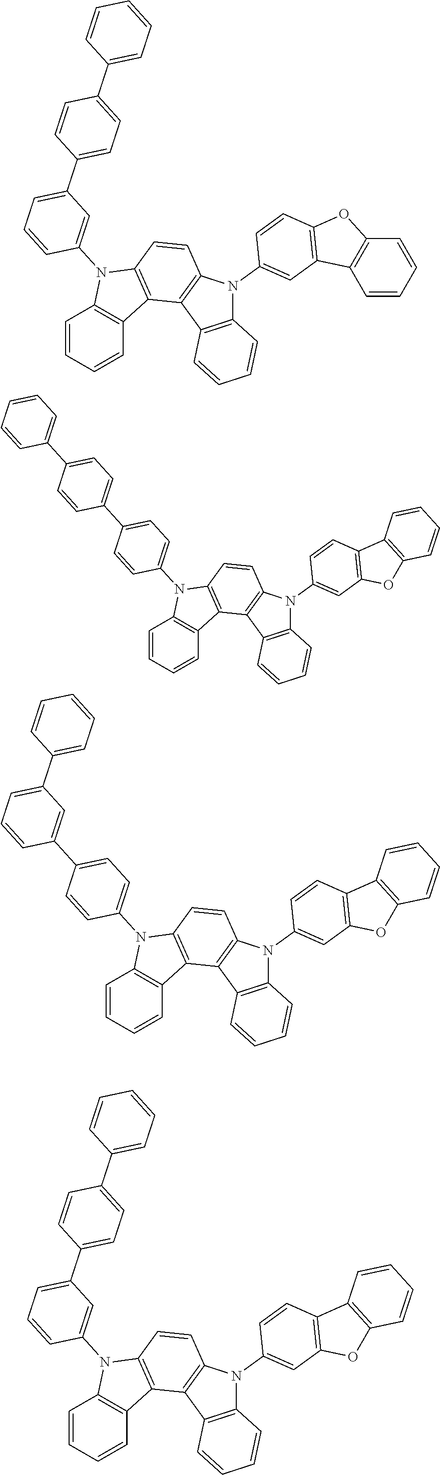 [SMILES: c1ccc(-c2ccc(-c3cccc(-n4c5ccccc5c5c6c7ccccc7n(-c7ccc8oc9ccccc9c8c7)c6ccc54)c3)cc2)cc1 ; c1ccc(-c2ccc(-c3ccc(-n4c5ccccc5c5c6c7ccccc7n(-c7ccc8c(c7)oc7ccccc78)c6ccc54)cc3)cc2)cc1 ; c1ccc(-c2cccc(-c3ccc(-n4c5ccccc5c5c6c7ccccc7n(-c7ccc8c(c7)oc7ccccc78)c6ccc54)cc3)c2)cc1 ; c1ccc(-c2ccc(-c3cccc(-n4c5ccccc5c5c6c7ccccc7n(-c7ccc8c(c7)oc7ccccc78)c6ccc54)c3)cc2)cc1]

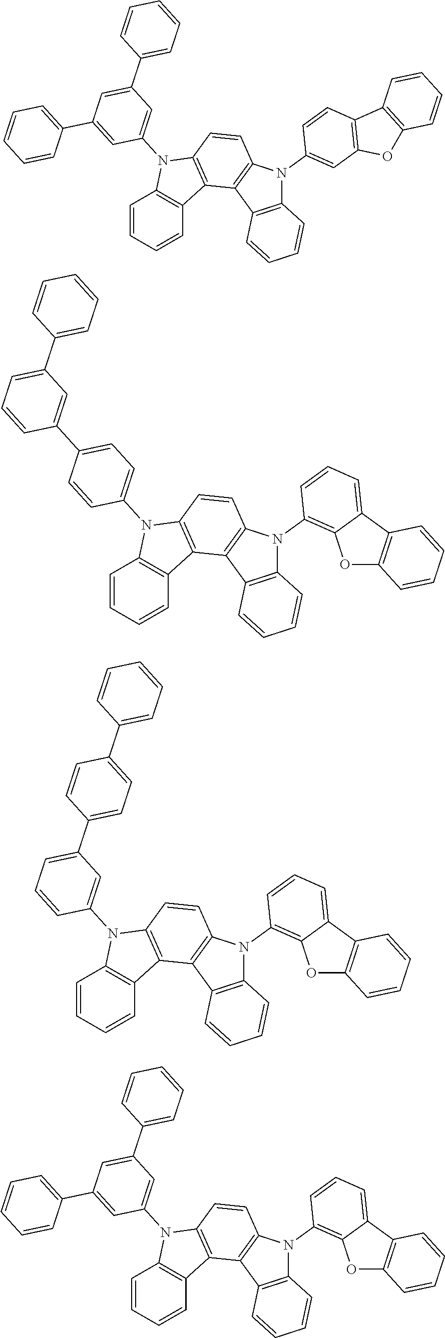

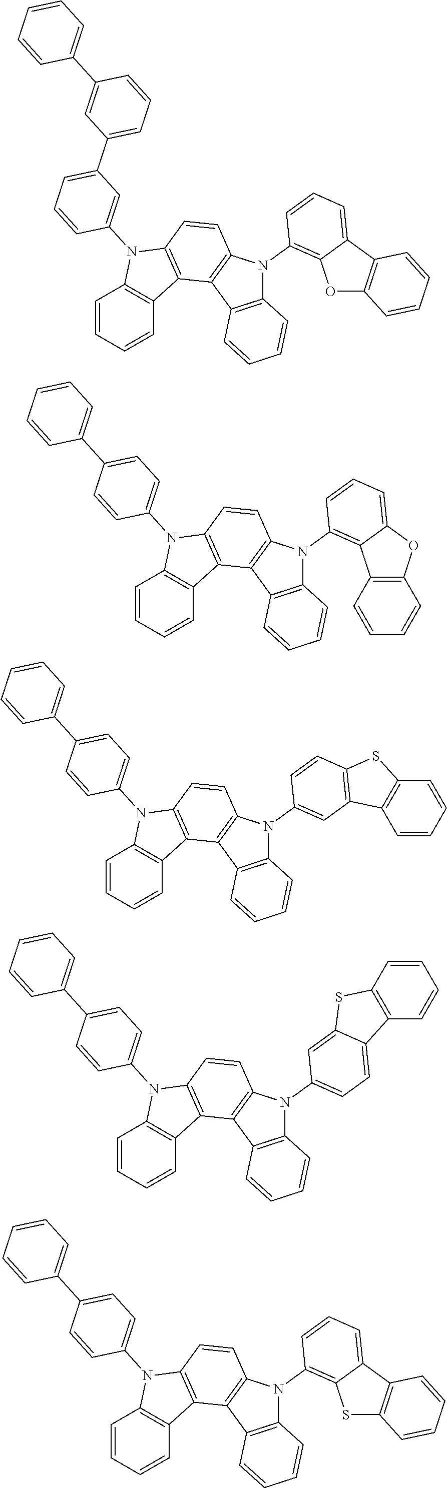 [SMILES: c1ccc(-c2cccc(-c3cccc(-n4c5ccccc5c5c6c7ccccc7n(-c7cccc8c7oc7ccccc78)c6ccc54)c3)c2)cc1 ; c1ccc(-c2ccc(-n3c4ccccc4c4c5c6ccccc6n(-c6cccc7oc8ccccc8c67)c5ccc43)cc2)cc1 ; c1ccc(-c2ccc(-n3c4ccccc4c4c5c6ccccc6n(-c6ccc7sc8ccccc8c7c6)c5ccc43)cc2)cc1 ; c1ccc(-c2ccc(-n3c4ccccc4c4c5c6ccccc6n(-c6ccc7c(c6)sc6ccccc67)c5ccc43)cc2)cc1 ; c1ccc(-c2ccc(-n3c4ccccc4c4c5c6ccccc6n(-c6cccc7c6sc6ccccc67)c5ccc43)cc2)cc1]

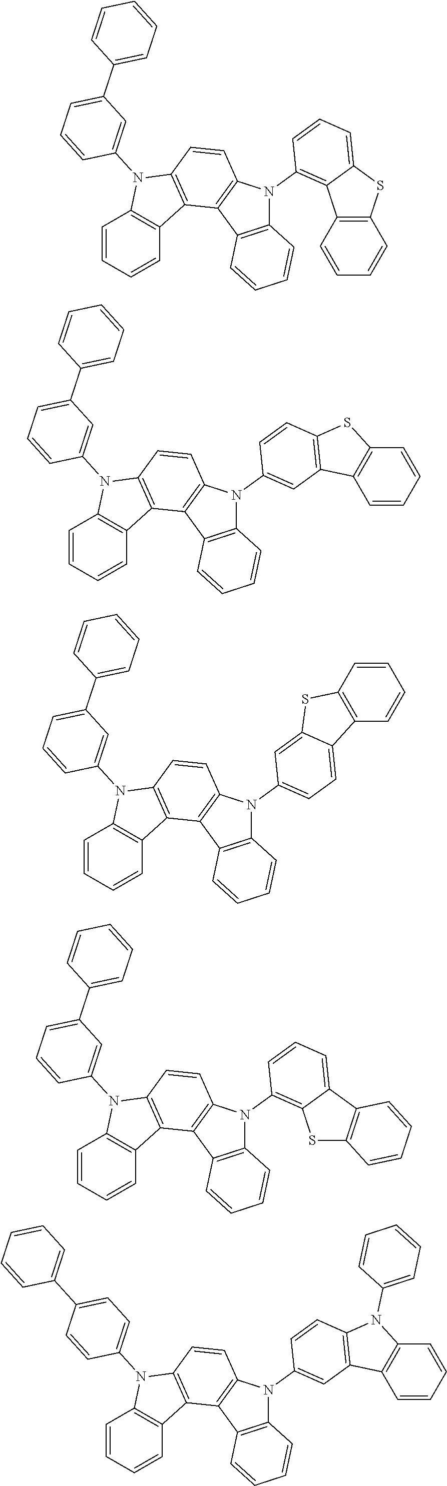

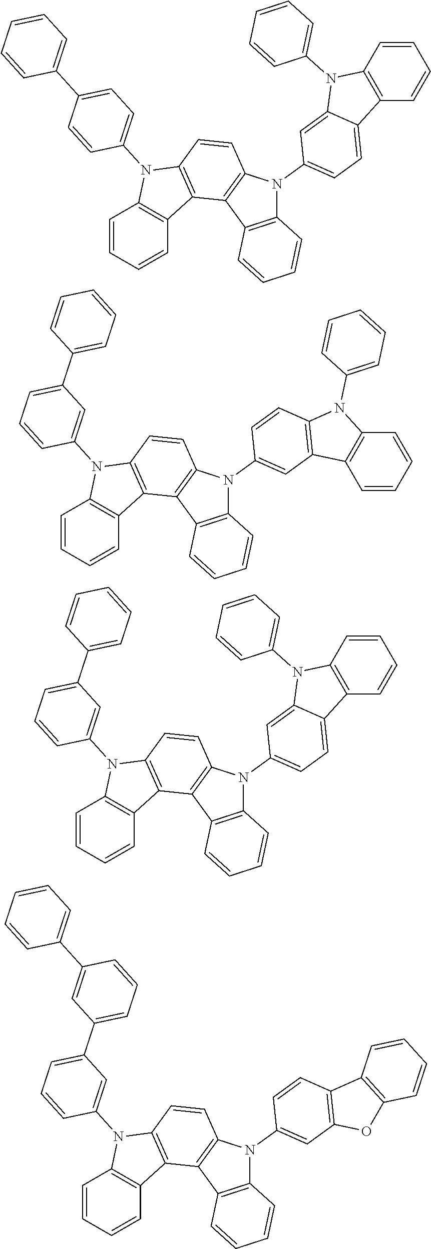

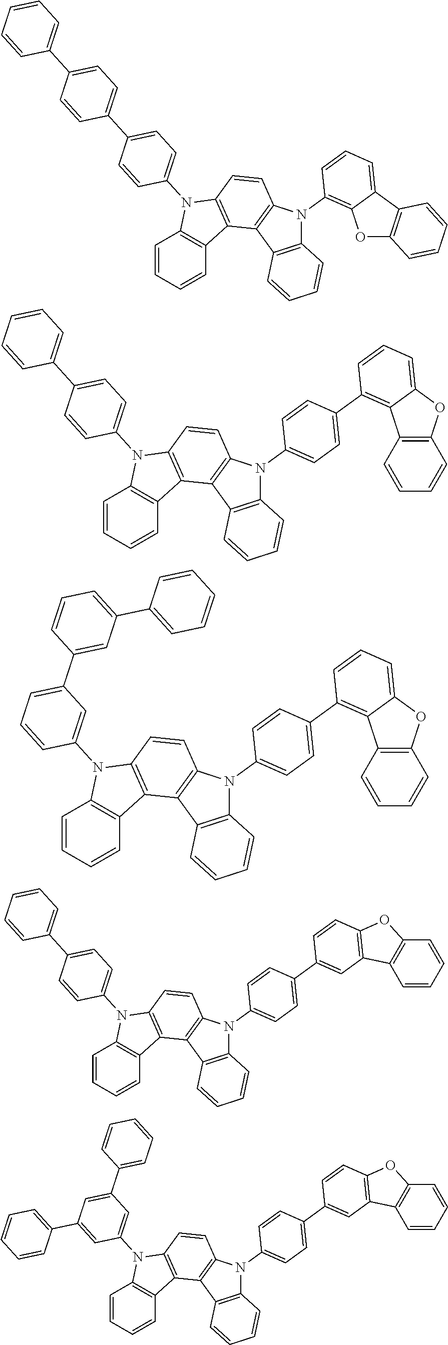

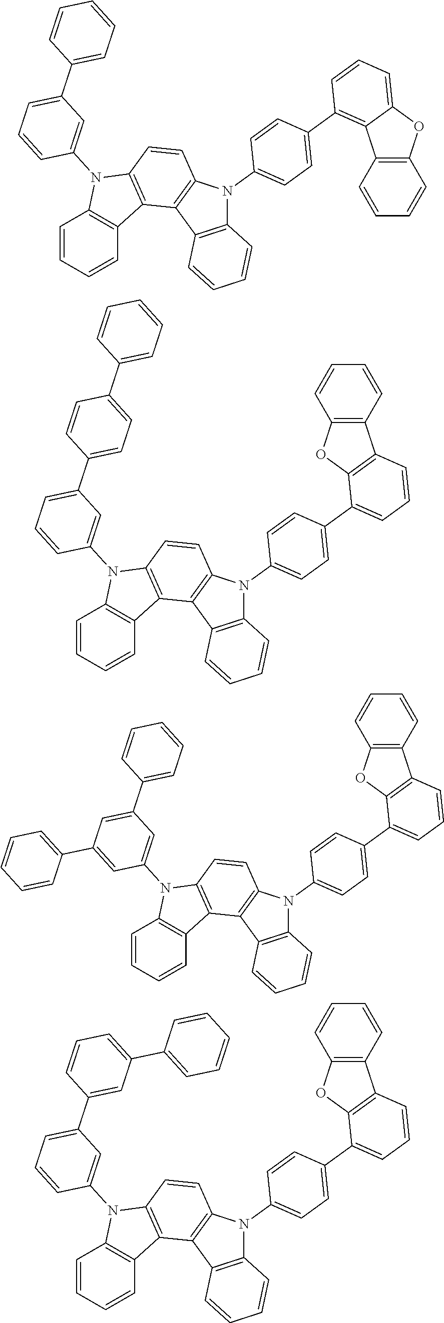

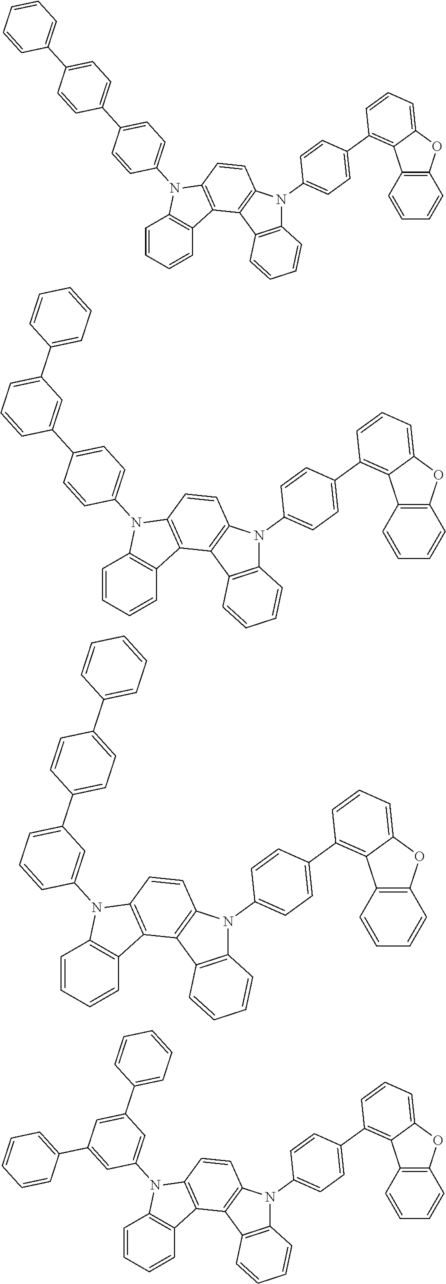

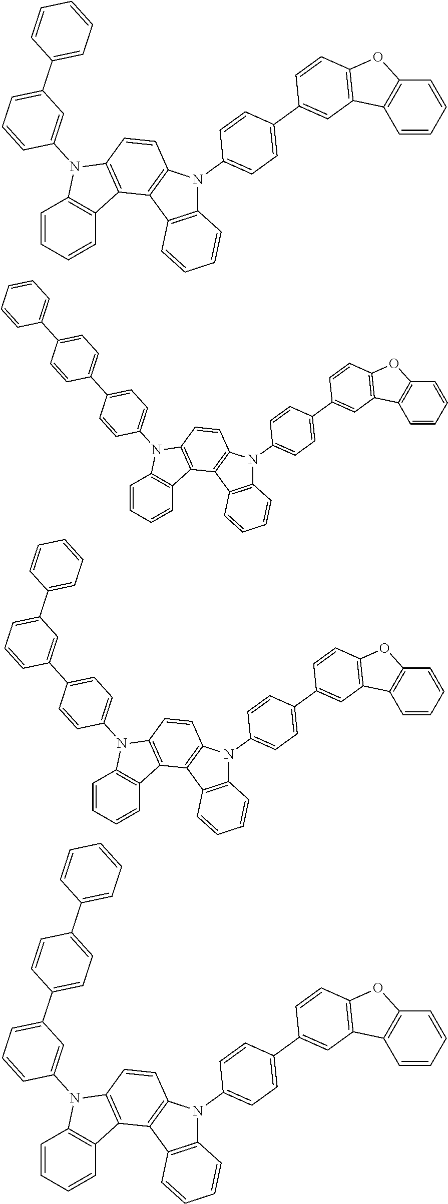

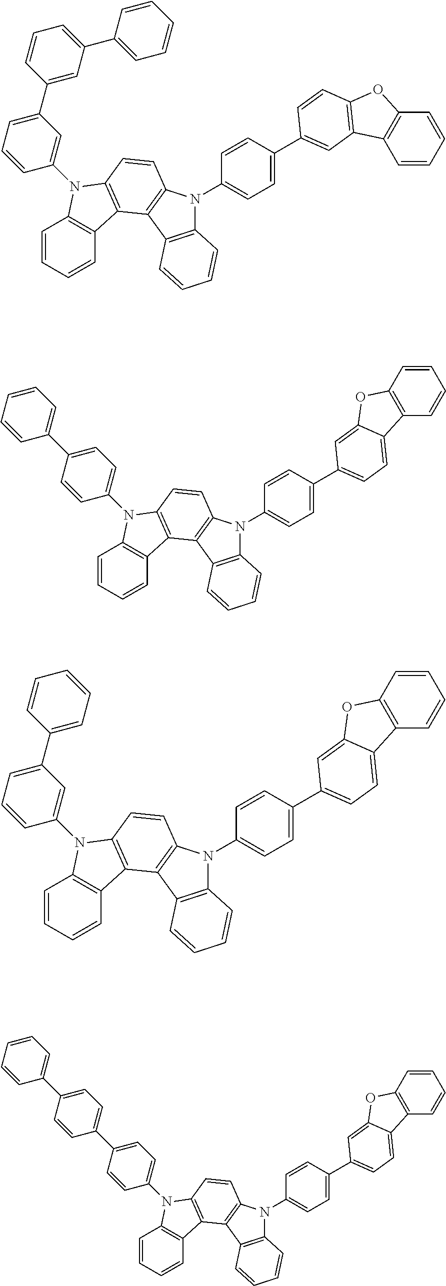 [SMILES: c1ccc(-c2cccc(-c3cccc(-n4c5ccccc5c5c6c7ccccc7n(-c7ccc(-c8ccc9oc%10ccccc%10c9c8)cc7)c6ccc54)c3)c2)cc1 ; c1ccc(-c2ccc(-n3c4ccccc4c4c5c6ccccc6n(-c6ccc(-c7ccc8c(c7)oc7ccccc78)cc6)c5ccc43)cc2)cc1 ; c1ccc(-c2cccc(-n3c4ccccc4c4c5c6ccccc6n(-c6ccc(-c7ccc8c(c7)oc7ccccc78)cc6)c5ccc43)c2)cc1 ; c1ccc(-c2ccc(-c3ccc(-n4c5ccccc5c5c6c7ccccc7n(-c7ccc(-c8ccc9c(c8)oc8ccccc89)cc7)c6ccc54)cc3)cc2)cc1]

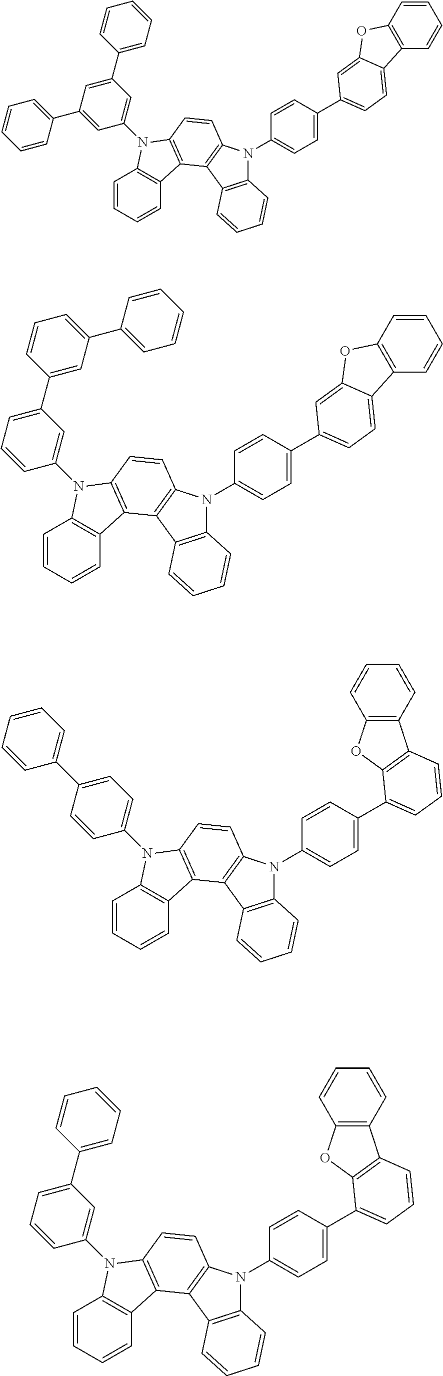 [SMILES: c1ccc(-c2cc(-c3ccccc3)cc(-n3c4ccccc4c4c5c6ccccc6n(-c6ccc(-c7ccc8c(c7)oc7ccccc78)cc6)c5ccc43)c2)cc1 ; c1ccc(-c2cccc(-c3cccc(-n4c5ccccc5c5c6c7ccccc7n(-c7ccc(-c8ccc9c(c8)oc8ccccc89)cc7)c6ccc54)c3)c2)cc1 ; c1ccc(-c2ccc(-n3c4ccccc4c4c5c6ccccc6n(-c6ccc(-c7cccc8c7oc7ccccc78)cc6)c5ccc43)cc2)cc1 ; c1ccc(-c2cccc(-n3c4ccccc4c4c5c6ccccc6n(-c6ccc(-c7cccc8c7oc7ccccc78)cc6)c5ccc43)c2)cc1]

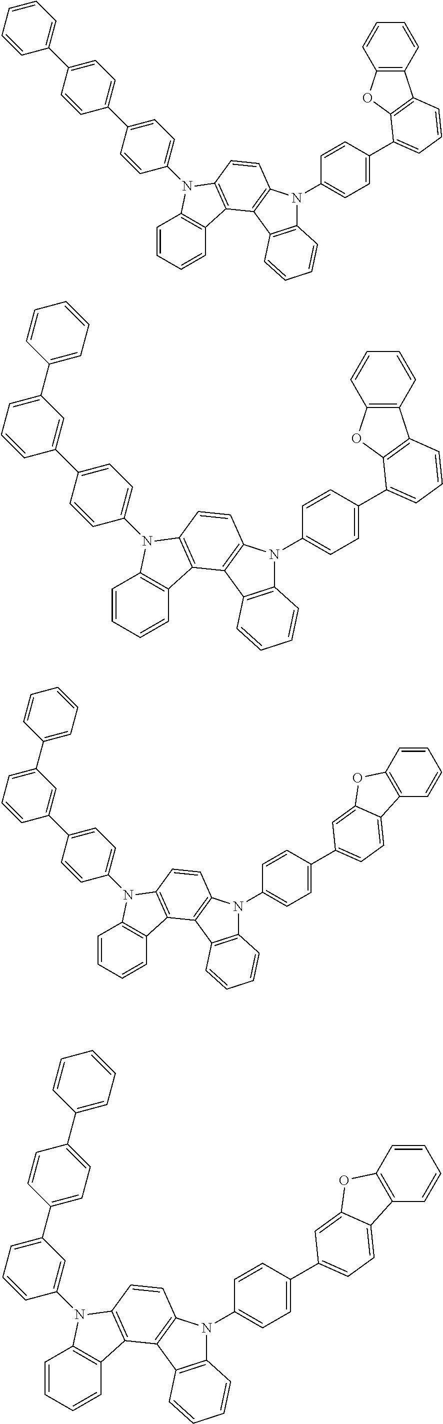 [SMILES: c1ccc(-c2ccc(-c3ccc(-n4c5ccccc5c5c6c7ccccc7n(-c7ccc(-c8cccc9c8oc8ccccc89)cc7)c6ccc54)cc3)cc2)cc1 ; c1ccc(-c2cccc(-c3ccc(-n4c5ccccc5c5c6c7ccccc7n(-c7ccc(-c8cccc9c8oc8ccccc89)cc7)c6ccc54)cc3)c2)cc1 ; c1ccc(-c2cccc(-c3ccc(-n4c5ccccc5c5c6c7ccccc7n(-c7ccc(-c8ccc9c(c8)oc8ccccc89)cc7)c6ccc54)cc3)c2)cc1 ; c1ccc(-c2ccc(-c3cccc(-n4c5ccccc5c5c6c7ccccc7n(-c7ccc(-c8ccc9c(c8)oc8ccccc89)cc7)c6ccc54)c3)cc2)cc1]

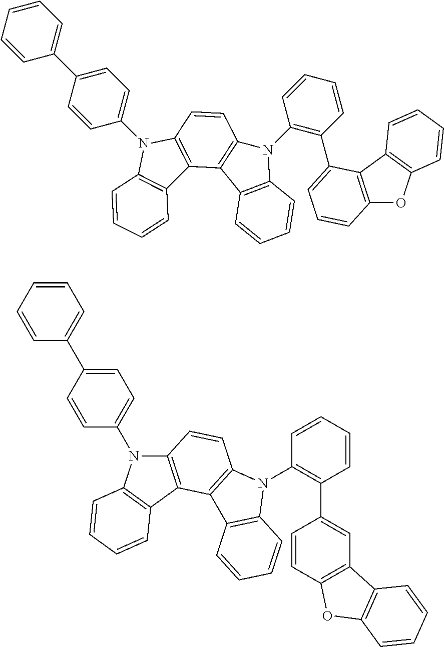 [SMILES: c1ccc(-c2ccc(-n3c4ccccc4c4c5c6ccccc6n(-c6ccccc6-c6cccc7oc8ccccc8c67)c5ccc43)cc2)cc1 ; c1ccc(-c2ccc(-n3c4ccccc4c4c5c6ccccc6n(-c6ccccc6-c6ccc7oc8ccccc8c7c6)c5ccc43)cc2)cc1]

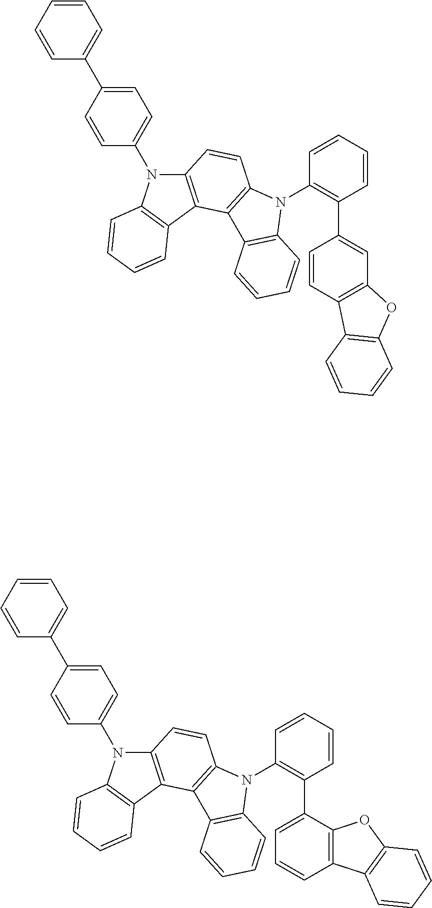 [SMILES: c1ccc(-c2ccc(-n3c4ccccc4c4c5c6ccccc6n(-c6ccccc6-c6ccc7c(c6)oc6ccccc67)c5ccc43)cc2)cc1 ; c1ccc(-c2ccc(-n3c4ccccc4c4c5c6ccccc6n(-c6ccccc6-c6cccc7c6oc6ccccc67)c5ccc43)cc2)cc1]

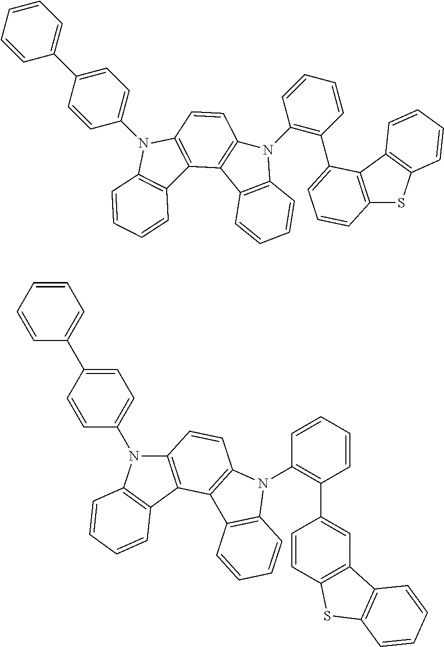 [SMILES: c1ccc(-c2ccc(-n3c4ccccc4c4c5c6ccccc6n(-c6ccccc6-c6cccc7sc8ccccc8c67)c5ccc43)cc2)cc1 ; c1ccc(-c2ccc(-n3c4ccccc4c4c5c6ccccc6n(-c6ccccc6-c6ccc7sc8ccccc8c7c6)c5ccc43)cc2)cc1]

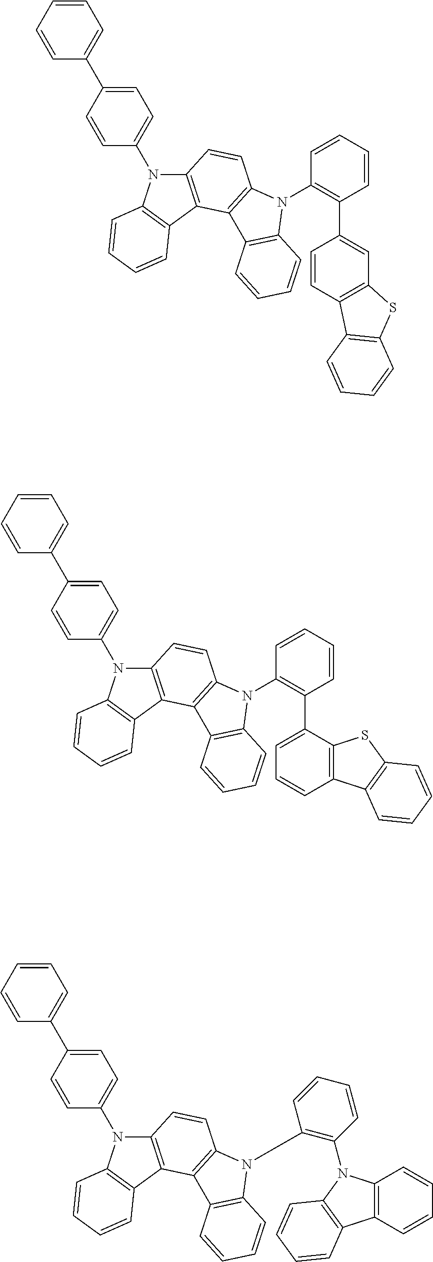 [SMILES: c1ccc(-c2ccc(-n3c4ccccc4c4c5c6ccccc6n(-c6ccccc6-c6ccc7c(c6)sc6ccccc67)c5ccc43)cc2)cc1 ; c1ccc(-c2ccc(-n3c4ccccc4c4c5c6ccccc6n(-c6ccccc6-c6cccc7c6sc6ccccc67)c5ccc43)cc2)cc1 ; c1ccc(-c2ccc(-n3c4ccccc4c4c5c6ccccc6n(-c6ccccc6-n6c7ccccc7c7ccccc76)c5ccc43)cc2)cc1]

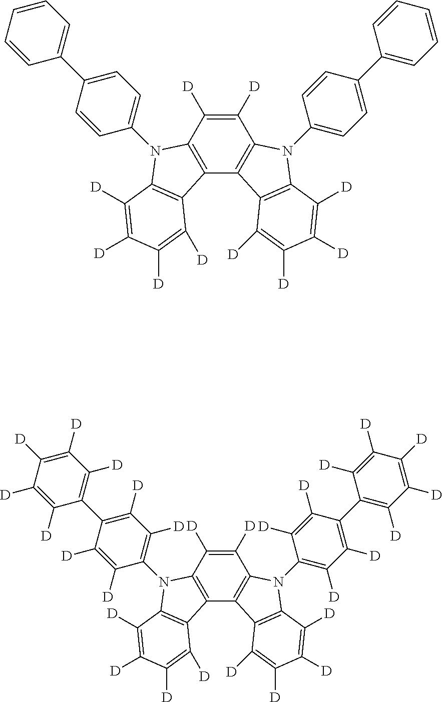 [SMILES: [2H]c1c([2H])c([2H])c2c(c1[2H])c1c3c4c([2H])c([2H])c([2H])c([2H])c4n(-c4ccc(-c5ccccc5)cc4)c3c([2H])c([2H])c1n2-c1ccc(-c2ccccc2)cc1 ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c(-c7c([2H])c([2H])c([2H])c([2H])c7[2H])c([2H])c6[2H])c5c([2H])c([2H])c43)c([2H])c2[2H])c([2H])c1[2H]]

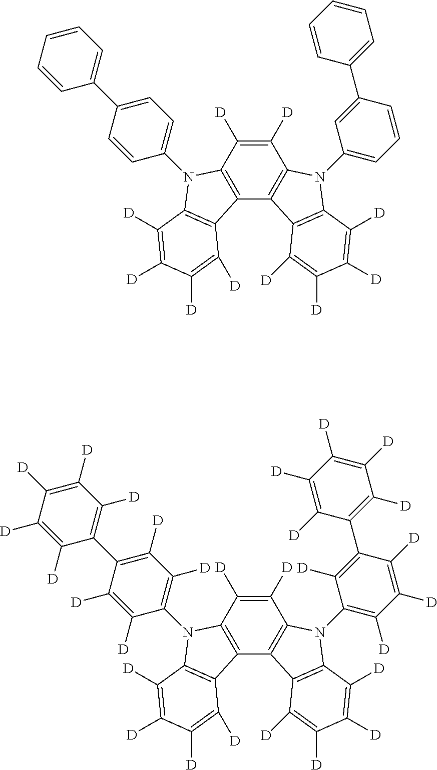 [SMILES: [2H]c1c([2H])c([2H])c2c(c1[2H])c1c3c4c([2H])c([2H])c([2H])c([2H])c4n(-c4cccc(-c5ccccc5)c4)c3c([2H])c([2H])c1n2-c1ccc(-c2ccccc2)cc1 ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c([2H])c(-c7c([2H])c([2H])c([2H])c([2H])c7[2H])c6[2H])c5c([2H])c([2H])c43)c([2H])c2[2H])c([2H])c1[2H]]

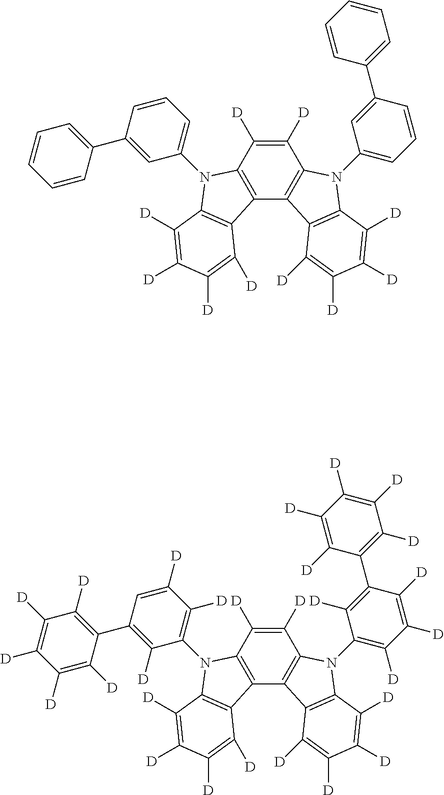 [SMILES: [2H]c1c([2H])c([2H])c2c(c1[2H])c1c3c4c([2H])c([2H])c([2H])c([2H])c4n(-c4cccc(-c5ccccc5)c4)c3c([2H])c([2H])c1n2-c1cccc(-c2ccccc2)c1 ; [2H]c1cc(-c2c([2H])c([2H])c([2H])c([2H])c2[2H])c([2H])c(-n2c3c([2H])c([2H])c([2H])c([2H])c3c3c4c5c([2H])c([2H])c([2H])c([2H])c5n(-c5c([2H])c([2H])c([2H])c(-c6c([2H])c([2H])c([2H])c([2H])c6[2H])c5[2H])c4c([2H])c([2H])c32)c1[2H]]

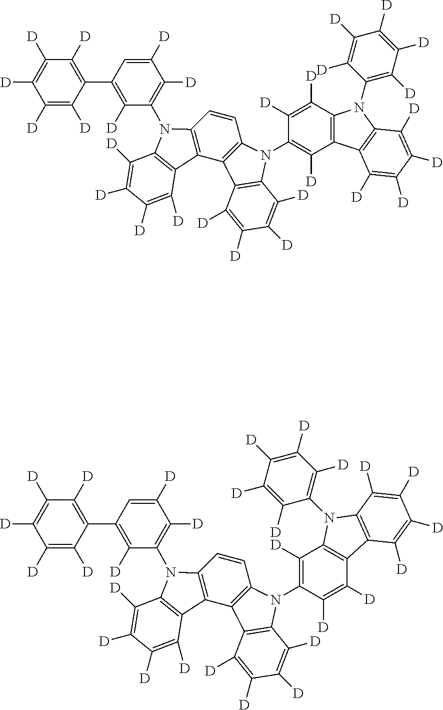 [SMILES: [2H]c1cc(-c2c([2H])c([2H])c([2H])c([2H])c2[2H])c([2H])c(-n2c3ccc4c(c5c([2H])c([2H])c([2H])c([2H])c5n4-c4c([2H])c([2H])c5c(c4[2H])c4c([2H])c([2H])c([2H])c([2H])c4n5-c4c([2H])c([2H])c([2H])c([2H])c4[2H])c3c3c([2H])c([2H])c([2H])c([2H])c32)c1[2H] ; [2H]c1cc(-c2c([2H])c([2H])c([2H])c([2H])c2[2H])c([2H])c(-n2c3ccc4c(c5c([2H])c([2H])c([2H])c([2H])c5n4-c4c([2H])c([2H])c5c6c([2H])c([2H])c([2H])c([2H])c6n(-c6c([2H])c([2H])c([2H])c([2H])c6[2H])c5c4[2H])c3c3c([2H])c([2H])c([2H])c([2H])c32)c1[2H]]

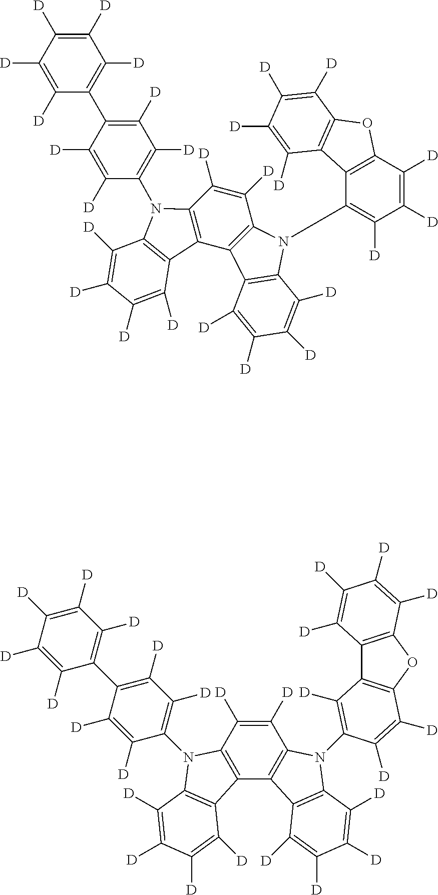 [SMILES: [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c([2H])c7oc8c([2H])c([2H])c([2H])c([2H])c8c67)c5c([2H])c([2H])c43)c([2H])c2[2H])c([2H])c1[2H] ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c7oc8c([2H])c([2H])c([2H])c([2H])c8c7c6[2H])c5c([2H])c([2H])c43)c([2H])c2[2H])c([2H])c1[2H]]

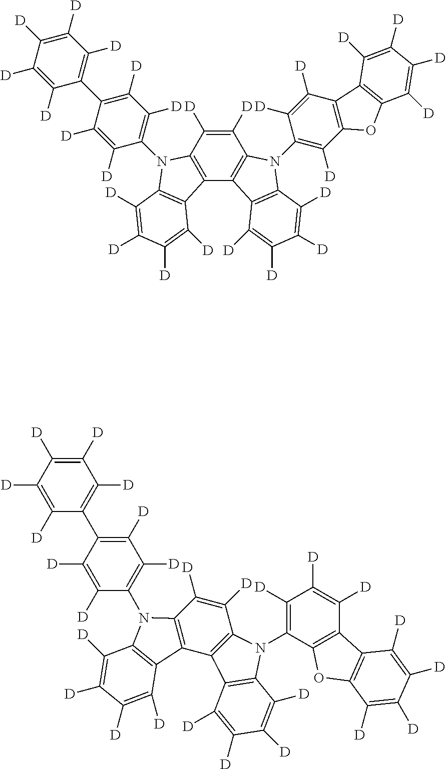 [SMILES: [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c7c(oc8c([2H])c([2H])c([2H])c([2H])c87)c6[2H])c5c([2H])c([2H])c43)c([2H])c2[2H])c([2H])c1[2H] ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c([2H])c7c6oc6c([2H])c([2H])c([2H])c([2H])c67)c5c([2H])c([2H])c43)c([2H])c2[2H])c([2H])c1[2H]]

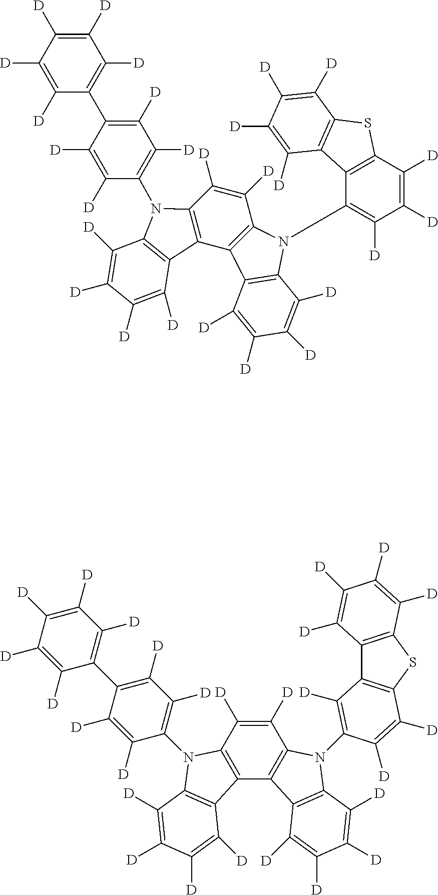 [SMILES: [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c([2H])c7sc8c([2H])c([2H])c([2H])c([2H])c8c67)c5c([2H])c([2H])c43)c([2H])c2[2H])c([2H])c1[2H] ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c7sc8c([2H])c([2H])c([2H])c([2H])c8c7c6[2H])c5c([2H])c([2H])c43)c([2H])c2[2H])c([2H])c1[2H]]

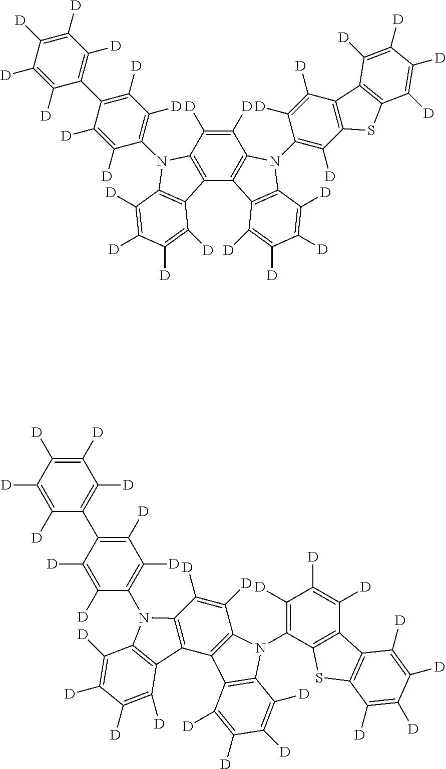 [SMILES: [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c7c(sc8c([2H])c([2H])c([2H])c([2H])c87)c6[2H])c5c([2H])c([2H])c43)c([2H])c2[2H])c([2H])c1[2H] ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c([2H])c7c6sc6c([2H])c([2H])c([2H])c([2H])c67)c5c([2H])c([2H])c43)c([2H])c2[2H])c([2H])c1[2H]]

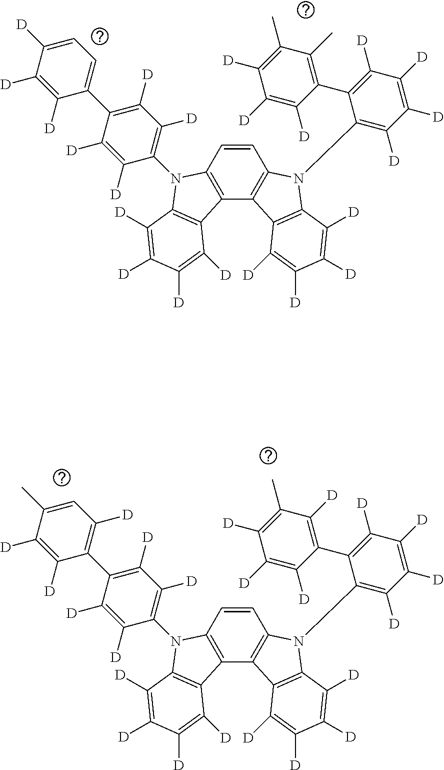 [SMILES: [2H]c1ccc(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c([2H])c(C)c5C)c4c4c([2H])c([2H])c([2H])c([2H])c43)c([2H])c2[2H])c([2H])c1[2H] ; [2H]c1cc(C)c([2H])c([2H])c1-c1c([2H])c([2H])c(-n2c3ccc4c(c5c([2H])c([2H])c([2H])c([2H])c5n4-c4c([2H])c([2H])c([2H])c([2H])c4-c4c([2H])c([2H])c([2H])c(C)c4[2H])c3c3c([2H])c([2H])c([2H])c([2H])c32)c([2H])c1[2H]]

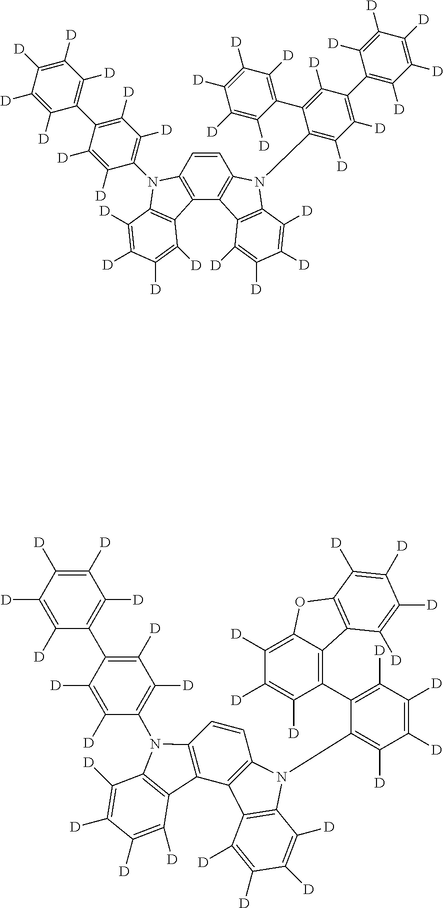

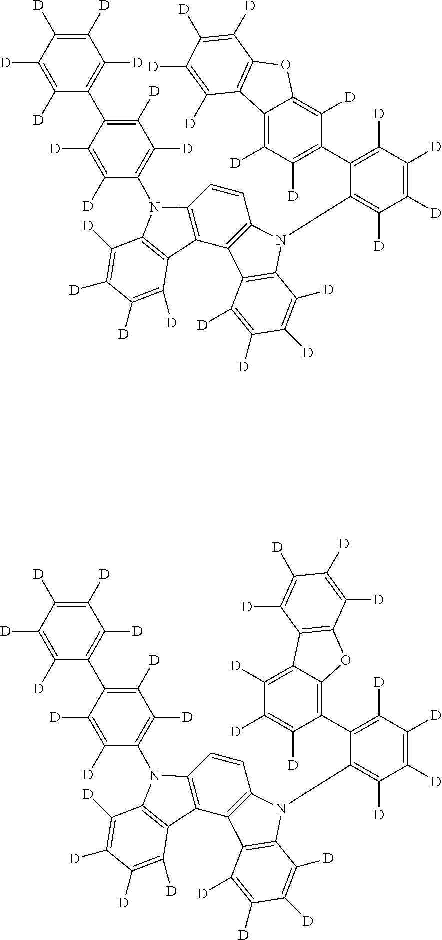 [SMILES: [2H]c1c([2H])c([2H])c(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c6c(oc7c([2H])c([2H])c([2H])c([2H])c76)c5[2H])c4c4c([2H])c([2H])c([2H])c([2H])c43)c([2H])c2[2H])c([2H])c1[2H] ; [2H]c1c([2H])c([2H])c(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c([2H])c6c5oc5c([2H])c([2H])c([2H])c([2H])c56)c4c4c([2H])c([2H])c([2H])c([2H])c43)c([2H])c2[2H])c([2H])c1[2H]]

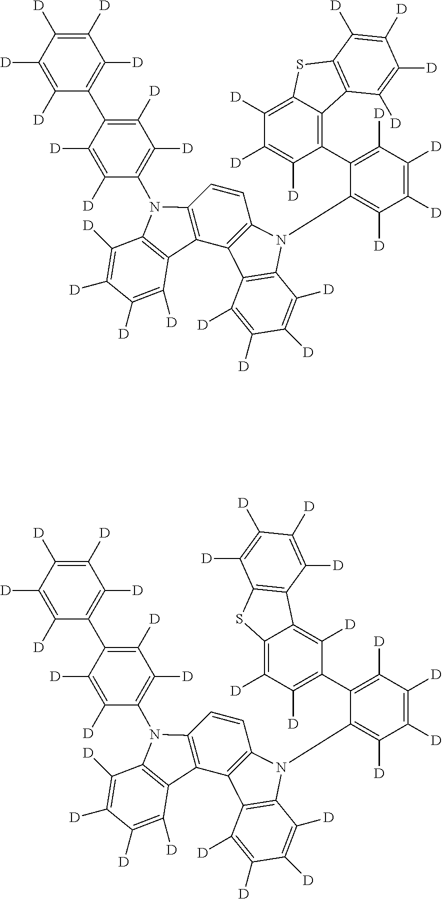 [SMILES: [2H]c1c([2H])c([2H])c(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c([2H])c6sc7c([2H])c([2H])c([2H])c([2H])c7c56)c4c4c([2H])c([2H])c([2H])c([2H])c43)c([2H])c2[2H])c([2H])c1[2H] ; [2H]c1c([2H])c([2H])c(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c6sc7c([2H])c([2H])c([2H])c([2H])c7c6c5[2H])c4c4c([2H])c([2H])c([2H])c([2H])c43)c([2H])c2[2H])c([2H])c1[2H]]

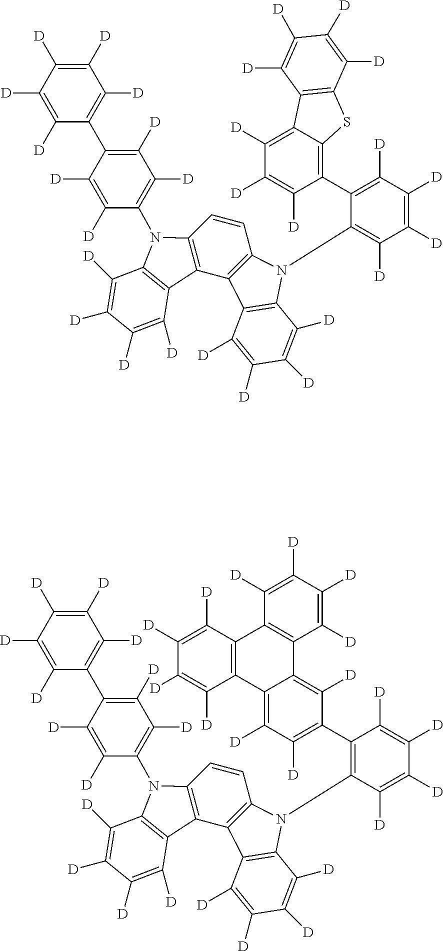

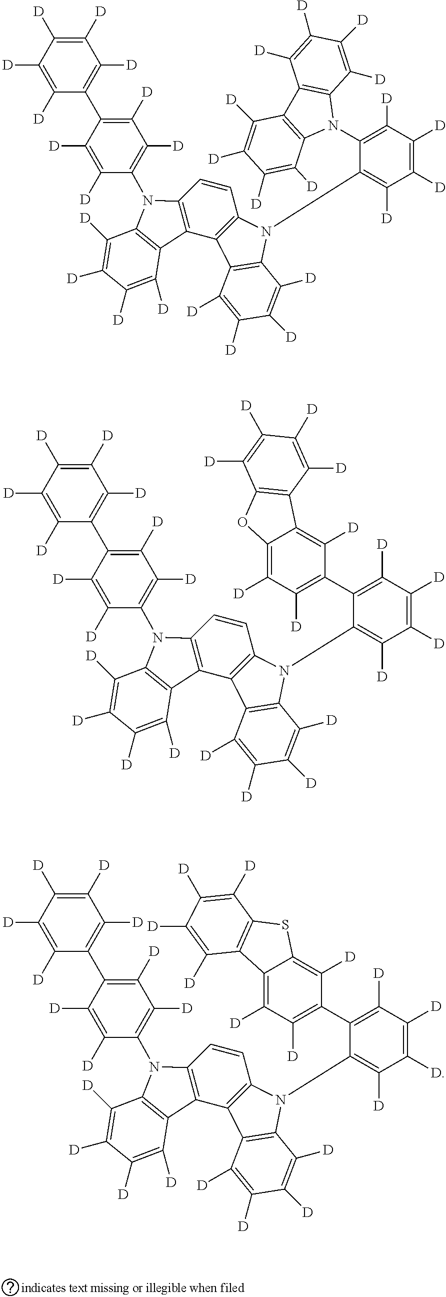

8. The composition for an organic light emitting device of claim 1, wherein:
Ar is phenyl, biphenylyl, terphenylyl, or quaterphenylyl,
wherein, Ar is unsubstituted or substituted with deuterium or tritium.

9. The composition for an organic light emitting device of claim 1, wherein:
R₁₁ to R₁₄ are each independently hydrogen, deuterium, tritium, or phenyl substituted or unsubstituted with deuterium or tritium; or are combined with adjacent substituents to form a benzofuran ring substituted or unsubstituted with deuterium or tritium, or a benzothiophene ring substituted or unsubstituted with deuterium or tritium.

10. The composition for an organic light emitting device of claim 1, wherein:
the substituents 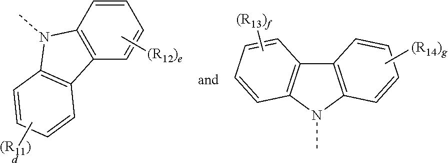
are each independently any one selected from the substituents represented by the following chemical formulas 2-1 to 2-8 and their deuterated or tritiated structures: 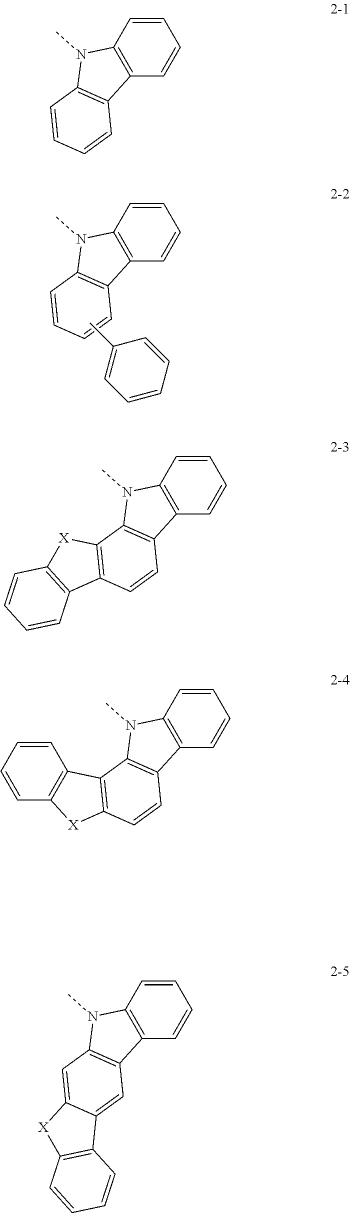 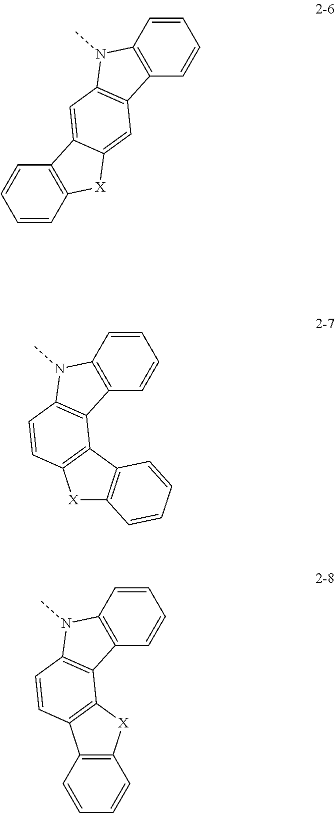
wherein in Chemical Formulas 2-1 to 2-8,
X is O of S.

11. The composition for an organic light emitting device of claim 1, wherein:
R₁₅ and R₁₆ are each independently hydrogen, deuterium, tritium, or phenyl unsubstituted or substituted with deuterium or tritium.

12. The composition for an organic light emitting device of claim 1, wherein:
the second compound is any one selected from the group consisting of the following compounds:

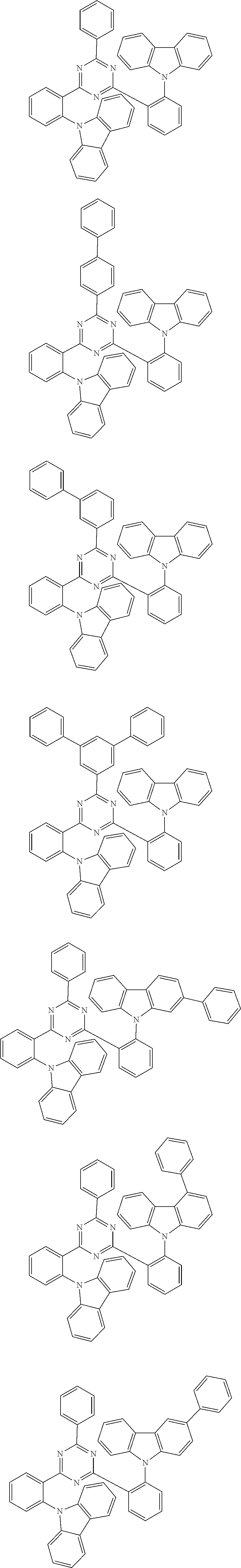

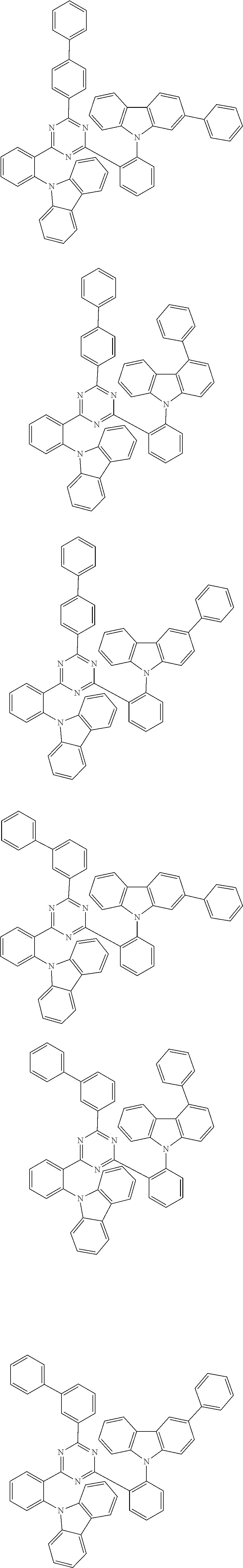

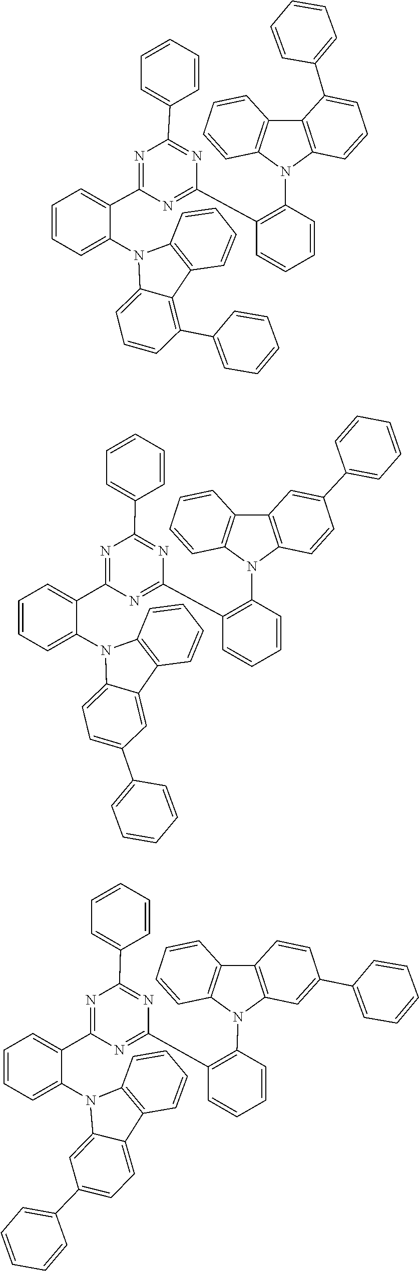

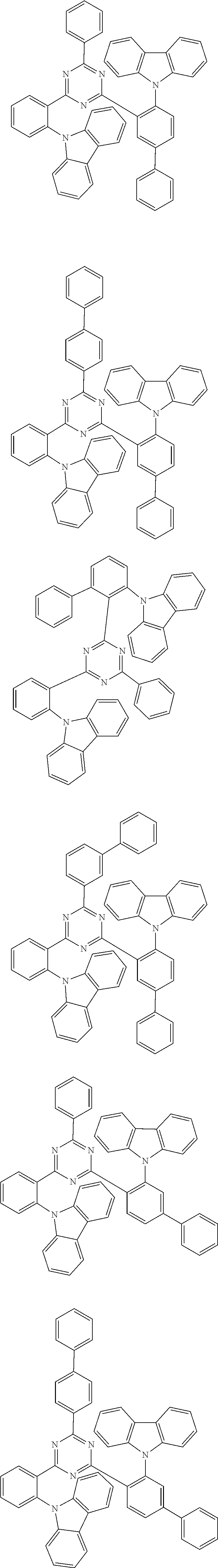

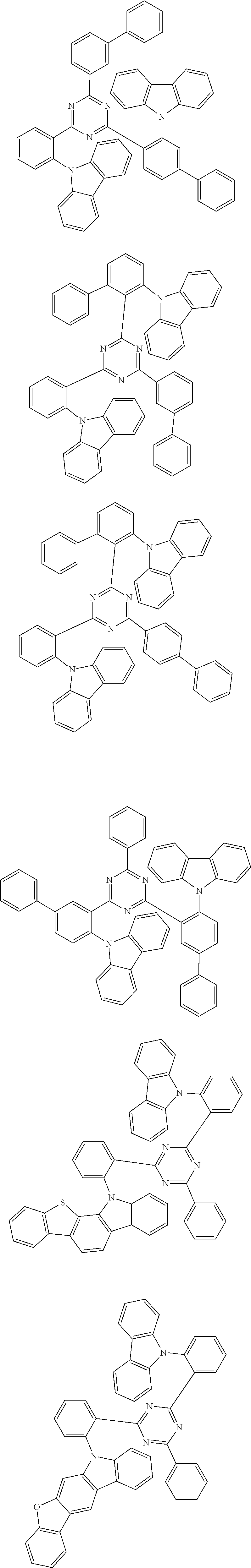

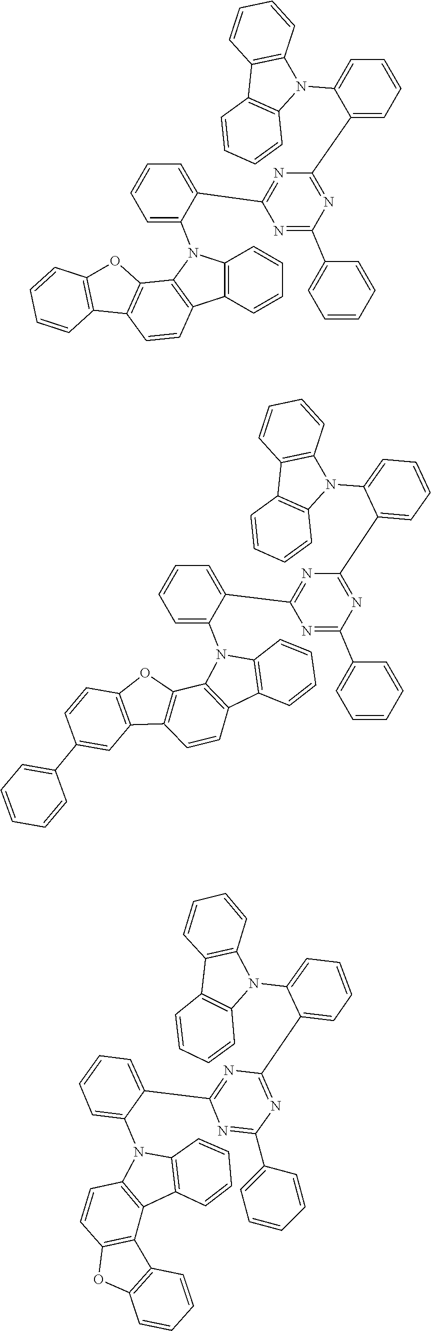 [SMILES: c1ccc(-c2nc(-c3ccccc3-n3c4ccccc4c4ccccc43)nc(-c3ccccc3-n3c4ccccc4c4ccc5c6ccccc6oc5c43)n2)cc1 ; c1ccc(-c2ccc3oc4c(ccc5c6ccccc6n(-c6ccccc6-c6nc(-c7ccccc7)nc(-c7ccccc7-n7c8ccccc8c8ccccc87)n6)c54)c3c2)cc1 ; c1ccc(-c2nc(-c3ccccc3-n3c4ccccc4c4ccccc43)nc(-c3ccccc3-n3c4ccccc4c4c5c(ccc43)oc3ccccc35)n2)cc1]

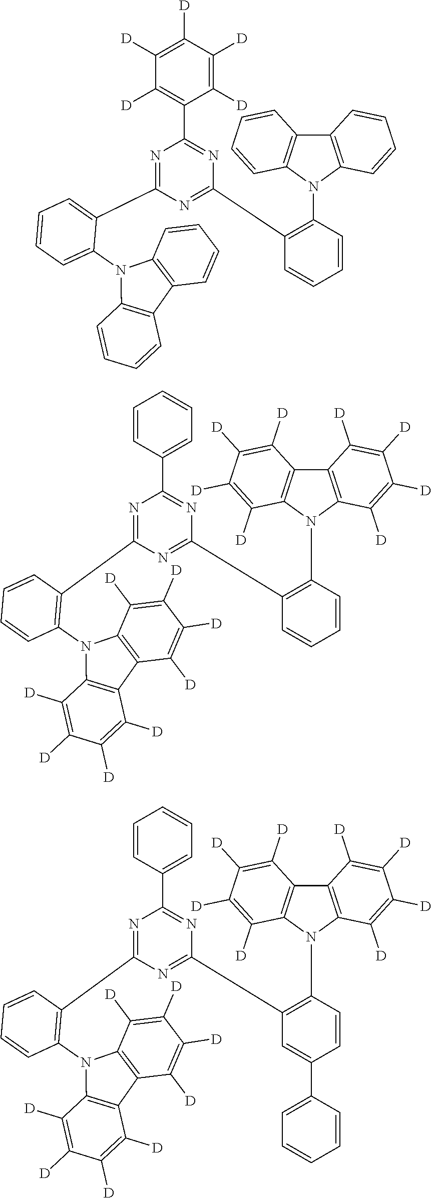

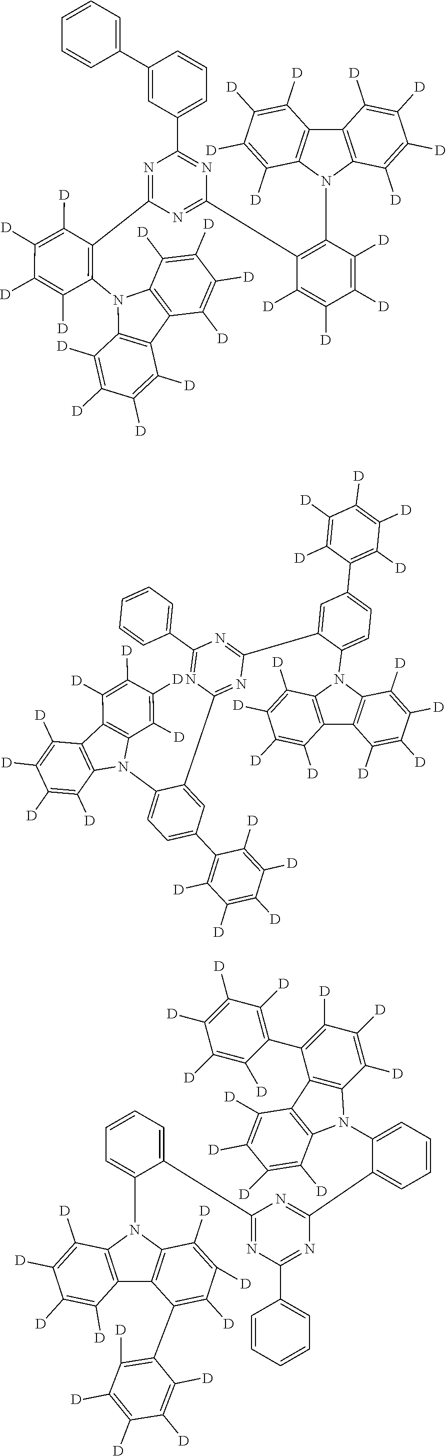

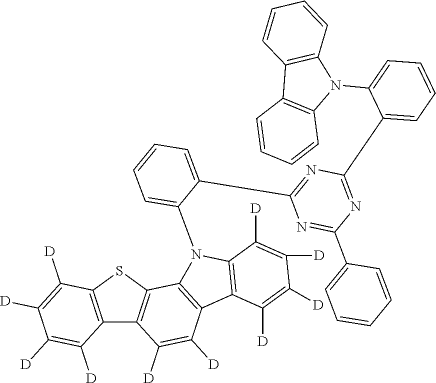 [SMILES: [2H]c1c([2H])c([2H])c2c(sc3c2c([2H])c([2H])c2c4c([2H])c([2H])c([2H])c([2H])c4n(-c4ccccc4-c4nc(-c5ccccc5)nc(-c5ccccc5-n5c6ccccc6c6ccccc65)n4)c32)c1[2H]]

13. The composition for an organic light emitting device of claim 1, wherein:
The substituent L₁-Ar₁ of the first compound and the substituent Ar of the second compound do not contain a fused polycyclic substituent.

14. The composition for an organic light emitting device of claim 1, wherein:
the first compound and the second compound are included in a weight ratio of 1:1 to 3:1.

15. The composition for an organic light emitting device of claim 1, wherein:
the composition is a mixture or an organic alloy.

16. An organic light emitting device comprising: a first electrode; a second electrode that is provided opposite to the first electrode; and one or more organic material layers that are provided between the first electrode and the second electrode, wherein one or more layers of the organic material layers comprises the composition for an organic light emitting device of claim 1.

17. The organic light emitting device of claim 16, wherein:
the organic material layers comprising the composition are a light emitting layer.

18. The organic light emitting device of claim 16, wherein:
the light emitting layer further comprises a dopant material, and
the dopant material is an iridium complex compound.

19. An organic light emitting device comprising:
an anode;
a cathode which is provided opposite to the anode; and
a light emitting layer which is interposed between the anode and the cathode,
wherein the light emitting layer includes a first compound represented by the following Chemical Formula 1, and a second compound represented by the following Chemical Formula 2: 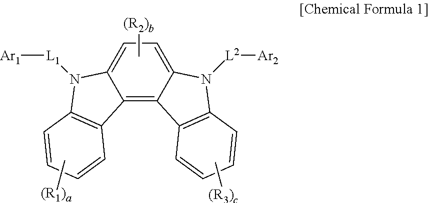
wherein in Chemical Formula 1,
L₁ and L₂ are each independently a single bond, or a substituted or unsubstituted C₆₋₆₀ arylene,
Ar₁ is a substituted or unsubstituted C₆₋₆₀ aryl,
Ar₂ is a substituted or unsubstituted C₆₋₆₀ aryl, or a substituted or unsubstituted C₂₋₆₀ heteroaryl containing at least one heteroatom selected among N, O and S, provided that the case where Ar₂ is a monocyclic containing one or more N atoms is excluded,
R₁ to R₃ are each independently hydrogen, deuterium, or tritium,
a and b are each independently an integer from 0 to 4, and
b is an integer from 0 to 2, 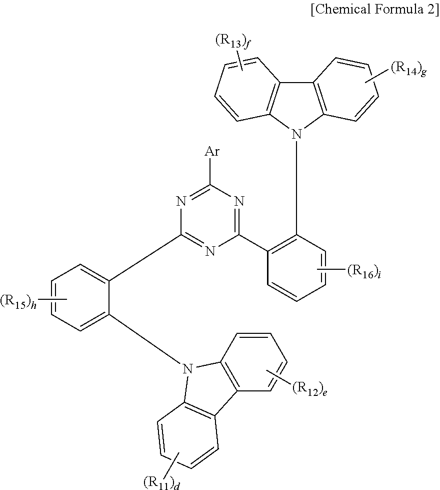
wherein in Chemical Formula 2,
Ar is C₆₋₆₀ aryl unsubstituted or substituted with one or more substituents selected from the group consisting of deuterium, tritium, alkyl, and aryl, or being unsubstituted or substituted with a substituent to which two or more substituents of the above-exemplified substituents are connected,
R₁₁ to R₁₄ are each independently hydrogen, deuterium, tritium, or a substituted or unsubstituted C₆₋₆₀ aryl; or are combined with adjacent substituents to form a substituted or unsubstituted C₆₋₆₀ aromatic ring or a substituted or unsubstituted C₂₋₆₀ heteroaromatic ring containing at least one heteroatom selected among N, O and S,
R₁₅ and R₁₆ are each independently hydrogen, deuterium, tritium, or a substituted or unsubstituted C₆₋₆₀ aryl, and
d to i are each independently an integer from 0 to 4.
